(19) United States
(12) Patent Application Publication
(10) Pub. No.: US 2025/0113445 A1
(43) Pub. Date: Apr. 3, 2025

(54) SYSTEMS, METHODS, AND DEVICES FOR CONFIGURING ONE OR MORE MATERIAL PROPERTIES OF A METAL MATERIAL UTILIZED IN A DEFORMABLE CIRCUIT

(71) Applicant: Meta Platforms Technologies, LLC, Menlo Park, CA (US)

(72) Inventors: Wenyang Pan, Redmond, WA (US); Zixuan Deng, Redmond, WA (US); Omar Awartani, Redmond, WA (US); Marcos Antonio Santana Andrade, JR., Seattle, WA (US); Felippe Jose Pavinatto, Lynnwood, WA (US); Kristopher Erickson, Sammamish, WA (US)

(21) Appl. No.: 18/479,768

(22) Filed: Oct. 2, 2023

(51) Int. Cl. H05K 3/40; H05K 1/03

(52) U.S. Cl. CPC H05K 3/4015; H05K 1/0393

(57) ABSTRACT

The present disclosure provides systems, methods, and devices for producing an interconnect. A method of manufacturing an electronic device includes forming a first circuit component at a first portion of a deformable substrate. The method further includes forming a second circuit component at a second portion of the deformable substrate. Additionally, the method includes electronically coupling the first circuit component and the second circuit component with a composition. The composition includes a first metal material further including a first weight percent (w %) of the composition. the first metal material is gallium indium alloy, gallium tin alloy, gallium indium tin alloy, gallium indium tin zinc alloy, or a combination thereof. The composition includes a filler material disposed within the first metal material. The filler material includes a second w % of the composition. Accordingly, the method forms an interconnect between the first circuit component and the second circuit component.

### CROSS-REFERENCE TO RELATED APPLICATION

The present application claims priority to U.S. Provisional Patent Application No. 63/412,333, entitled “Systems, Methods, and Devices for Configuring One or More Material Properties of a Metal Material Utilized in a Deformable Circuit,” filed Sep. 30, 2022, which is hereby incorporated by reference in its entirety for all purposes.

### TECHNICAL FIELD

This disclosure relates to additive manufacturing. More particularly, the present disclosure relates to using systems, methods, and devices for configuring one or more material properties of a metal material, such as that utilized in an interconnect for providing electrical communication through a deformable substrate.

### BACKGROUND

Flexible circuits have become a desirable product due to their ability for application with a wide variety of use capabilities for prolonged durations of time.

Conventional solutions for manufacturing such flexible circuits have proposed using a liquid metal, particularly gallium (Ga)-based liquid metals. Ga-based liquid metal is conventionally considered desirable for use in flexible circuits, particularly to form an interconnect of the flexible circuit, because Ga-based liquid metals are a class of materials with excellent electrical conductivity, thermal conductivity, and stretchability due to the fluidic properties of the Ga-based liquid metal. Conventional Ga-based liquid metals include a gallium indium alloy (e.g., eutectic GaIn (EGaln)) or a gallium indium tin alloy (e.g., Galinstan). However, such conventional Ga-based liquid metals have low viscosity, high surface tension, and poor wettability on certain substrates, such as silicon, utilized in the flexible circuits. This is particularly true for metal materials under ambient conditions. Accordingly, the low viscosity, high surface tension, and poor wettability of the conventional Ga-based liquid metals limit the printing techniques that are utilized with the conventional Ga-based liquid.

Given the above background, systems, methods, and devices are needed that enable rapid manufacture of objects using flexible electronics. In particular, there is a need for enabling the manufacture of objects using flexible electronics that is rapidly and repeatedly deformable in order to produce higher quality devices.

### SUMMARY

The present disclosure addresses the above-identified shortcomings.

The present disclosure is directed to systems, methods, and devices that facilitate an electrical communication through a circuit, in which the electrical communication is maintained when a force is applied to the circuit. This force includes a tensile force, a compressive force, a shear force, a torsional force, or a combination thereof. In some embodiments, this force is applied to the circuit upwards of 15,000 applications during which the electrical communication is maintained through the circuit.

The present disclosure is directed to providing systems, methods, and devices that utilize a composition. The composition is configurable in order control a viscosity of the composition and/or a wettability of the composition. In some embodiments, the composition includes a first metal material and a filler material. In some embodiments, the first metal material is a liquid metal material, such that the first metal material exists at a liquid phase at a temperature between 18 degrees Celsius (° C.) and 22° C. In some embodiments, the filler includes, or is, a metal oxide or a polymer such as a metal-oxide based polymer. For instance, in some embodiments, the filler includes indium tin oxide (ITO). However, the present disclosure is not limited thereto. In some embodiments, the composition of the present disclosure in comparison to conventional Ga-based liquid metals has a higher viscosity. Moreover, in some embodiments, the composition of the present disclosure in comparison to conventional Ga-based liquid metals has a higher wettability. Furthermore, in some embodiments, the composition of the present disclosure remains in a region of elastic deformation when a forced is applied including a stretchability as the pristine liquid metal.

In some embodiments, the systems, methods, and devices of the present disclosure provide for manufacture of an object at an additive manufacture apparatus that utilizes a composition of the present disclosure for disposition on a deformable substrate in order to form a circuit.

Turning to more specific aspects, one aspect of the present disclosure is directed to providing a method of manufacturing an electronic device. The method includes forming a first circuit component at a first portion of a deformable substrate. The method further includes forming a second circuit component at a second portion of the deformable substrate. Furthermore, the method includes electronically coupling the first circuit component and the second circuit component with a composition. The composition includes a first metal material having a first weight percent (w %) of the composition. The first metal material is gallium indium alloy, gallium tin alloy, gallium indium tin alloy, gallium indium tin zinc alloy, or a combination thereof. The composition further includes a filler material disposed within the first metal material. The filler material includes a second w % of the composition. From this composition, the method forms an interconnect between the first circuit component and the second circuit component.

In some embodiments, the composition is a non-Newtonian composition and/or a shear-thinning composition.

In some embodiments, the composition includes a homogenous mixture of the first metal material and the filler material.

In some embodiments, the filler material is a metal oxide, a metal oxide-based polymer, or a combination thereof.

In some embodiments, the filler material includes aluminum, carbon, copper, gallium, indium-tin oxide (ITO), lithium, nickel, titanium, or a combination thereof.

In some embodiments, the filler material includes a non-intrinsic metal oxide.

In some embodiments, the filler material is added to the first metal material in the form of microflakes, nanoflakes, microparticles, nanoparticles, nanowires, nanotubes, or a combination thereof, in order to form the composition.

In some embodiments, the filler material includes poly(3,4-ethylenedioxythiophene) (PEDOT) or polystyrene sulfonate (PEDOT:PSS).

In some embodiments, the method further includes disposing exogenously the filler material within the first metal material to form the composition.

In some embodiments, the method further includes disposing the filler material within the first metal material without sintering the first metal material and/or the filler material to form the composition.

In some embodiments, the second w % of the filler material is between 0.5 w % and 25 w % within the composition, or between 13 w % and 15 w % within the composition.

In some embodiments, the method further includes coupling the first circuit component to the second circuit component with the composition to form the interconnect when the filler material is oversaturated in excess of a saturation point of the filler material in the first metal material in the composition.

In some embodiments, the interconnect formed by the composition has a resistance under at most 100 Ohms per centimeter (cm) when the interconnect is subjected to 100% strain at a first strain cycle, and under at most 100 Ohms per cm when subjected to 100% strain at a second strain cycle, in which the second strain cycle is at least 15,000 strain cycles greater than the first strain cycle.

In some embodiments, the method further includes disposing the composition between the first circuit component and the second circuit component using a source for the composition that, at a temperature between 64 degrees Fahrenheit (° F.) and 72° F., has a viscosity that is between 0.5 Pascal seconds (Pa·s) and 1.6 Pa·s, thereby forming the interconnect.

In some embodiments, the composition further includes a dispersant material different from the first metal material and the filler material.

In some embodiments, the interconnect has a width of between 1 and 500 micron (μm), between 2 and 400 μm, between 3 and 300 μm, between 4 and 200 μm, between 6 and 100 μm, or between 10 and 90 μm. Moreover, the interconnect has a thickness of between 1 and 500 μm, between 2 and 400 μm, between 3 and 300 μm, between 4 and 200 μm, between 6 and 100 μm, or between 10 and 90 μm.

In some embodiments, the first circuit component and the second circuit component form part of an active-matrix array.

In some embodiments, the interconnect is free of degradation in conductivity when the deformable substrate is bent around a cylinder that has a radius of between 2 cm and 10 cm for a period of time between 2 seconds and five minutes and then released.

### BRIEF DESCRIPTION OF THE DRAWINGS

The implementations disclosed herein are illustrated by way of example, and not by way of limitation, in the figures of the accompanying drawings. Like reference numerals refer to corresponding parts throughout the drawings.

FIG. 1 illustrates an exemplary distributed additive manufacture system topology including a computer system and an additive manufacture system, in accordance with an embodiment of the present disclosure;

FIG. 2 illustrates various modules and/or components of a computer system, in accordance with an exemplary embodiment of the present disclosure;

FIG. 3A illustrates a cross-sectional side view of an electronic device, in accordance with an embodiment of the present disclosure;

FIG. 3B illustrates a cross-sectional side view of a composition, in accordance with an embodiment of the present disclosure;

FIGS. 4A, 4B, 4C, and 4D collectively provide a flow chart illustrating exemplary methods for forming a deformable electrical communication between a first circuit component and a second circuit component, in accordance with an embodiment of the present disclosure, in which optional elements of embodiments are indicated by dashed boxes and/or lines;

FIG. 5 illustrates a first volume of a conventional Ga-based liquid metal and a second volume of a composition of the present disclosure, in accordance with an exemplary embodiment of the present disclosure;

FIG. 6 illustrates a chart depicting an apparent viscosity against a shear rate for various compositions, in accordance with some embodiments of the present disclosure;

FIG. 7 illustrates a plurality of line interconnects formed by disposing a composition using various additive manufacture apparatuses, in accordance with some embodiments of the present disclosure;

FIG. 8 illustrates a plurality of line interconnects formed by disposing a composition using various additive manufacture apparatuses, in accordance with some embodiments of the present disclosure;

FIG. 9 illustrates a chart depicting a resistance of a composition when subjected to 100% strain at a first strain cycle, in accordance with an exemplary embodiment of the present disclosure;

FIG. 10 illustrates a deformable substrate including a first layer of a circuit and a second layer of the circuit, in accordance with an exemplary embodiment of the present disclosure;

FIG. 11A illustrates an enlarged view of an electronic device prior to a force applied to a substrate of the electronic device, in accordance with an exemplary embodiment of the present disclosure;

FIG. 11B illustrates another enlarged view of the electronic device of FIG. 11B after to a force is applied to a substrate of the electronic device;

FIG. 12A illustrates a first layer of a first metal material disposed on a surface of a deformable substrate, in accordance with some embodiments of the present disclosure;

FIG. 12B illustrates a second layer of a second metal material disposed on the first layer of the first metal material of FIG. 12A;

FIG. 13 illustrates various logic functions that are used in some embodiments of the present disclosure; and

FIG. 14 illustrates an electronic device including a deformable substrate, in accordance with an embodiment of the present disclosure.

### DETAILED DESCRIPTION

The present disclosure provides systems, methods, and devices for utilizing a composition within a deformable substrate. A method of manufacturing an electronic device includes forming a first circuit component at a first portion of a deformable substrate. The method further includes forming a second circuit component at a second portion of the deformable substrate. Additionally, the method includes electronically coupling the first circuit component and the second circuit component with a composition. The composition includes a first metal material further including a first weight percent (w %) of the composition. In some embodiments, the first metal material is gallium indium alloy, gallium tin alloy, gallium indium tin alloy, gallium indium tin zinc alloy, or a combination thereof. The composition includes a filler material disposed within the first metal material. The filler material includes a second w % of the composition. In some embodiments, the filler material is indium tin oxide (ITO). Accordingly, the method forms an interconnect between the first circuit component and the second circuit component through the composition. Moreover, since the composition includes the first metal material, the electronically coupling of the first circuit component and the second circuit component is maintained when the deformable substrate is subjected to at least 100% strain.

Reference will now be made in detail to embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, components, circuits, and networks have not been described in detail so as not to unnecessarily obscure aspects of the embodiments.

Plural instances may be provided for components, operations or structures described herein as a single instance. Finally, boundaries between various components, operations, and data stores are somewhat arbitrary, and particular operations are illustrated in the context of specific illustrative configurations. Other forms of functionality are envisioned and may fall within the scope of the implementation(s). In general, structures and functionality presented as separate components in the example configurations may be implemented as a combined structure or component. Similarly, structures and functionality presented as a single component may be implemented as separate components. These and other variations, modifications, additions, and improvements fall within the scope of the implementation(s).

It will also be understood that, although the terms “first,” “second,” etc. may be used herein to describe various elements, these elements should not be limited by these terms. These terms are only used to distinguish one element from another. For example, a first layer could be termed a second layer, and, similarly, a second layer could be termed a first layer, without departing from the scope of the present disclosure. The first layer and the layer are both layers, but they are not the same layer.

The terminology used herein is for the purpose of describing particular implementations only and is not intended to be limiting of the claims. As used in the description of the implementations and the appended claims, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The foregoing description included example systems, methods, techniques, instruction sequences, and computing machine program products that embody illustrative implementations. For purposes of explanation, numerous specific details are set forth in order to provide an understanding of various implementations of the inventive subject matter. It will be evident, however, to those skilled in the art that implementations of the inventive subject matter may be practiced without these specific details. In general, well-known instruction instances, protocols, structures, and techniques have not been shown in detail.

The foregoing description, for purpose of explanation, has been described with reference to specific implementations. However, the illustrative discussions below are not intended to be exhaustive or to limit the implementations to the precise forms disclosed. Many modifications and variations are possible in view of the above teachings. The implementations are chosen and described in order to best explain the principles and their practical applications, to thereby enable others skilled in the art to best utilize the implementations and various implementations with various modifications as are suited to the particular use contemplated.

In the interest of clarity, not all of the routine features of the implementations described herein are shown and described. It will be appreciated that, in the development of any such actual implementation, numerous implementation-specific decisions are made in order to achieve the designer's specific goals, such as compliance with use case constraints, and that these specific goals will vary from one implementation to another and from one designer to another. Moreover, it will be appreciated that such a design effort might be complex and time-consuming, but nevertheless be a routine undertaking of engineering for those of ordering skill in the art having the benefit of the present disclosure.

For convenience in explanation and accurate definition in the appended claims, the terms “upper,” “lower,” “up,” “down,” “upwards,” “downwards,” “laterally,” “longitudinally,” “inner,” “outer,” “inside,” “outside,” “inwardly,” “outwardly,” “interior,” “exterior,” “front,” “rear,” “back,” “forwards,” and “backwards” are used to describe features of the exemplary embodiments with reference to the positions of such features as displayed in the figures.

Furthermore, when a reference number is given an “i^{th}” denotation, the reference number refers to a generic component, set, or embodiment. For instance, a circuit component “circuit component i” refers to the i^{th} circuit component in a plurality of circuit components (e.g., a circuit component 330-i in a plurality of circuit components 330).

As used herein, the term “mil” means a thousandth of an inch.

As used herein, the term “about” or “approximately” can mean within an acceptable error range for the particular value as determined by one of ordinary skill in the art, which can depend in part on how the value is measured or determined, e.g., the limitations of the measurement system. For example, “about” can mean within 1 or more than 1 standard deviation, per the practice in the art. “About” can mean a range of ±20%, ±10%, ±5%, or ±1% of a given value. Where particular values are described in the application and claims, unless otherwise stated, the term “about” means within an acceptable error range for the particular value. The term “about” can have the meaning as commonly understood by one of ordinary skill in the art. The term “about” can refer to ±10%. The term “about” can refer to ±5%.

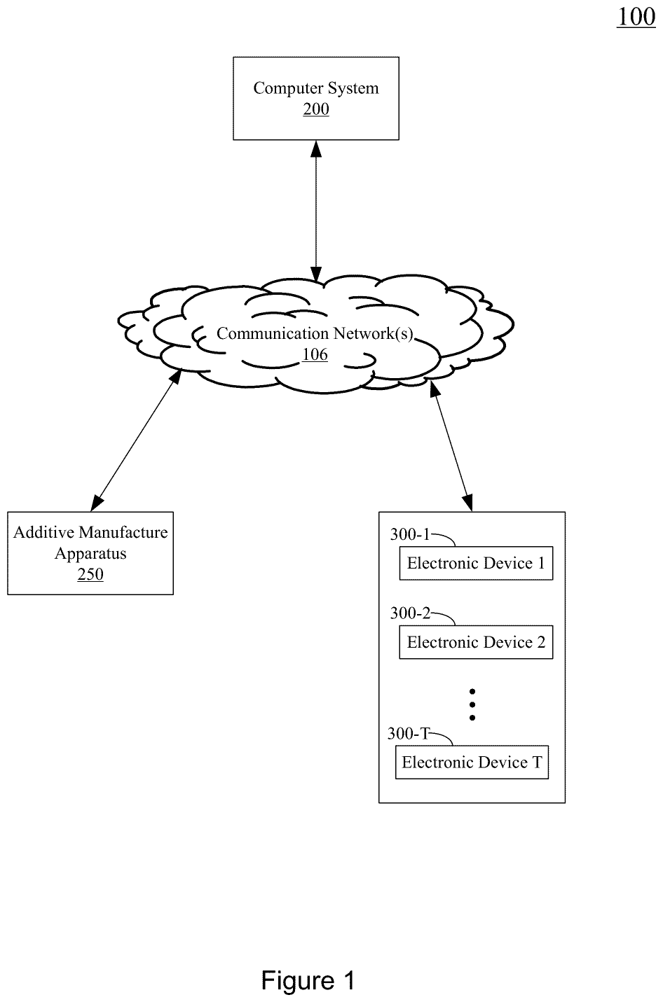

In the present disclosure, unless expressly stated otherwise, descriptions of devices and systems will include implementations of one or more computers. For instance, and for purposes of illustration in FIG. 1, a computer system 200 is represented as single device that includes all the functionality of the computer system 200. However, the present disclosure is not limited thereto. For instance, the functionality of the computer system 200 may be spread across any number of networked computers and/or reside on each of several networked computers and/or by hosted on one or more virtual machines and/or containers at a remote location accessible across a communications network (e.g., communication networks 106). One skilled in the art of the present disclosure will appreciate that a wide array of different computer topologies is possible for the computer system 200, and other devices and systems of the preset disclosure, and that all such topologies are within the scope of the present disclosure.

In general, the present disclosure provides systems, methods, and devices for producing interconnects that utilize a composition. In some embodiments, the systems, methods, and devices of the present disclosure provide interconnects, such as one or more line interconnects and/or one or more via interconnects, that interface with a liquid metal material and/or a circuit component of a circuit.

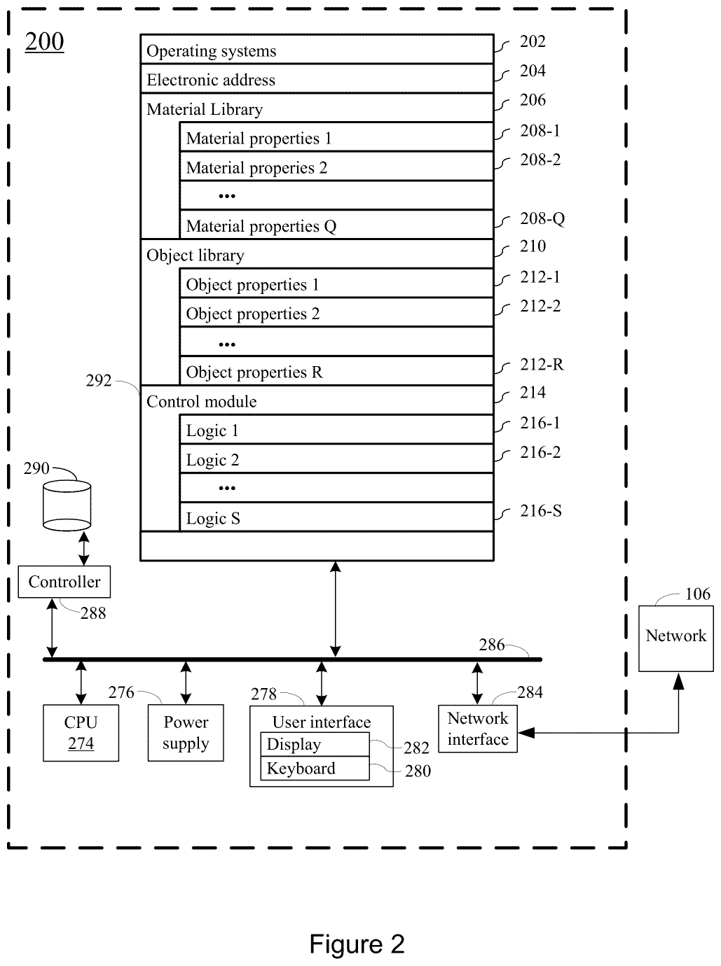

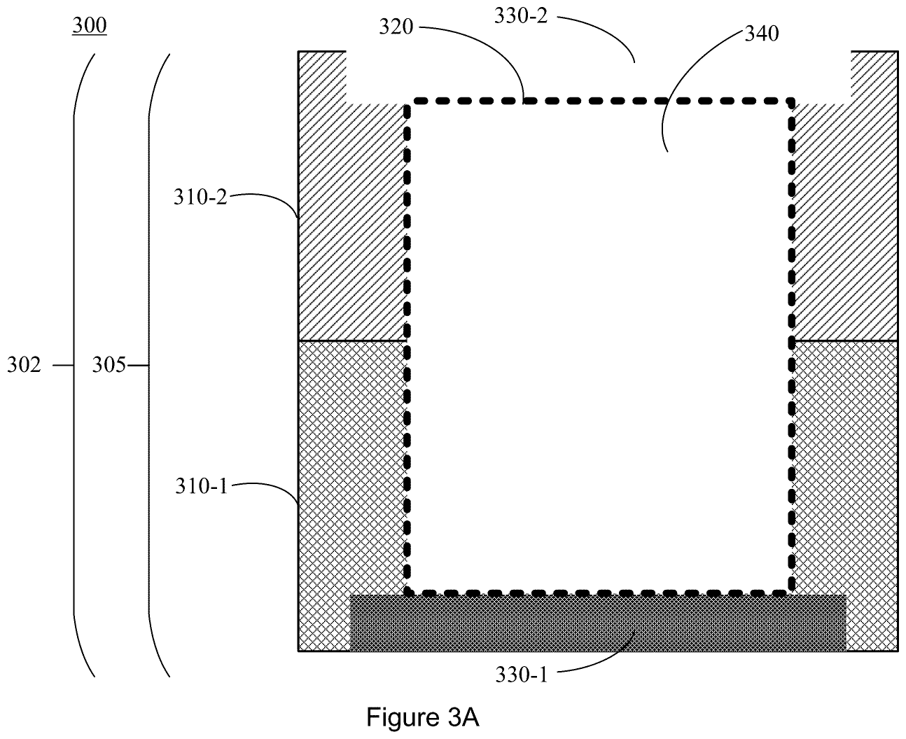

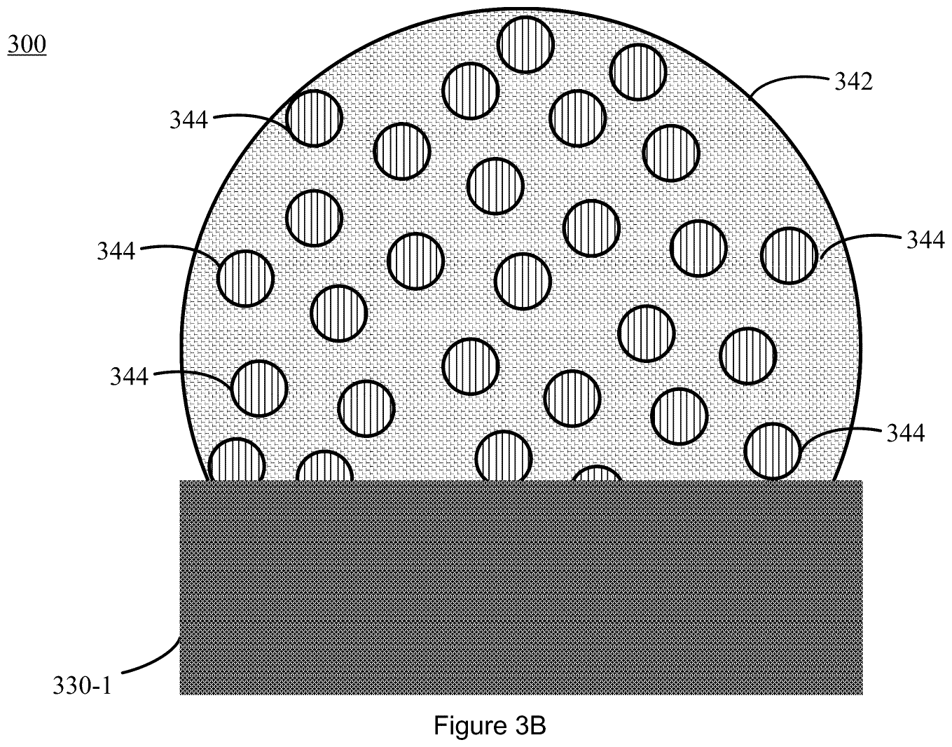

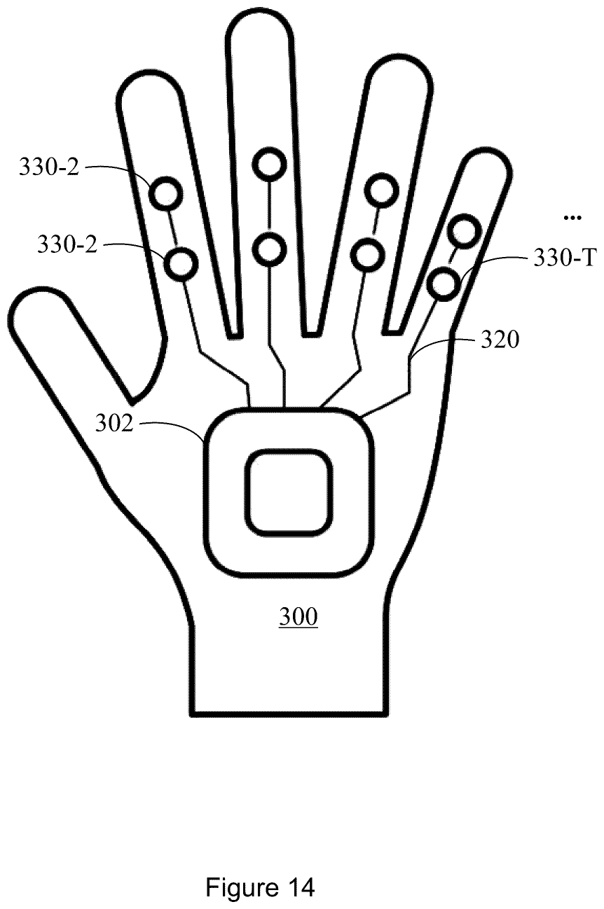

Referring to FIGS. 1, 2, 3A, and 3B, a system for producing an interconnect is provided. More specifically, FIG. 1 depicts a block diagram of a distributed additive manufacture system (e.g., distributed additive manufacture system 100) according to some embodiments of the present disclosure. In some embodiments, the system 100 facilitates the manufacture, at least in part, of an electronic device (e.g., electronic device 300-1 of FIG. 1, electronic device 300 of FIG. 3A, electronic device 300 of FIG. 3B, electronic device 300 of FIG. 14, etc.) at a computer system (e.g., computer system 200 of FIG. 1, computer system 200 of FIG. 2, etc.).

Of course, other topologies of the system 100 are possible. For instance, in some embodiments, any of the illustrated devices and systems can in fact constitute several computer systems that are linked together in a network or be a virtual machine and/or container in a cloud-computing environment. Moreover, rather than relying on a physical communication network 106, the illustrated devices and systems may wirelessly transmit information between each other. As such, the exemplary topology shown in FIG. 1 merely serves to describe the features of an embodiment of the present disclosure in a manner that will be readily understood to one skilled in the art.

Referring to FIG. 1, in some embodiments, a distributed additive manufacture system 100 includes a computer system 200 that facilitates manufacture of an electronic device 300 in response to one or more instructions for manufacturing the electronic device 300. In some embodiments, the computer system 200 and an additive manufacture apparatus (e.g., additive manufacture apparatus 250 of FIG. 1, etc.) are in a single monolithic casing without a communication network 106. In other embodiments, the computer system 200 and the additive manufacture apparatus 250 are separated by some distance and are in electrical communication with each other over the communication network as illustrated in FIG. 1.

In some embodiments, the communication networks 106 optionally includes the Internet, one or more local area networks (LANs), one or more wide area networks (WANs), other types of networks, or a combination of such networks.

Examples of communication networks 106 include the World Wide Web (WWW), an intranet and/or a wireless network, such as a cellular telephone network, a wireless local area network (LAN) and/or a metropolitan area network (MAN), and other devices by wireless communication. The wireless communication optionally uses any of a plurality of communications standards, protocols and technologies, including Global System for Mobile Communications (GSM), Enhanced Data GSM Environment (EDGE), high-speed downlink packet access (HSDPA), high-speed uplink packet access (HSUPA), Evolution, Data-Only (EV-DO), HSPA, HSPA+, Dual-Cell HSPA (DC-HSPDA), long term evolution (LTE), near field communication (NFC), wideband code division multiple access (W-CDMA), code division multiple access (CDMA), time division multiple access (TDMA), Bluetooth, Wireless Fidelity (Wi-Fi) (e.g., IEEE 802.11a, IEEE 802.11ac, IEEE 802.11ax, IEEE 802.11b, IEEE 802.11g and/or IEEE 802.11n), voice over Internet Protocol (VoIP), Wi-MAX, a protocol for e-mail (e.g., Internet message access protocol (IMAP) and/or post office protocol (POP)), instant messaging (e.g., extensible messaging and presence protocol (XMPP), Session Initiation Protocol for Instant Messaging and Presence Leveraging Extensions (SIMPLE), Instant Messaging and Presence Service (IMPS)), and/or Short Message Service (SMS), or any other suitable communication protocol, including communication protocols not yet developed as of the filing date of this document.

Now that a distributed additive manufacture system 100 has generally been described, an exemplary computer system 200 for controlling an additive manufacture apparatus 250 by providing one or more instructions, such as one or more non-transitory logics, for manufacture of an electronic device 300 will be described with reference to FIG. 2.

In various embodiments, the computer system 200 includes one or more processing units (CPUs) 274, a network or other communications interface 284, and memory 292.

The memory 292 includes high-speed random-access memory, such as DRAM, SRAM, DDR RAM, or other random access solid state memory devices, and optionally also includes non-volatile memory, such as one or more magnetic disk storage devices, optical disk storage devices, flash memory devices, or other non-volatile solid state storage devices. The memory 292 may optionally include one or more storage devices remotely located from the CPU(s) 274. The memory 292, or alternatively the non-volatile memory device(s) within memory 292, includes a non-transitory computer readable storage medium. Access to memory 292 by other components of the computer system 200, such as the CPU(s) 274, is, optionally, controlled by a controller. In some embodiments, the memory 292 can include mass storage that is remotely located with respect to the CPU(s) 274. In other words, some data stored in the memory 292 may in fact be hosted on devices that are external to the computer system 200, but that can be electronically accessed by the computer system 200 over an Internet, intranet, or other form of communication network 106 or electronic cable using communication interface 284.

In some embodiments, the memory 292 of the computer system 200 for controlling an additive manufacture apparatus 250 to manufacture an electronic device 300 stores:
an optional operating system 202 (e.g., ANDROID, iOS, DARWIN, RTXC, LINUX, UNIX, OS X, WINDOWS, or an embedded operating system such as VxWorks) that includes procedures for handling various basic system services;
an electronic address 204 associated with the computer system 200 that identifies the computer system 200;
a material library 206 that stores a plurality of material properties 208 associated with a corresponding material that is utilized by the additive manufacture apparatus 250;
an object library 210 that stores a plurality of object properties 212 for manufacturing a corresponding object, such as a circuit and/or a circuit component at the additive manufacture apparatus 250; and
a control module 214 that stores one or more non-transitory logics 216 that instruct a control of a manufacture the corresponding object at the additive manufacture apparatus 250.

In some embodiments, an electronic address 204 is associated with the computer system 200. The electronic address 204 is utilized to identify the computer system 200 at least uniquely from other devices and components of the distributed additive manufacture system 100 (e.g., uniquely identify computer system 200 from additive manufacture apparatus 250 of FIG. 1).

In some embodiments, a material library 206 is configured to store at least a plurality of materials properties 208 that is associated with a corresponding material (e.g., first plurality of material properties 208-1 is associated with a corresponding first material, second plurality of material properties 208-2 is associated with a corresponding second material, etc.). Each corresponding material associated with a respective plurality of material properties 208 is found at or produced by the additive manufacture apparatus 250. For instance, in some embodiments, the corresponding material associated with the plurality of material properties 208 is the resin 325 accommodated by the resin enclosure of the additive manufacture apparatus 250. In some embodiments, the corresponding material associated with the plurality of material properties 208 is a media 375 of the additive manufacture apparatus 250. Moreover, in some embodiments, the corresponding material associated with the plurality of material properties 208 is a material of the resin enclosure or a different component of the 3D printer system (e.g., outer glass container, temperature control system, etc.). For instance, in some such embodiments, the corresponding material associated with the plurality of material properties 208 is a coolant of the additive manufacture apparatus 250.

In some embodiments, a respective material property 208 in the plurality of material properties 208 is associated with a physical property of the corresponding material. As a non-limiting example, in some such embodiments, the physical property of the corresponding material associated with the respective material property is a first model of a phase diagram of the corresponding material that includes an evaluation of a boiling point of the corresponding material, an evaluation of a melting point of the corresponding material, an evaluation of a critical point of the corresponding material, an evaluation of a supercritical fluidic phase region of the corresponding material, an evaluation of a glass transition temperature, or a combination thereof. As another non-limiting example, in some embodiments, the physical property of the corresponding material associated with the respective material property 208 is a second model of a viscosity of the corresponding material, a third model of an index of refraction of the corresponding material, a fourth model of an evaluation of a depth of curing of the corresponding material volumetric shrinkage of the corresponding material, a fifth model of a flexural strength of the corresponding material, or a combination thereof. In some embodiments, the physical property of the corresponding material is a thermal property, such as a sixth model of a thermal conductivity of the corresponding material, a seventh model of a thermal diffusivity of the corresponding material, an eight model of a specific heat capacity, a ninth model of a thermal effusivity of the corresponding model, a tenth model of a material density of the corresponding material, an eleventh model of a conductivity of the corresponding material, or a combination thereof.

In some embodiments, from the plurality of material properties 208 associated with the physical property of the corresponding material, a manufacture of an object, such as an interconnect of the present disclosure, is dynamically modifiable based on one or more material properties in the plurality of material properties 208, such as by changing a mass of the material deposited by an additive manufacture apparatus 250 when manufacturing the object.

For instance, in some embodiments, the respective material property in the plurality of material properties 208 is associated with the supply of the corresponding material at an additive manufacture apparatus 250, such as the amount (e.g., a weight, a volume, a mass flow rate, etc.) of a reservoir of the corresponding material at the additive manufacture apparatus 250. One skilled in the art of the present disclosure will appreciate that a wide domain of material properties 208 are applicable to the systems, methods, and devices of the present disclosure.

In some embodiments, the plurality of material properties 208 stored by the material library 206 includes between 5 material properties and 10,000 material properties, between 5 material properties and 5,000 material properties, between 5 material properties and 1,000 material properties, between 5 material properties and 700 material properties, between 5 material properties and 500 material properties, between 5 material properties and 400 material properties, between 5 material properties and 100 material properties, between 50 material properties and 10,000 material properties, between 50 material properties and 5,000 material properties, between 50 material properties and 1,000 material properties, between 50 material properties and 700 material properties, between 50 material properties and 500 material properties, between 50 material properties and 400 material properties, between 50 material properties and 100 material properties, between 350 material properties and 10,000 material properties, between 350 material properties and 5,000 material properties, between 350 material properties and 1,000 material properties, between 350 material properties and 700 material properties, between 350 material properties and 500 material properties, between 350 material properties and 400 material properties, between 1,250 material properties and 10,000 material properties, between 1,250 material properties and 5,000 material properties, or between 6,250 material properties and 10,000 material properties. In some embodiments, the plurality of material properties 208 stored by the material library 206 includes at least 5 material properties, at least 20 material properties, at least 50 material properties, at least 200 material properties, at least 500 material properties, at least 1,000 material properties, at least 3,000 material properties, at least 8,000 material properties, or at least 10,000 material properties. In some embodiments, the plurality of materials properties 208 stored by the material library 206 includes at most 5 material properties, at most 20 material properties, at most 50 material properties, at most 200 material properties, at most 500 material properties, at most 1,000 material properties, at most 3,000 material properties, at most 8,000 material properties, or at most 10,000 material properties.

Additional details and information regarding certain material properties is found at Standard Handbook for Mechanical Engineers, twelfth edition, 2018, McGraw-Hill, Inc, print, which is hereby incorporated by reference in its entirety for all purposes.

In some embodiments, the object library 210 is configured to store at least a plurality of object properties 212 that is associated with a corresponding object (e.g., first plurality of object properties 212-1 is associated with a corresponding first object, second plurality of material properties 212-2 is associated with a corresponding second object, etc.). In some embodiments, a respective object property 212 in the plurality of object properties 212 includes a set of non-transitory instructions for manufacturing the corresponding object at an additive manufacture apparatus 250 by way of one or more additive manufacturing techniques. For instance, in some embodiments, the first object property in a first plurality of object properties 212-1 includes a first set of non-transitory instructions for manufacturing a corresponding second object at a direct writing additive manufacture apparatus 250, the second object property in the first plurality of object properties 212-1 includes a second set of non-transitory instructions for manufacturing the corresponding second object at a screen printing additive manufacture apparatus 250, and the like.

In some embodiments, the plurality of object properties 212 stored by the object library 210 includes between 5 object properties and 10,000 object properties, between 5 object properties and 5,000 object properties, between 5 object properties and 1,000 object properties, between 5 object properties and 700 object properties, between 5 object properties and 500 object properties, between 5 object properties and 400 object properties, between 5 object properties and 100 object properties, between 50 object properties and 10,000 object properties, between 50 object properties and 5,000 object properties, between 50 object properties and 1,000 object properties, between 50 object properties and 700 object properties, between 50 object properties and 500 object properties, between 50 object properties and 400 object properties, between 50 object properties and 100 object properties, between 350 object properties and 10,000 object properties, between 350 object properties and 5,000 object properties, between 350 object properties and 1,000 object properties, between 350 object properties and 700 object properties, between 350 object properties and 500 object properties, between 350 object properties and 400 object properties, between 1,250 object properties and 10,000 object properties, between 1,250 object properties and 5,000 object properties, or between 6,250 object properties and 10,000 object properties. In some embodiments, the plurality of materials properties 208 stored by the material library 206 includes at least 5 object properties, at least 20 object properties, at least 50 object properties, at least 200 object properties, at least 500 object properties, at least 1,000 object properties, at least 3,000 object properties, at least 8,000 object properties, or at least 10,000 object properties. In some embodiments, the plurality of materials properties 208 stored by the material library 206 includes at most 5 object properties, at most 20 object properties, at most 50 object properties, at most 200 object properties, at most 500 object properties, at most 1,000 object properties, at most 3,000 object properties, at most 8,000 object properties, or at most 10,000 object properties.

In some embodiments, the control module 214 stores one or more non-transitory logics 216 (e.g., first non-transitory logic 216-1, second non-transitory logic 216-2, . . . , non-transitory logic S 216-S of FIG. 2). In some embodiments, each of the non-transitory logics 216 is configured to control an aspect of an additive manufacture apparatus 250 by one or more instructions for the additive manufacture apparatus 250. For instance, in some embodiments, a respective non-transitory logic 216 includes one or more instructions to modify a flow rate of a material disposed (e.g., extruded) by the additive manufacture apparatus 250, and the like. As another non-limiting example, in some embodiments, a respective non-transitory logic 216 is configured to switch the power state of a computer system 200, such as the respective powered state (e.g., switch to/from a powered state, an unpowered stated, etc.) of a power supply of an additive manufacture apparatus associated with the computer system 200 (e.g., a 3D printer system, etc.), the respective powered state of a temperature control system of the additive manufacture apparatus 250, or a combination thereof.

In some embodiments, the object library 210 is subsumed by, or in communication with, the control module 214. For instance, in some embodiments, the non-transitory logic 216 of the control module 214 includes a geometric slicer for translating slicing a corresponding object for manufacture at an additive manufacture apparatus 250.

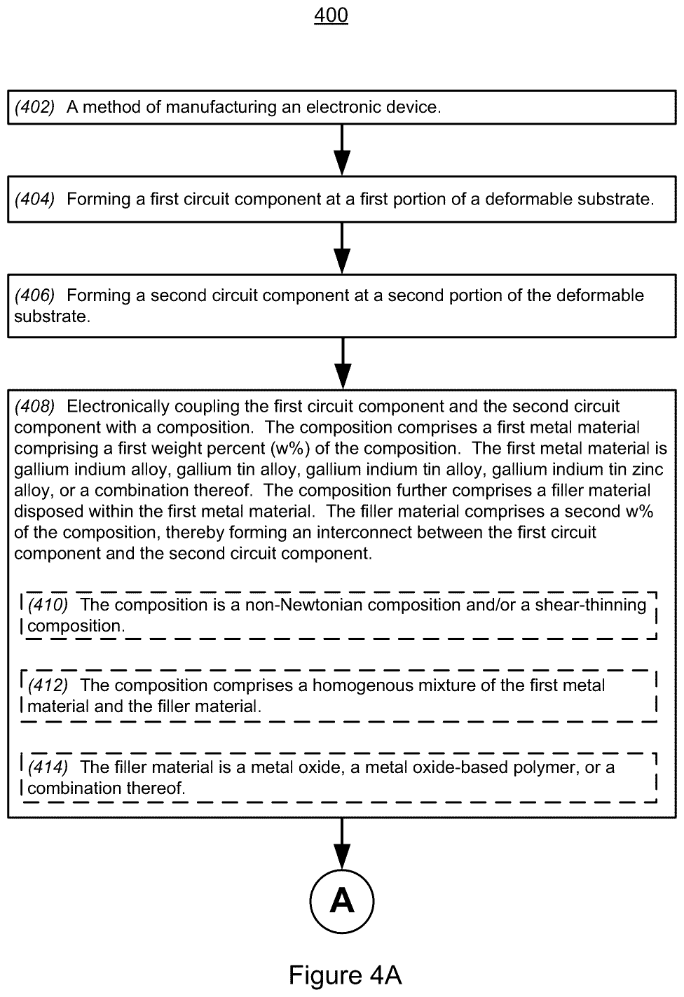

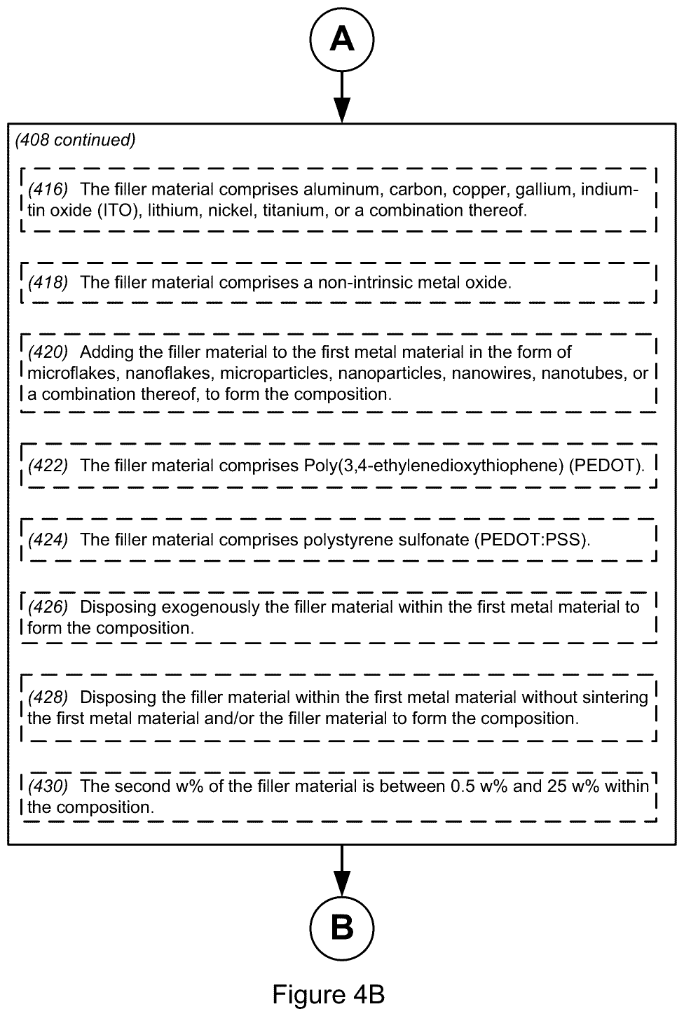

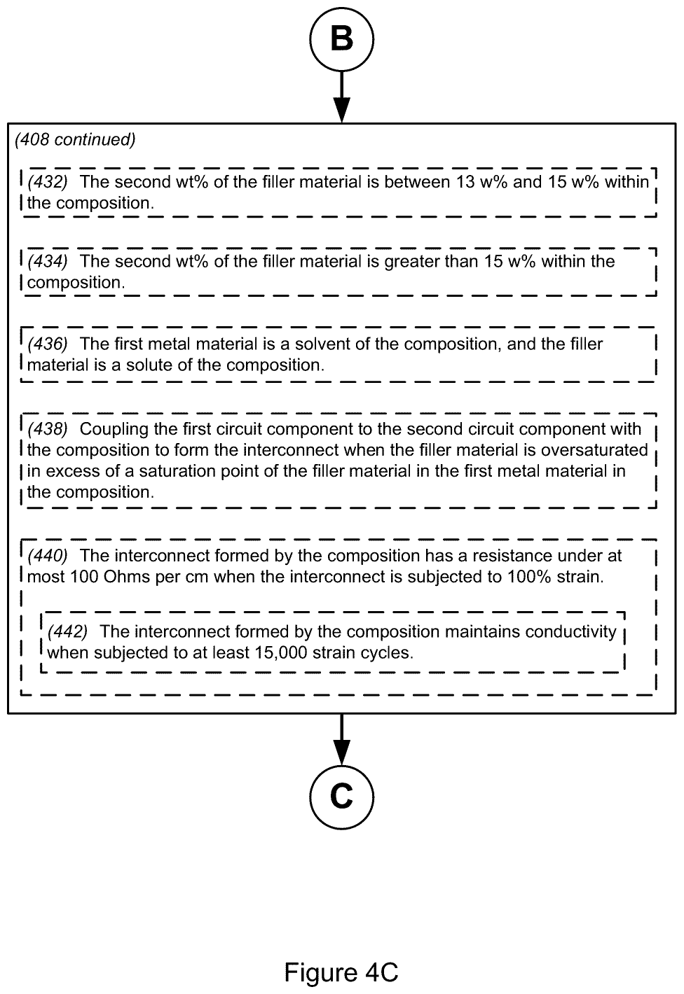

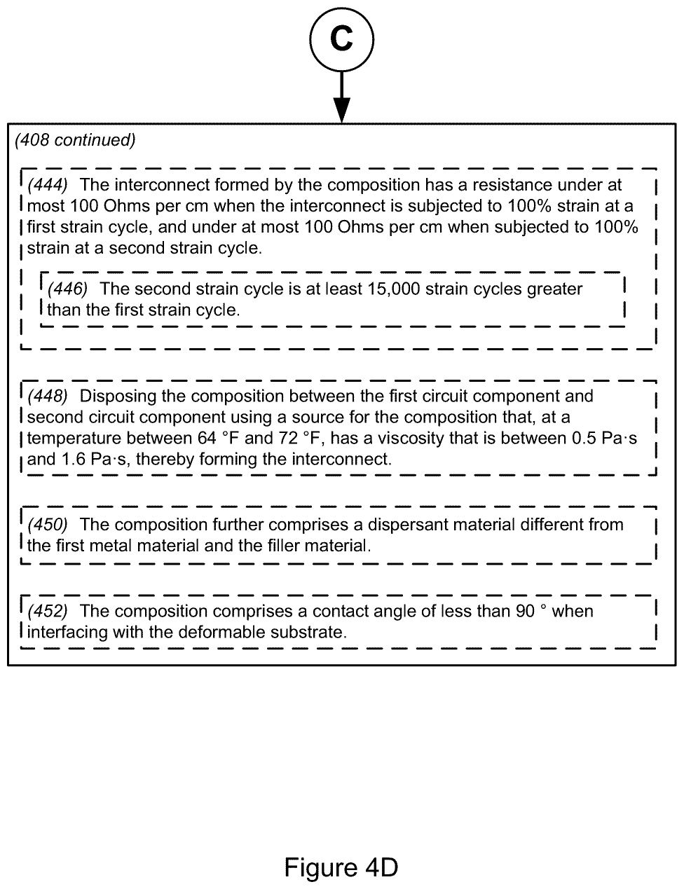

Each of the above identified modules and applications correspond to a set of executable instructions for performing one or more functions described above and the methods described in the present disclosure (e.g., the computer-implemented methods and other information processing methods described herein; method 400 of FIGS. 4A through 4D; etc.). These modules (e.g., sets of instructions) need not be implemented as separate software programs, procedures or modules, and thus various subsets of these modules are, optionally, combined or otherwise re-arranged in various embodiments of the present disclosure. In some embodiments, the memory 292 optionally stores a subset of the modules and data structures identified above. Furthermore, in some embodiments, the memory 292 stores additional modules and data structures not described above.

It should be appreciated that the computer system 200 of FIG. 2 is only one example of a computer system 200, and that the computer system 200 optionally has more or fewer components than shown, optionally combines two or more components, or optionally has a different configuration or arrangement of the components. The various components shown in FIG. 2 are implemented in hardware, software, firmware, or a combination thereof, including one or more signal processing and/or application specific integrated circuits.

Referring to FIGS. 3A and 3B, an electronic device (e.g., electronic device 300 of FIG. 1, electronic device 300 of FIG. 3A, electronic device 300 of method 400 of FIGS. 4A through 4D, electronic device 300 of FIG. 14, etc.) in accordance with some embodiments with some embodiments of the present disclosure is provided. Moreover, referring briefly to FIG. 28, in some embodiments, the electronic device 300 is a garment that is worn by a subject, such as around a wrist, a hand, a finger, or a combination thereof of the subject. However, the present disclosure is not limited thereto.

In some embodiments, the electronic device 300 is a display device. For instance, in some embodiments, the electronic device is a head-mounted display device (e.g., a heads-up display (HUD)). However, the present disclosure is not limited thereto.

The electronic device 300 includes a deformable substrate (e.g., deformable substrate 302 of FIG. 3A, etc.). In some embodiments, the deformable substrate 302 includes a supporting material upon which or within which an object (e.g., an electronic circuit 305) is fabricated or attached to or is on. In some embodiments, the deformable substrate 302 or a portion of the deformable substrate 302 is processed (e.g., patterned) during manufacture of the object. In some embodiments, the deformable substrate 302 remains substantially unchanged when the object is formed upon or within the deformable substrate 302.

The deformable substrate 302 includes a planar surface, a substantially planar surface, a curved surface, a round surface (e.g., an edge having a radius of curvature greater than zero), one or more sharp edges, or any combination thereof.

In some embodiments, the deformable substrate 302 is rigid or flexible, stretchable or non-stretchable, thick or thin (e.g., in form of a sheet or a film), removable (e.g., the substrate functions as a sacrificial layer that can be at least partially removed when desired or needed) or non-removable, or any combination thereof. In some embodiments, the deformable substrate is a monolayer.

As used herein, the term “deformable substrate” refers to a substrate or a portion of it (e.g., a layer) capable of altering its shape subject to pressure or stress.

For instance, in some embodiments, the substrate or at least a portion of it is flexible, bendable, stretchable, inflatable, or the like. For instance, in some embodiments, the deformable substrate or at least a portion of it (e.g., a layer) is made with a material having a Young's Modulus lower than about 0.5, lower than about 0.4 Gpa, lower than about 0.3 Gpa, or lower than about 0.2 Gpa. Such a material allows the substrate or a portion of it to deform (e.g., bend, stretch or the like) under pressure or strain. In some embodiments, the deformable substrate 302 or at least a portion of it is made of a material having Young's Modulus lower than about 0.1 Gpa to provide enhanced flexibility and tackability (e.g., a function of viscosity and concentration, etc.). Examples of materials with low Young's Modulus include, but are not limited to elastomeric materials, viscoelastic polymeric materials, synthetic resins having low sliding performance, high corrosion resistance and high strength, such as silicone, medical grade polyurethane, polyethylene terephthalate (PET), polyimide (PI), polyphenylene sulfide (PPS) or fluorine-containing resin.

In some embodiments, the deformable substrate 302 includes a layer or a portion made of a relatively rigid material. For instance, in some embodiments, the deformable substrate includes a layer or a portion made of a material having Young's Modulus higher than about 0.5 Gpa, higher than about 1.0 Gpa, higher than about 2.0 Gpa, higher than about 3.0 Gpa, higher than 4.0 Gpa, or higher than about 5.0 Gpa. Examples of materials with relatively higher Young's Modulus include, but are not limited to, polyethylene, PEEK, polyester, aramid, composite, glass epoxy, and polyethylene naphalate.

The deformable substrate 302 includes a circuit (e.g., circuit 305 of FIG. 3A, circuit 305 of FIG. 3B, etc.). In some embodiments, the circuit 305 includes a printed circuit board (PCB). For instance, in some embodiments, the circuit 305 includes a flexible printed circuit (FPC). By utilizing the FPC with the circuit 305, the electronic device 300 of the present disclosure is provided with improved durability since substantially all of the electronic device 300 is formed of or on a deformable material. However, the present disclosure is not limited thereto.

In some embodiments, the circuit 305 includes a plurality of layers (e.g., first layer 310-1 of circuit 305, second layer 310-2 of circuit 305, third layer 310-3 of circuit 305, etc.), which yields a multilayer circuit 305. For instance, in some embodiments, the circuit 305 includes between 1 layer and 10 layers, between 1 layer and 8 layers, between 1 layer and 6 layers, between 1 layer and 4 layers, between 1 layer and 3 layers, between 1 layer and 2 layers, between 2 layers and 10 layers, between 2 layers and 8 layers, between 2 layers and 6 layers, between 2 layers and 4 layers, between 2 layers and 3 layers, between 3 layers and 10 layers, between 3 layers and 8 layers, between 3 layers and 6 layers, between 3 layers and 4 layers, between 4 layers and 10 layers, between 4 layers and 8 layers, between 4 layers and 6 layers, between 5 layers and 10 layers, between 5 layers and 8 layers, between 5 layers and 6 layers, between 6 layers and 10 layers, between 6 layers and 8 layers, between 7 layers and 10 layers, between 7 layers and 8 layers, between 8 layers and 10 layers, or between 9 layers and 10 layers. In some embodiments, the circuit 305 includes at least 1 layer, at least 2 layers, at least 3 layers, at least 4 layers, at least 5 layers, at least 6 layers, at least 7 layers, at least 8 layers, at least 9 layers, or at least 10 layers. In some embodiments, the circuit 305 includes at most 1 layer, at most 2 layers, at most 3 layers, at most 4 layers, at most 5 layers, at most 6 layers, at most 7 layers, at most 8 layers, at most 9 layers, or at most 10 layers. For instance, in some embodiments, the circuit 305 includes a deformable first layer 310-1 and a rigid second layer 310-2. As a non-limiting example, in some embodiments, the deformable first layer 310-1 is configured to operate in an elastic deformation region of a first material of the deformable first layer 310-1 when a force is applied to the circuit, and the rigid second layer 310-2 is configured to operate in a plastic deformation region of a second material of the rigid second layer 310-2 when the force is applied to the circuit. However, the present disclosure is not limited thereto.

In some embodiments, the one or more layers 310 of circuit 305 and the deformable substrate 302 have a one-to-one relationship, such that each layer of the circuit 305 is a layer of the deformable substrate 302. However, the present disclosure is not limited thereto. For instance, in some embodiments, the one or more layers 310 of circuit 305 and the deformable substrate 302 have a many-to-one relationship, such as two or more layers 310 of circuit 305 formed on a single layer of the deformable substrate 302 (e.g., first layer 310-1 of circuit 305 formed on a first surface of a first layer of deformable substrate 302 and a first layer 310-2 of circuit 305 formed of a second surface of the first layer of the deformable substrate 302, in which the second surface is opposite the first surface).

Moreover, in some embodiments, the circuit 305 includes a channel (e.g., channel 320 of FIG. 3A). In some embodiments, the channel 320 extends from a first portion of the deformable substrate 302 to a second portion of the deformable substrate 302. For instance, in some embodiments, the circuit 305 includes at least two layers 310 including a first layer 310-1 and a second layer 310-2. In some embodiments, the circuit 305 includes at least three layers 310 including the first layer 310-1, the second layer 310-2, and a third layer 310-3. However, the present disclosure is not limited thereto.

In some embodiments, the first layer 310-1 includes the first portion of the deformable substrate 302. Moreover, the second layer 310-2 includes the second portion of the deformable substrate 302. Accordingly, in some embodiments, the channel 320 extends from a first terminal of the first layer 310-1 to a second terminal of the second layer 310-2. Accordingly, the channel 320 of the circuit 305 extends through at least two layers 310 of the circuit 305, which allows for providing electrical communication between the at least two layers 310. Said otherwise, in some embodiments, the channel 320 is, or forms, a via interconnect of the circuit 305 providing electrical communication between one or more circuit components of the first layer 310-1 and one or more circuit components of the second layer 310-2 of the circuit 305. However, the present disclosure is not limited thereto.

In some embodiments, the first portion of the deformable substrate 302 and the second portion of the deformable substrate 302 form part of a planar surface of the deformable substrate 302. For instance, in some embodiments, the channel 320 is a line interconnect utilized to provide electrical communication between one or more circuit components at the first portion of the planar surface of the deformable substrate 302 and one or more circuit components of the second layer 310-2 at the second portion of the planar surface of the deformable substrate 302.

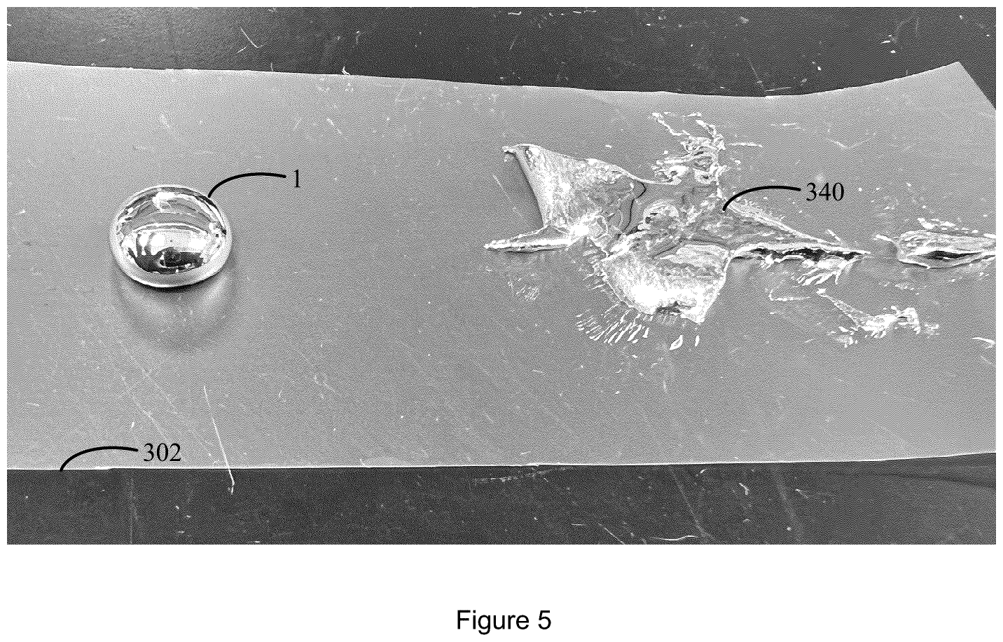

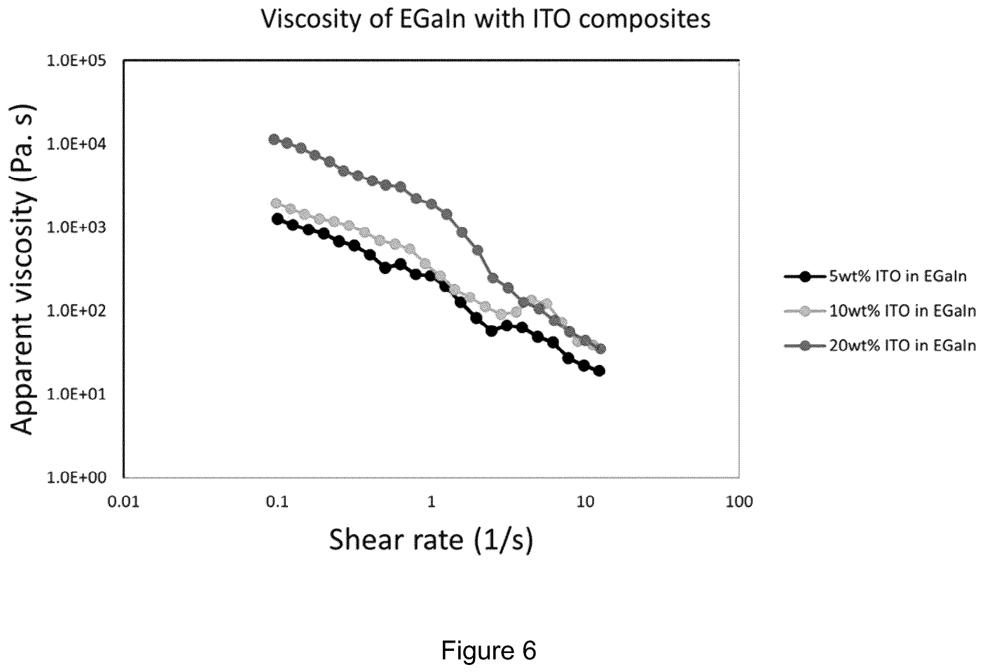

In some embodiments, the circuit 305 further includes two or more circuit components (e.g., first circuit component 330-1 of FIG. 3A, second circuit component 330-2 of FIG. 3A, first circuit component 330-1 of FIG. 3B, second circuit component 330-2 of FIG. 3B, first circuit component 330-1 of method 400, second circuit component 330-2 of method 400, first circuit component 330-1 of method 500, first circuit component 330-1 of FIG. 5A, first circuit component 330-1 of FIG. 5B, first circuit component 330-1 of FIG. 5C, first circuit component 330-1 of FIG. 5D, first circuit component 330-1 of FIG. 5E, first circuit component 330-1 of FIG. 5F first circuit component 330-1 of method 600, first circuit component 330-1 of FIG. 6A, first circuit component 330-1 of FIG. 6B, first circuit component 330-1 of FIG. 6C, first circuit component 330-1 of FIG. 6D, first circuit component 330-1 of method 700, second circuit component 330-2 of method 700, etc.). For instance, in some embodiments, a circuit component 330 of the circuit 305 includes a terminal, an energy source (e.g., power supply), an interconnect (e.g., a line interconnect, such as a wire), a load (e.g., a device, a sensor, etc.), a controller (e.g., switch), or a combination thereof. As a non-limiting example, in some embodiments, the circuit component 330 includes a terminal, a resistor, a transistor, a capacitor, an inductor, a transformer, a diode, a sensor, or a combination thereof. In some embodiments, the first circuit component 330-1 is the same type of component as the second circuit component 330-1 (e.g., both the first circuit component 330-1 and the second circuit component 330-2 include a load, both the first circuit component 330-1 and the second circuit component 330-2 include a conductor, etc.). However, the present disclosure is not limited thereto.

In some embodiments, the first circuit component 330-1 and the second circuit component 330-2 form part of an active-matrix array. For instance, in some embodiments, the first circuit component 330-1 or the second circuit component 330-2 is a transistor, an electrode, or a capacitor disposed on the deformable substrate 302, and the other of the first circuit component 330-1 or the second circuit component 330-2 is different from the transistor, the electrode, or the capacitor of the first circuit component 330-1 or the second circuit component 330-2.

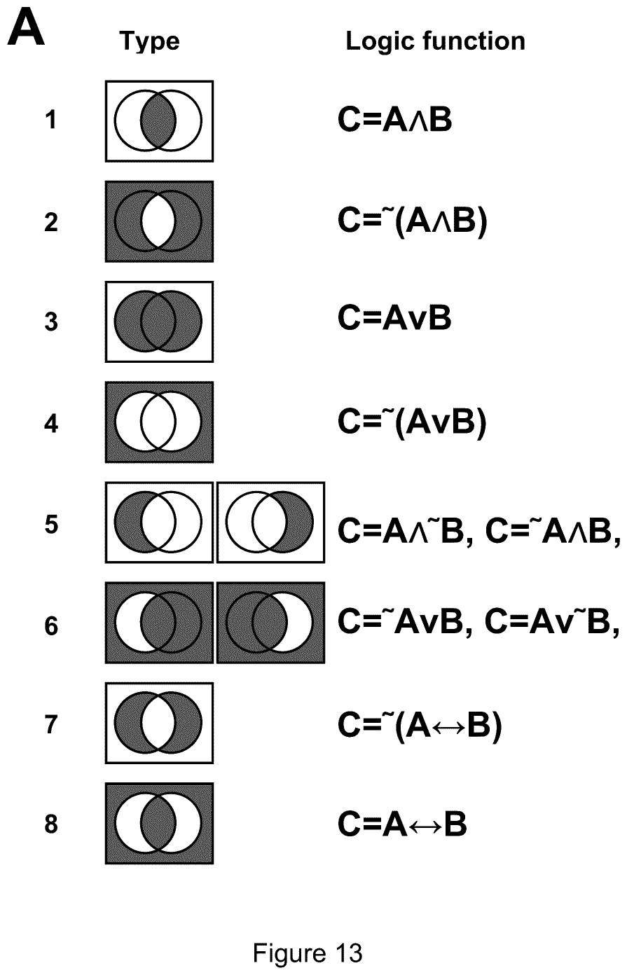

In some embodiments, the first circuit component 330-1 and the second circuit component 330-2 are part of a transistor switch. For instance, in some embodiments, the transistor switch is configured to control an electronical communication through the circuit 305 using a logic function, such as an OR logic function based on either a cutoff or saturation of the electronical communication. In some embodiments, two or more transistor switches are arranged (e.g., in series and/or parallel) in order to implement a logic function, such as one or more logic functions of FIG. 13.

In some embodiments, the circuit 305 includes between 2 and 10 million circuit components 330 (e.g., first circuit component 330-1, second circuit component 330-2, . . . , circuit component N 330-N), between 2 and 1 million circuit components 330, between 2 and 100,000 circuit components 330, between 2 and 10,000 circuit components 330, between 2 and 1,000 circuit components 330, between 2 and 100 circuit components 330, between 2 and 10 circuit components 330, between 5 and 10 million circuit components 330, between 5 and 1 million circuit components 330, between 5 and 100,000 circuit components 330, between 5 and 10,000 circuit components 330, between 5 and 1,000 circuit components 330, between 5 and 100 circuit components 330, between 5 and 10 circuit components 330, between 10 and 10 million circuit components 330 (e.g., first circuit component 330-1, second circuit component 330-10, . . . , circuit component N 330-N), between 10 and 1 million circuit components 330, between 10 and 100,000 circuit components 330, between 10 and 10,000 circuit components 330, between 10 and 1,000 circuit components 330, between 10 and 100 circuit components 330, between 500 and 10 million circuit components 330 (e.g., first circuit component 330-1, second circuit component 330-500, . . . , circuit component N 330-N), between 500 and 1 million circuit components 330, between 500 and 100,000 circuit components 330, between 500 and 10,000 circuit components 330, between 500 and 1,000 circuit components 330, between 5,000 and 10 million circuit components 330 (e.g., first circuit component 330-1, second circuit component 330-2, . . . , circuit component N 330-N), between 5,000 and 1 million circuit components 330, between 5,000 and 100,000 circuit components 330, or between 5,000 and 10,000 circuit components 330.

In some embodiments, the circuit 305 includes at least 2 circuit components 330, at least 3 circuit components 330, at least 5 circuit components 330, at least 10 circuit components 330, at least 50 circuit components 330, at least 100 circuit components 330, at least 500 circuit components 330, at least 1,000 circuit components 330, at least 5,000 circuit components 330, at least 10,000 circuit components 330, at least 25,000 circuit components 330, at least 40,000 circuit components 330, at least 100,000 circuit components 330, at least 250,000 circuit components 330, at least 500,000 circuit components 330, at least 1 million circuit components 330, at least 5 million circuit components 330, or at least 10 million circuit components 330. In some embodiments, the circuit 305 includes at most 2 circuit components 330, at most 3 circuit components 330, at most 5 circuit components 330, at most 10 circuit components 330, at most 50 circuit components 330, at most 100 circuit components 330, at most 500 circuit components 330, at most 1,000 circuit components 330, at most 5,000 circuit components 330, at most 10,000 circuit components 330, at most 25,000 circuit components 330, at most 40,000 circuit components 330, at most 100,000 circuit components 330, at most 250,000 circuit components 330, at most 500,000 circuit components 330, at most 1 million circuit components 330, at most 5 million circuit components 330, or at most 10 million circuit components 330.

In some embodiments, each respective circuit component 330 is disposed adjacent to, on, or within a corresponding portion of the deformable substrate 302. For instance, in some embodiments, the circuit 305 includes a first circuit component 330-1 that is disposed within a first portion of the deformable substrate 302. Moreover, in some embodiments, the circuit 305 includes a second circuit component 330-2 that is adjacent to, on, or within the second portion of the deformable substrate 302. Accordingly, the first portion and the second portion of the deformable substrate 302 and/or one or more layers between the first portion and the second portion of the deformable substrate 302, or any combination thereof (e.g., both the first and second portion of the deformable substrate as illustrated in FIG. 3A) include a gap, or span, that requires carrying electrical communication therethrough between the first circuit component 330-1 and the second circuit component 330-2.

Furthermore, the circuit 305 includes a first metal material (e.g., first metal material 342 of FIG. 3A, first metal material 342 of FIG. 3B, etc.). As a non-limiting example, in some embodiments, the first metal material 342 includes copper (Cu), gold (Au), silver (Ag), nickel (Ni), platinum (Pt), or any combination thereof, or any alloy thereof. Thus, in some embodiments, the first metal material 342 is utilized to wet a portion or surface of the circuit 305 in order to increase a wettability of the portion or surface of the circuit 305. Thus, the portion or surface of the circuit 305 is selectively wetted by the first metal material 342 based on a position of the first metal material 342 disposed on the surface. In some embodiments, a material wets a surface (e.g., surface of deformable substrate 302) when the adhesion of molecules of the material at the surface of the material is greater than the cohesion of the molecules at the interior of the material.

For instance, in some embodiments, the electronic device 300 includes the first circuit component 330-1 overlaying a first portion of the deformable substrate 302 (e.g., overlaying a first portion of the circuit 305). In some embodiments, the first portion of the deformable substrate 302 includes a first portion of the channel 320. In some embodiments, the first portion of the channel 320 includes an interior surface of the channel 320, an edge of the channel 320, a rim of the channel 320, a brim of the channel 320, or a combination thereof. Accordingly, by disposing the first circuit component 310-1 on the interior surface of the channel 320, the edge of the channel 320, the rim of the channel 320, the brim of the channel 320, or the combination thereof, a liquid metal material, such as a composition 340 of the present disclosure (e.g., second metal material 342 of FIG. 3B, etc.), is forced to wet throughout and/or to an opening of an interior volume of the channel 320, such as the first electronic component 310-1 underlying or accommodated by the channel 320.

In some embodiments, the at least two layers 310 of the circuit 305 further includes a third layer (e.g., third layer 310-3 of FIG. 3A, third layer 310-3 of FIG. 3B, etc.). In some embodiments, the third layer 310-3 is configured to overlay an opening of the channel 320, such as by covering a rim of the channel 320, an edge of the channel 320, or the like, in order to seal an end portion of the channel 320.

In some embodiments, the first circuit component 330-1 includes an exterior surface (e.g., exterior surface 332-1 of FIG. 3A, exterior surface 332-1 of FIG. 3B, exterior surface 332-1 of FIG. 5A, exterior surface 332-1 of FIG. 6A, etc.) that includes an electroless nickel immersion gold (ENIG). In some embodiments, the exterior surface 332 includes a top surface, a front surface, a side surface, a rear surface, a face, an edge, or a combination thereof of the first circuit component. In some embodiments, the exterior surface 332 of the first circuit component 330-1 includes tin (Sn) (e.g., immersion tin (ISn). In some embodiments, the exterior surface 332 of the first circuit component 330-1 includes an electroless nickel immersion silver (ENInAg).

Now that a general topology of the distributed additive manufacture system 100 has been described in accordance with various embodiments of the present disclosures, details regarding some processes in accordance with FIGS. 4A, 4B, 4C, and 4D will be described. Specifically, FIGS. 4A, 4B, 4C, and 4D illustrates a flow chart of methods (e.g., method 400) for forming a deformable electrical communication, in accordance with embodiments of the present disclosure.

Various modules in the memory 292 of the computer system 200 perform certain processes of the methods 400 described in FIGS. 4A, 4B, 4C, and 4D, unless expressly stated otherwise. Furthermore, it will be appreciated that the processes in FIGS. 4A, 4B, 4C, and 4D can be encoded in a single module or any combination of modules.

Block 402. Referring to block 402 of FIG. 4A, a method 400 of manufacturing an electronic device (e.g., electronic device 300 of FIG. 3A, electronic device 300 of FIG. 14, etc.).

In some embodiments, the method 400 is utilized to manufacture an entire electronic device 300, such that the electronic device manufactured by the method 400 is readily utilizable by and end-user. However, the present disclosure is not limited thereto. For instance, in some embodiments, the method 400 is utilized to manufacture a portion of the electronic device 300, such as one or more circuit components and/or one or more interconnects of the electronic device 300.

In some embodiments, the method 400 is performed at a computer system (e.g., computer system 200 of FIG. 2, additive manufacture apparatus 250 of FIG. 1). The computer system 200 includes one or more processors (e.g., CPU 274 of FIG. 2), and a first memory (e.g., memory 292 of FIG. 2) that is coupled to the one or more processors 274. The first memory 292 stores one or more programs (e.g., material library 206, object library 210, control module 214, or a combination thereof of FIG. 2) that is executed by the one or more processors 274. The one or more programs includes one or more instructions (e.g., block 404 of FIG. 4A, block 420 of FIG. 4B, block 432 of FIG. 4C, etc.) for performing the method 400.

As such, portions of the method 400 require a computer (e.g., computer system 200 of FIG. 2, additive manufacture apparatus 250 of FIG. 1) to be used because the considerations used by the systems, methods, and apparatuses of the present disclosure, on the scale performed by the systems, methods, and apparatuses of the present disclosure, cannot be mentally performed. In other words, the systems, methods, and apparatuses of the present disclosure have outputs that need to be determined using the computer rather than mentally in such embodiments.

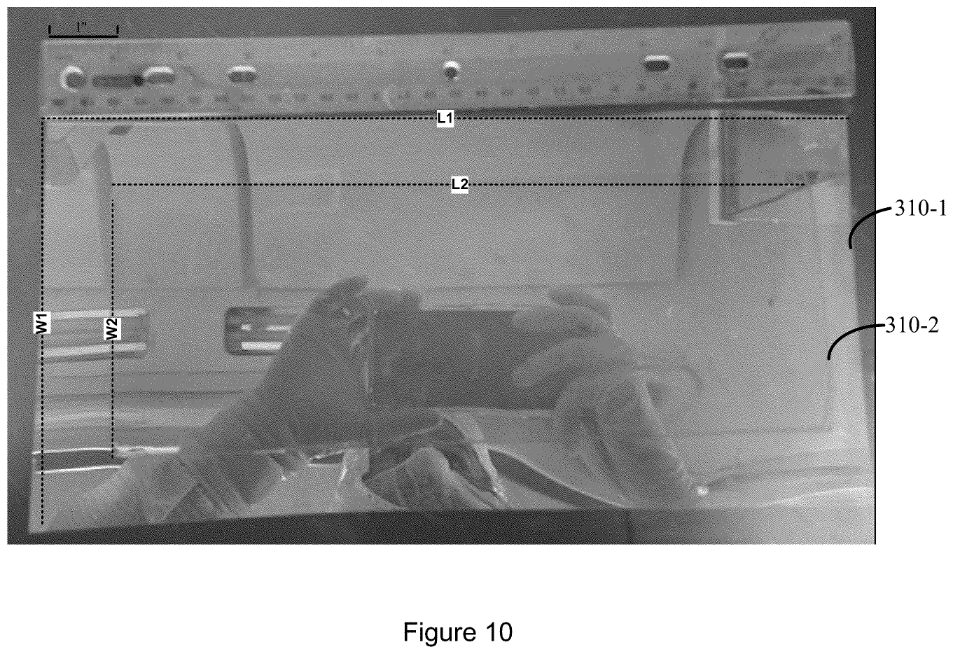

Block 404. Referring to block 404, the method 400 includes forming a first circuit component (e.g., first circuit component 330-1 of FIG. 3A). In some embodiments, the first circuit component 330-1 is formed at a first portion of a deformable substrate (e.g., deformable substrate 302 of FIG. 3A, deformable substrate 302 of FIG. 10, etc.).

In some embodiments, the deformable substrate 302 includes one or more materials selected from a variety of materials, including but not limited to silicon (Si), glass, plastic, or polymeric materials (e.g., a plastic film), fabric, synthetic paper, or the like. For instance, in some embodiments, the deformable substrate 302 is made of a semiconductor material (alone or together with other materials). Examples of semiconductor materials include, but are not limited to Si, metal oxide or gallium arsenide (GaAs). In some embodiments, the deformable substrate 302 serves as a foundation (e.g., platform, base, etc.) for manufacture of objects (e.g., one or more circuit components 330), such as transistors and integrated circuits (ICs). In some embodiments, the deformable substrate 302 is made of a polymeric material (e.g., alone, or together with other materials). Examples of polymeric materials include, but are not limited to polyester (PE), polycarbonate (PC), polyimide (PI), polyethylene terephthalate (PET), polyethylene naphthalate (PEN), Acrylic or Polymethyl Methacrylate (PMMA), Polypropylene (PP), Polyvinyl Chloride (PVC), Acrylonitrile-Butadiene-Styrene (ABS), or the like.

In some embodiments, a first layer 310-1 of the deformable substrate 302 includes polyethylene terephthalate (PET). In some embodiments, the first layer is loaded with nanoparticles of a first material, such as Au, Ag, Cu, Pt, palladium (Pd), or a combination thereof, or any alloy thereof.

In some embodiments, a second layer of the deformable substrate 302 is formed overlaying a portion of the first layer of the deformable substrate 302. In some embodiments, the second layer includes one or more polyorganosiloxanes, one or more fillers, one or more additives, or a combination thereof.

In some embodiments, the second layer of the deformable substrate 302 includes a silicon solvent. In some embodiments, the silicon solvent includes a first portion of hexamethyldisiloxane and a second portion of octamethyltrisiloxane.

In some embodiments, the second layer of the deformable substrate 302 includes 50 w % of the one or more polyorganosiloxanes, one or more fillers, one or more additives, or the combination thereof. In some embodiments, the deformable substrate 302 includes 50 w % of the first portion of hexamethyldisiloxane and the second portion of octamethyltrisiloxane.

Block 406. Referring to block 406, the method 400 includes forming a second circuit component (e.g., second circuit component 310-2 of FIG. 3A, etc.) at a second portion of the deformable substrate 302.

In some embodiments, the first circuit component 330-1 is formed utilizing a first additive manufacture apparatus 250. In some embodiments, the second circuit component 330-2 is formed utilizing the first additive manufacture apparatus 250. In some embodiments, the second circuit component 330-2 is formed utilizing a second additive manufacture apparatus 250 different from the first additive manufacture apparatus 250. In some embodiments, the additive manufacture apparatus 250 includes a binder jetting mechanism, a material extrusion mechanism, a material jetting mechanism, a polyjet mechanism, a powder bed mechanism, a sheet lamination mechanism, vat photopolymerization mechanism, or a combination thereof.

In some embodiments, the first additive manufacture apparatus 250 is utilized to form the first electronic component 310-1 via a direct writing printing pattern, a stencil printing pattern, a screen printing pattern, or a combination thereof. In some embodiments, the second additive manufacture apparatus 250 is utilized to form the first electronic component 310-2 via the direct writing printing pattern, the stencil printing pattern, the screen printing pattern, or a combination thereof. In some embodiments, a third additive manufacture apparatus 250 is utilized to form the deformable substrate 302 via the direct writing printing pattern, the stencil printing pattern, the screen printing pattern, or a combination thereof. In some embodiments, a fourth additive manufacture apparatus 250 is utilized to dispose the composition 340 via the direct writing printing pattern, the stencil printing pattern, the screen printing pattern, or a combination thereof.

In some embodiments, the forming the first circuit component 330-1, the second circuit component 330-2, an interconnect including a composition 340, or any combination thereof is performed by one or more mechanical surface modification techniques and/or one or more chemical surface modification techniques, such as by disposing a layer of the composition 340 on a first surface of a channel 320 in order to form a via interconnect. For instance, in some embodiments, the forming the layer of the composition 340 is performed by a hydrothermal treatment technique, a micro-arc oxidation technique, a plasma ion implantation (PII) technique, a plasma spraying technique, a selective melting technique, a sol-gel technique, a sputtering technique, an electrochemical deposition technique, or a combination thereof. As a non-limiting example, in some embodiments, includes sputtering technique includes impinging a plurality of ions of the first metal material 342 and/or the filler material 344 at the first surface of the channel 320. In some embodiments, the sputtering technique is performed in a vacuum environment. Accordingly, in some embodiments, by impinging the plurality of ions of the composition 340 at the first surface of the channel 320, the thickness L2 of the layer of the composition is relatively small in comparison to a width D1 (e.g., smallest width in cases where a cross-section of the channel is irregular or other than circular, the diameter in cases where a cross-section of the channel is circular) of the channel 320. However, the present disclosure is not limited thereto.

In some embodiments, the electronically coupling includes tracing out one or more lines, one or more vias, or any combination of one or more lines and one or more vias to form the interconnect between the first circuit component and the second circuit component using the composition.

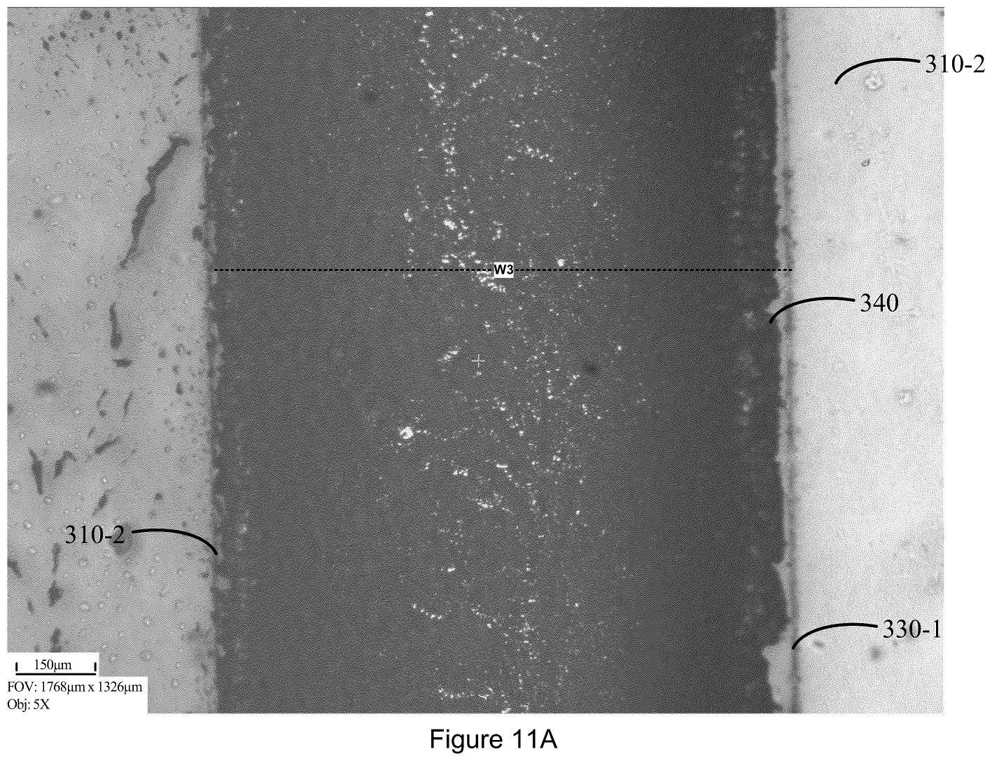

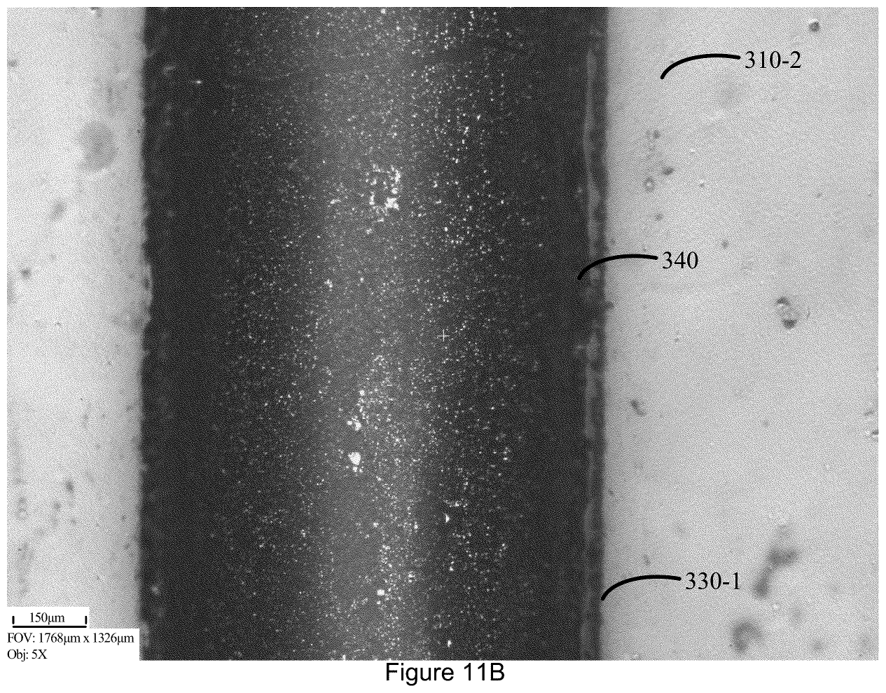

Block 408. Referring to block 408, the method 400 includes electronically coupling the first circuit component 330-1 and the second circuit component 330-2 with a composition (e.g., composition 340 of FIG. 3B, composition 340 of FIG. 11A, composition 340 of FIG. 11B, etc.). In some embodiments, by electronically coupling the first circuit component 330-1 and the second circuit component 330-2 electronical communication is enabled through the composition 340 interposing between the first circuit component 330-1 and the second circuit component 330-2.

In some embodiments, the first circuit component 330-1 and the second circuit component 330-2 is coupled by the composition 340, such as by disposing a volume of the composition 340 utilizing an additive manufacture apparatus 250. In some embodiments, the composition 340 is coupled to the first circuit component 330-1 and/or the second circuit component 330-2 by utilizing a second additive manufacture apparatus 250 different from the first additive manufacture apparatus 250. In some embodiments, the additive manufacture apparatus 250 includes a binder jetting mechanism, a material extrusion mechanism, a material jetting mechanism, a polyjet mechanism, a powder bed mechanism, a sheet lamination mechanism, vat photopolymerization mechanism, or a combination thereof.

As a non-limiting example, in some embodiments, the volume of the composition 340 is disposed by the additive manufacture apparatus 250 at a traverse rate (e.g., nozzle velocity) between 0.5 millimeters per second (mm/s) and 100 mm/s, between 0.5 mm/s and 90 mm/s, between 0.5 mm/s and 80 mm/s, between 0.5 mm/s and 70 mm/s, between 0.5 mm/s and 60 mm/s, between 0.5 mm/s and 50 mm/s, between 0.5 mm/s and 40 mm/s, between 0.5 mm/s and 30 mm/s, between 0.5 mm/s and 20 mm/s, between 0.5 mm/s and 15 mm/s, between 0.5 mm/s and 10 mm/s, between 0.5 mm/s and 5 mm/s, between 2 mm/s and 100 mm/s, between 2 mm/s and 90 mm/s, between 2 mm/s and 80 mm/s, between 2 mm/s and 70 mm/s, between 2 mm/s and 60 mm/s, between 2 mm/s and 50 mm/s, between 2 mm/s and 40 mm/s, between 2 mm/s and 30 mm/s, between 2 mm/s and 20 mm/s, between 2 mm/s and 15 mm/s, between 2 mm/s and 10 mm/s, between 2 mm/s and 5 mm/s, between 8 mm/s and 100 mm/s, between 8 mm/s and 90 mm/s, between 8 mm/s and 80 mm/s, between 8 mm/s and 70 mm/s, between 8 mm/s and 60 mm/s, between 8 mm/s and 50 mm/s, between 8 mm/s and 40 mm/s, between 8 mm/s and 30 mm/s, between 8 mm/s and 20 mm/s, between 8 mm/s and 15 mm/s, between 8 mm/s and 10 mm/s, between 18 mm/s and 100 mm/s, between 18 mm/s and 90 mm/s, between 18 mm/s and 80 mm/s, between 18 mm/s and 70 mm/s, between 18 mm/s and 60 mm/s, between 18 mm/s and 50 mm/s, between 18 mm/s and 40 mm/s, between 18 mm/s and 30 mm/s, between 18 mm/s and 20 mm/s, between 25 mm/s and 100 mm/s, between 25 mm/s and 90 mm/s, between 25 mm/s and 80 mm/s, between 25 mm/s and 70 mm/s, between 25 mm/s and 60 mm/s, between 25 mm/s and 50 mm/s, between 25 mm/s and 40 mm/s, between 25 mm/s and 30 mm/s, between 40 mm/s and 100 mm/s, between 40 mm/s and 90 mm/s, between 40 mm/s and 80 mm/s, between 40 mm/s and 70 mm/s, between 40 mm/s and 60 mm/s, between 40 mm/s and 50 mm/s, between 50 mm/s and 100 mm/s, between 50 mm/s and 90 mm/s, between 50 mm/s and 80 mm/s, between 50 mm/s and 70 mm/s, between 50 mm/s and 60 mm/s, between 60 mm/s and 100 mm/s, between 60 mm/s and 90 mm/s, between 60 mm/s and 80 mm/s, between 60 mm/s and 70 mm/s, between 85 mm/s and 100 mm/s, or between 85 mm/s and 90 mm/s.

In some embodiments, the volume of the composition 340 is disposed by the additive manufacture apparatus 250 at a traverse rate of at least 1 mm/s, at least 2 mm/s, at least 4 mm/s, at least 6 mm/s, at least 8 mm/s, at least 10 mm/s, at least 10 mm/s, at least 12 mm/s, at least 14 mm/s, at least 16 mm/s, at least 18 mm/s, at least 20 mm/s, at least 22 mm/s, at least 24 mm/s, at least 26 mm/s, at least 28 mm/s, at least 30 mm/s, at least 32 mm/s, at least 34 mm/s, at least 36 mm/s, at least 38 mm/s, at least 40 mm/s, at least 42 mm/s, at least 44 mm/s, at least 46 mm/s, at least 48 mm/s, at least 50 mm/s, at least 52 mm/s, at least 54 mm/s, at least 56 mm/s, at least 58 mm/s, at least 60 mm/s, at least 62 mm/s, at least 64 mm/s, at least 66 mm/s, at least 68 mm/s, at least 70 mm/s, at least 72 mm/s, at least 74 mm/s, at least 76 mm/s, at least 78 mm/s, at least 80 mm/s, at least 82 mm/s, at least 84 mm/s, at least 86 mm/s, at least 88 mm/s, at least 90 mm/s, at least 92 mm/s, at least 94 mm/s, at least 96 mm/s, at least 98 mm/s, or at least 100 mm/s. In some embodiments, the volume of the composition 340 is disposed by the additive manufacture apparatus 250 at a traverse rate of at most 1 mm/s, at most 2 mm/s, at most 4 mm/s, at most 6 mm/s, at most 8 mm/s, at most 10 mm/s, at most 10 mm/s, at most 12 mm/s, at most 14 mm/s, at most 16 mm/s, at most 18 mm/s, at most 20 mm/s, at most 22 mm/s, at most 24 mm/s, at most 26 mm/s, at most 28 mm/s, at most 30 mm/s, at most 32 mm/s, at most 34 mm/s, at most 36 mm/s, at most 38 mm/s, at most 40 mm/s, at most 42 mm/s, at most 44 mm/s, at most 46 mm/s, at most 48 mm/s, at most 50 mm/s, at most 52 mm/s, at most 54 mm/s, at most 56 mm/s, at most 58 mm/s, at most 60 mm/s, at most 62 mm/s, at most 64 mm/s, at most 66 mm/s, at most 68 mm/s, at most 70 mm/s, at most 72 mm/s, at most 74 mm/s, at most 76 mm/s, at most 78 mm/s, at most 80 mm/s, at most 82 mm/s, at most 84 mm/s, at most 86 mm/s, at most 88 mm/s, at most 90 mm/s, at most 92 mm/s, at most 94 mm/s, at most 96 mm/s, at most 98 mm/s, or at most 100 mm/s.

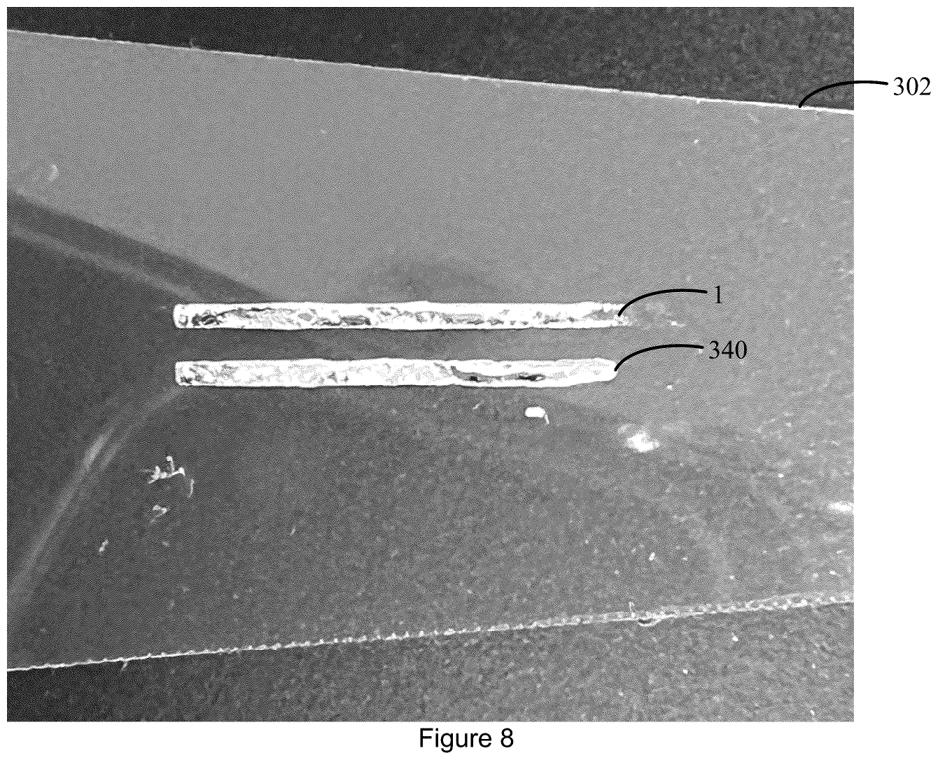

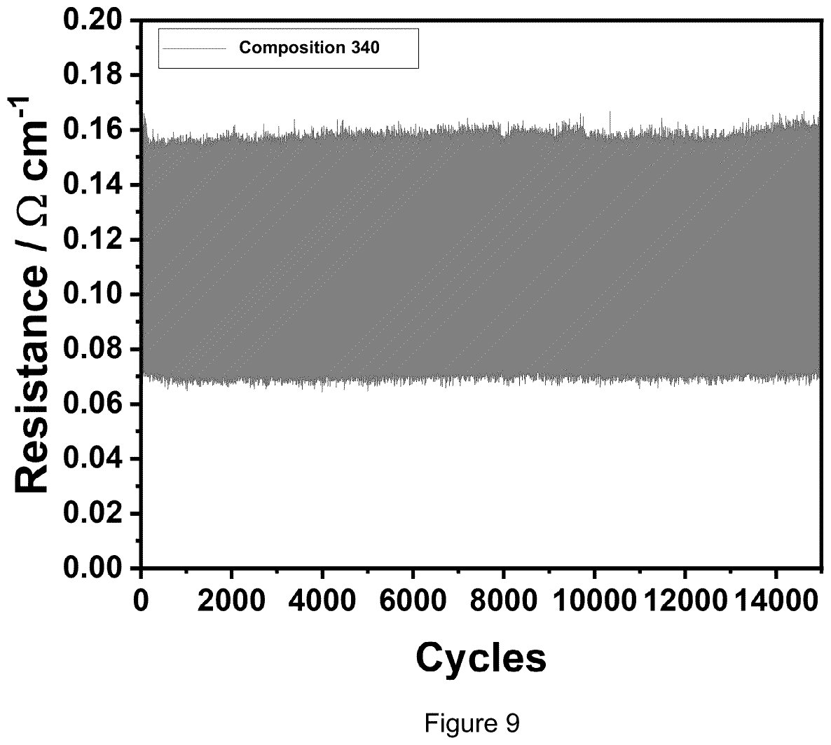

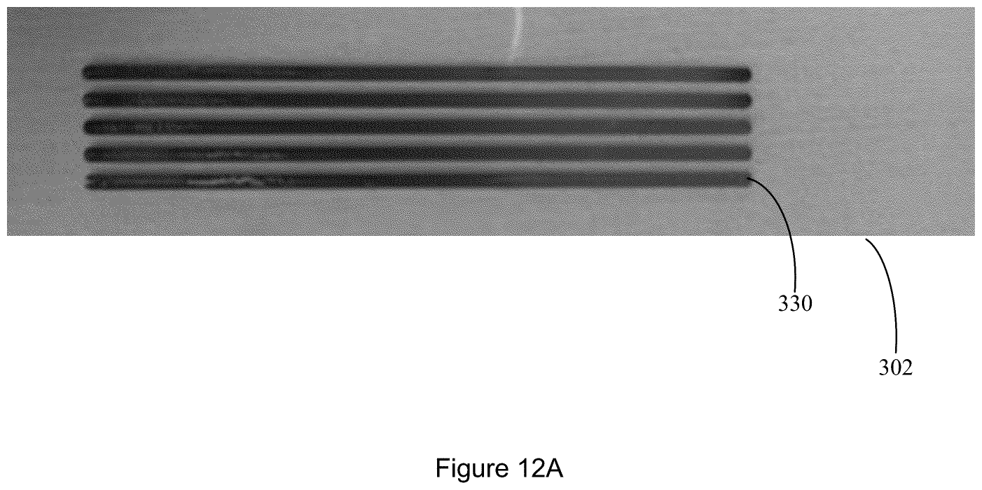

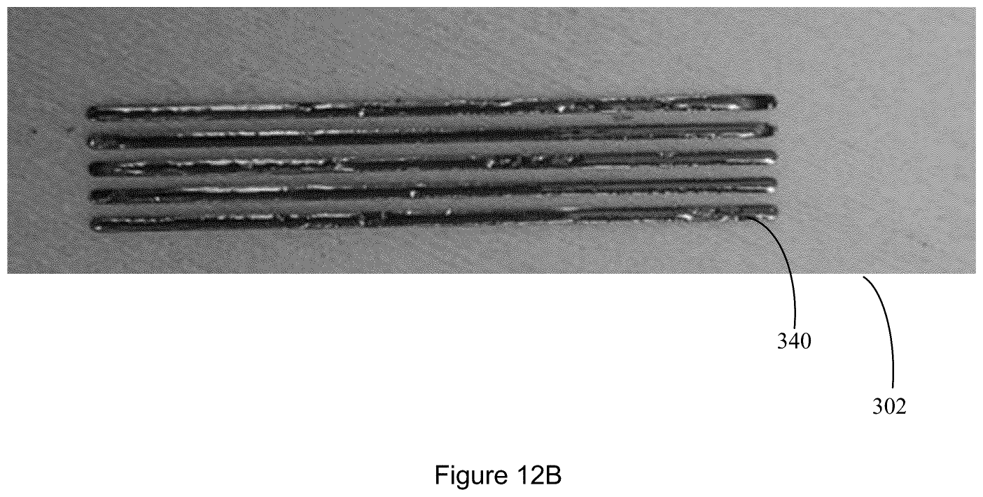

In some embodiments, a thickness of a layer of the composition 340 is between 1 μm and 5 μm. For instance, in some embodiments, the layer of the first metal material 340-1 has thickness W3 and is overlaid the first portion of the deformable substrate 302, such as a first layer 310-1 of the circuit 305 of the deformable substrate 302, in order to form a line interconnect (e.g., interconnect of method 700, interconnect of FIG. 8, interconnect of FIG. 9, interconnect of FIG. 11A, interconnect of FIG. 11B, interconnect of FIG. 12A, interconnect of FIG. 12B, etc.).

In some embodiments, the thickness of the layer of the composition 340 is between 0.5 μm and 6 μm, between 0.5 μm and 5.5 μm, between 0.5 μm and 5 μm, between 0.5 μm and 4.5 μm, between 0.5 μm and 4 μm, between 0.5 μm and 3.5 μm, between 0.5 μm and 3 μm, between 0.5 μm and 2.5 μm, between 0.5 μm and 2 μm, between 0.5 μm and 1.5 μm, between 0.5 μm and 1 μm, between 0.7 μm and 5.5 μm, between 0.7 μm and 5 μm, between 0.7 μm and 4.5 μm, between 0.7 μm and 4 μm, between 0.7 μm and 3.5 μm, between 0.7 μm and 3 μm, between 0.7 μm and 2.5 μm, between 0.7 μm and 2 μm, between 0.7 μm and 1.5 μm, between 0.7 μm and 1 μm, between 1 μm and 5.5 μm, between 1 μm and 5 μm, between 1 μm and 4.5 μm, between 1 μm and 4 μm, between 1 μm and 3.5 μm, between 1 μm and 3 μm, between 1 μm and 2.5 μm, between 1 μm and 2 μm, between 1 μm and 1.5 μm, between 1.2 μm and 5.5 μm, between 1.2 μm and 5 μm, between 1.2 μm and 4.5 μm, between 1.2 μm and 4 μm, between 1.2 μm and 3.5 μm, between 1.2 μm and 3 μm, between 1.2 μm and 2.5 μm, between 1.2 μm and 2 μm, between 1.2 μm and 1.5 μm, between 1.5 μm and 5.5 μm, between 1.5 μm and 5 μm, between 1.5 μm and 4.5 μm, between 1.5 μm and 4 μm, between 1.5 μm and 3.5 μm, between 1.5 μm and 3 μm, between 1.5 μm and 2.5 μm, between 1.5 μm and 2 μm, between 1.7 μm and 5.5 μm, between 1.7 μm and 5 μm, between 1.7 μm and 4.5 μm, between 1.7 μm and 4 μm, between 1.7 μm and 3.5 μm, between 1.7 μm and 3 μm, between 1.7 μm and 2.5 μm, between 1.7 μm and 2 μm, between 2 μm and 5.5 μm, between 2 μm and 5 μm, between 2 μm and 4.5 μm, between 2 μm and 4 μm, between 2 μm and 3.5 μm, between 2 μm and 3 μm, between 2 μm and 2.5 μm, between 2.2 μm and 5.5 μm, between 2.2 μm and 5 μm, between 2.2 μm and 4.5 μm, between 2.2 μm and 4 μm, between 2.2 μm and 3.5 μm, between 2.2 μm and 3 μm, between 2.2 μm and 2.5 μm, between 2.5 μm and 5.5 μm, between 2.5 μm and 5 μm, between 2.5 μm and 4.5 μm, between 2.5 μm and 4 μm, between 2.5 μm and 3.5 μm, between 2.5 μm and 3 μm, between 2.7 μm and 5.5 μm, between 2.7 μm and 5 μm, between 2.7 μm and 4.5 μm, between 2.7 μm and 4 μm, between 2.7 μm and 3.5 μm, between 2.7 μm and 3 μm, between 3 μm and 5.5 μm, between 3 μm and 5 μm, between 3 μm and 4.5 μm, between 3 μm and 4 μm, between 3 μm and 3.5 μm, between 3.2 μm and 5.5 μm, between 3.2 μm and 5 μm, between 3.2 μm and 4.5 μm, between 3.2 μm and 4 μm, between 3.2 μm and 3.5 μm, between 3.5 μm and 5.5 μm, between 3.5 μm and 5 μm, between 3.5 μm and 4.5 μm, between 3.5 μm and 4 μm, between 3.7 μm and 5.5 μm, between 3.7 μm and 5 μm, between 3.7 μm and 4.5 μm, between 3.7 μm and 4 μm, between 4 μm and 5.5 μm, between 4 μm and 5 μm, between 4 μm and 4.5 μm, between 4.2 μm and 5.5 μm, between 4.2 μm and 5 μm, between 4.2 μm and 4.5 μm, between 4.5 μm and 5.5 μm, between 4.5 μm and 5 μm, between 4.7 μm and 5.5 μm, or between 4.7 μm and 5 μm.

In some embodiments, the thickness of the layer of the composition 340 is at least 0.5 μm, at least 0.6 μm, at least 0.7 μm, at least 0.8 μm, at least 0.9 μm, at least 1.0 μm, at least 1.1 μm, at least 1.2 μm, at least 1.3 μm, at least 1.4 μm, at least 1.5 μm, at least 1.6 μm, at least 1.7 μm, at least 1.8 μm, at least 1.9 μm, at least 2.0 μm, at least 2.1 μm, at least 2.2 μm, at least 2.3 μm, at least 2.4 μm, at least 2.5 μm, at least 2.6 μm, at least 2.7 μm, at least 2.8 μm, at least 2.9 μm, at least 3.0 μm, at least 3.1 μm, at least 3.2 μm, at least 3.3 μm, at least 3.4 μm, at least 3.5 μm, at least 3.6 μm, at least 3.7 μm, at least 3.8 μm, at least 3.9 μm, at least 4.0 μm, at least 4.1 μm, at least 4.2 μm, at least 4.3 μm, at least 4.4 μm, at least 4.5 μm, at least 4.6 μm, at least 4.7 μm, at least 4.8 μm, at least 4.9 μm, at least 5.0 μm, at least 5.1 μm, at least 5.2 μm, at least 5.3 μm, at least 5.4 μm, at least 5.5 μm, at least 5.6 μm, at least 5.7 μm, at least 5.8 μm, at least 5.9 μm, or at least 6 μm. In some embodiments, the thickness of a layer of the composition 340 is at most 0.5 μm, at most 0.6 μm, at most 0.7 μm, at most 0.8 μm, at most 0.9 μm, at most 1.0 μm, at most 1.1 μm, at most 1.2 μm, at most 1.3 μm, at most 1.4 μm, at most 1.5 μm, at most 1.6 μm, at most 1.7 μm, at most 1.8 μm, at most 1.9 μm, at most 2.0 μm, at most 2.1 μm, at most 2.2 μm, at most 2.3 μm, at most 2.4 μm, at most 2.5 μm, at most 2.6 μm, at most 2.7 μm, at most 2.8 μm, at most 2.9 μm, at most 3.0 μm, at most 3.1 μm, at most 3.2 μm, at most 3.3 μm, at most 3.4 μm, at most 3.5 μm, at most 3.6 μm, at most 3.7 μm, at most 3.8 μm, at most 3.9 μm, at most 4.0 μm, at most 4.1 μm, at most 4.2 μm, at most 4.3 μm, at most 4.4 μm, at most 4.5 μm, at most 4.6 μm, at most 4.7 μm, at most 4.8 μm, at most 4.9 μm, at most 5.0 μm, at most 5.1 μm, at most 5.2 μm, at most 5.3 μm, at most 5.4 μm, at most 5.5 μm, at most 5.6 μm, at most 5.7 μm, at most 5.8 μm, at most 5.9 μm, or at most 6 μm.

In some embodiments, thickness of the layer of the composition 340 is between 0.01 mil (e.g., 0.019685 mil) to 0.24 mil (e.g., 0.23622 mil), between 0.01 mil and 0.15 mil, between 0.02 mil and 0.22 mil, between 0.02 mil and 0.18 mil, between 0.02 mil and 0.15 mil, between 0.02 mil and 0.11 mil, between 0.02 mil and 0.10 mil, between 0.04 mil and 0.20 mil, between 0.04 mil and 0.18 mil, between 0.04 mil and 0.15 mil, between 0.04 mil and 0.11 mil, between 0.04 mil and 0.10 mil, between 0.06 mil and 0.18 mil, between 0.06 mil and 0.15 mil, between 0.06 mil and 0.11 mil, between 0.06 mil and 0.10 mil, between 0.08 mil and 0.16 mil, between 0.08 mil and 0.15 mil, between 0.08 mil and 0.11 mil, between 0.08 mil and 0.10 mil, between 0.10 mil and 0.16 mil, between 0.10 mil and 0.15 mil, between 0.10 mil and 0.11 mil, or between 0.11 mil and 0.13 mil.

In some embodiments, the thickness of the layer of the composition 340 is at least 0.01 mil, at least 0.02 mil, at least 0.03 mil, at least 0.04 mil, at least 0.05 mil, at least 0.06 mil, at least 0.07 mil, at least 0.08 mil, at least 0.09 mil, at least 0.10 mil, at least 0.11 mil, at least 0.12 mil, at least 0.13 mil, at least 0.14 mil, at least 0.15 mil, at least 0.16 mil, at least 0.17 mil, at least 0.18 mil, at least 0.19 mil, at least 0.20 mil, at least 0.21 mil, at least 0.22 mil, at least 0.23 mil, at least 0.24 mil, or at least 0.25 mil.

In some embodiments, the thickness of the layer of the composition 340 is at most 0.01 mil, at most 0.02 mil, at most 0.03 mil, at most 0.04 mil, at most 0.05 mil, at most 0.06 mil, at most 0.07 mil, at most 0.08 mil, at most 0.09 mil, at most 0.10 mil, at most 0.11 mil, at most 0.12 mil, at most 0.13 mil, at most 0.14 mil, at most 0.15 mil, at most 0.16 mil, at most 0.17 mil, at most 0.18 mil, at most 0.19 mil, at most 0.20 mil, at most 0.21 mil, at most 0.22 mil, at most 0.23 mil, at most 0.24 mil, or at most 0.25 mil.

The composition 340 includes a first metal material (e.g., first metal material 342 of FIG. 3B). In some embodiments, the first metal material 342 is or includes a liquid metal. In some embodiments, the second metal material 340-2 includes liquid metal. In some embodiments, the liquid metal is a metal material that exists at a liquid phase at or near room temperature (e.g., at or near between 18° C. and 22° C.). In some embodiments, the second metal material 340-2 includes a gallium-based (Ga-based) alloy. For instance, in some embodiments, the second metal material 340-2 includes a gallium indium alloy (e.g., eutectic GaIn), a gallium tin alloy, a gallium indium tin alloy (e.g., Galinstan), a gallium indium tin zinc alloy, or any combination thereof. In some embodiments, the second metal material 340-2 includes more than one alloys. For instance, in some embodiments, the second metal material 340-2 includes eutectic GaIn and/or Galinstan.

In some embodiments, the first metal material 342 includes Ga between 25 weight percent (w %) and 95 w %, between 25 w % and 75 w %, between 25 w % and 50 w %, 50 w % and 95 w %, between 50 w % and 75 w %, or 75 w % and 95 w % of the first metal material 342. In some embodiments, the first metal material 342 includes Ga in at least 25 w %, at least 30 w %, at least 35 w %, at least 40 w %, at least 45 w %, at least 50 w %, at least 55 w %, at least 60 w %, at least 65 w %, at least 70 w %, at least 75 w %, at least 80 w %, at least 85 w %, at least 90 w %, or at least 95 w % of the first metal material 342. In some embodiments, the first metal material 342 includes Ga in at most 25 w %, at most 30 w %, at most 35 w %, at most 40 w %, at most 45 w %, at most 50 w %, at most 55 w %, at most 60 w %, at most 65 w %, at most 70 w %, at most 75 w %, at most 80 w %, at most 85 w %, at most 90 w %, or at most 95 w % of the first metal material 342.

In some embodiments, the first metal material 342 includes Ga between 25 weight percent (w %) and 95 w %, between 25 w % and 75 w %, between 25 w % and 50 w %, 50 w % and 95 w %, between 50 w % and 75 w %, or 75 w % and 95 w % of the composition 340. In some embodiments, the first metal material 342 includes Ga in at least 25 w %, at least 30 w %, at least 35 w %, at least 40 w %, at least 45 w %, at least 50 w %, at least 55 w %, at least 60 w %, at least 65 w %, at least 70 w %, at least 75 w %, at least 80 w %, at least 85 w %, at least 90 w %, or at least 95 w % of the composition 340. In some embodiments, the first metal material 342 includes Ga in at most 25 w %, at most 30 w %, at most 35 w %, at most 40 w %, at most 45 w %, at most 50 w %, at most 55 w %, at most 60 w %, at most 65 w %, at most 70 w %, at most 75 w %, at most 80 w %, at most 85 w %, at most 90 w %, or at most 95 w % of the composition 340.

The composition 340 further includes a filler material (e.g., filler material 344 of FIG. 3B). In some embodiments, the filler material 344 is configured to yield a composition 340 with a first viscosity that is greater than a second viscosity of the first metal material 342. Said otherwise, in some embodiments, the filler material 344 is configured to combine with the first metal material 342 in order to form the composition 340 that increases a viscosity of the first metal material 342. Moreover, in some embodiments, the first viscosity allows the composition 340 to be disposed by utilizing an additive manufacture apparatus 250, such as through a direct writing pattern, a screen printing pattern technique, a stencil printing pattern technique, or a combination thereof when the first metal material 342 would otherwise be unsuitable for utilizing with the additive manufacture apparatus 250 due to a low value relatively of the second viscosity of the first metal material 342.

In some embodiments, the filler material 344 is configured to yield a composition 340 with a first conductivity that is greater than or equal to, equal to, or substantially equal to a second conductivity of the first metal material 342. Said otherwise, in some embodiments, the filler material 344 is configured to combine with the first metal material 342 in order to form the composition 340 that does not change or substantially change the conductivity of the first metal material 342.

In some embodiments, the filler material 344 is disposed within the first metal material 342. For instance, in some embodiments, the first metal material 342 is utilized to accommodate the filler material 344, consume the filler material 344, dissolve the filler material 344, encapsulate the filler material 344, enclose the filler material 344, entrap the filler material 344, inject the filler material 344, implant the filler material 344, insert the filler material 344, or a combination thereof. As a non-limiting example, in some embodiments, the filler material 344 is disposed within the first metal material 342 by forming the composition 340 as an emulsion.

Accordingly, in some embodiments, the composition 340 of the present disclosure is utilized to form an interconnect (e.g., a third circuit component) between the first circuit component 330-1 and the second circuit component 330-2.

In some embodiments, the thickness of the interconnect is between 1 μm and 500 μm, between 1 μm and 450 μm, between 1 μm and 400 μm, between 1 μm and 350 μm, between 1 μm and 300 μm, between 1 μm and 250 μm, between 1 μm and 200 μm, between 1 μm and 150 μm, between 1 μm and 100 μm, between 1 μm and 50 μm, between 1 μm and 10 μm, between 2 μm and 500 μm, between 2 μm and 450 μm, between 2 μm and 400 μm, between 2 μm and 350 μm, between 2 μm and 300 μm, between 2 μm and 250 μm, between 2 μm and 200 μm, between 2 μm and 150 μm, between 2 μm and 100 μm, between 2 μm and 50 μm, between 2 μm and 10 μm, between 3 μm and 500 μm, between 3 μm and 450 μm, between 3 μm and 400 μm, between 3 μm and 350 μm, between 3 μm and 300 μm, between 3 μm and 250 μm, between 3 μm and 200 μm, between 3 μm and 150 μm, between 3 μm and 100 μm, between 3 μm and 50 μm, between 3 μm and 10 μm, between 4 μm and 500 μm, between 4 μm and 450 μm, between 4 μm and 400 μm, between 4 μm and 350 μm, between 4 μm and 300 μm, between 4 μm and 250 μm, between 4 μm and 200 μm, between 4 μm and 150 μm, between 4 μm and 100 μm, between 4 μm and 50 μm, between 4 μm and 10 μm, between 5 μm and 500 μm, between 5 μm and 450 μm, between 5 μm and 400 μm, between 5 μm and 350 μm, between 5 μm and 300 μm, between 5 μm and 250 μm, between 5 μm and 200 μm, between 5 μm and 150 μm, between 5 μm and 100 μm, between 5 μm and 50 μm, between 5 μm and 10 μm, between 6 μm and 500 μm, between 6 μm and 450 μm, between 6 μm and 400 μm, between 6 μm and 350 μm, between 6 μm and 300 μm, between 6 μm and 250 μm, between 6 μm and 200 μm, between 6 μm and 150 μm, between 6 μm and 100 μm, between 6 μm and 50 μm, between 6 μm and 10 μm, between 10 μm and 500 μm, between 10 μm and 450 μm, between 10 μm and 400 μm, between 10 μm and 350 μm, between 10 μm and 300 μm, between 10 μm and 250 μm, between 10 μm and 200 μm, between 10 μm and 150 μm, between 10 μm and 100 μm, between 10 μm and 90 μm, between 10 μm and 50 μm, between 75 μm and 500 μm, between 75 μm and 450 μm, between 75 μm and 400 μm, between 75 μm and 350 μm, between 75 μm and 300 μm, between 75 μm and 250 μm, between 75 μm and 200 μm, between 75 μm and 150 μm, between 75 μm and 100 μm, between 150 μm and 500 μm, between 150 μm and 450 μm, between 150 μm and 400 μm, between 150 μm and 350 μm, between 150 μm and 300 μm, between 150 μm and 250 μm, between 150 μm and 200 μm, between 225 μm and 500 μm, between 225 μm and 450 μm, between 225 μm and 400 μm, between 225 μm and 350 μm, between 225 μm and 300 μm, between 225 μm and 250 μm, between 300 μm and 550 μm, between 300 μm and 500 μm, between 300 μm and 450 μm, between 300 μm and 400 μm, between 300 μm and 350 μm between 375 μm and 500 μm, between 375 μm and 450 μm, between 375 μm and 400 μm, or between 450 μm and 500 μm.

In some embodiments, the thickness of the interconnect changes as a function of length and/or depth of the interconnect. For instance, in some embodiments, the width of the interconnect is at least 1, 2, 3, 5, 10, 15, 20, or 25 percent larger at one point in the length of the interconnect as it is at a second point in the length of the interconnect. In some embodiments, the first point in the length of the interconnect is the first point at which the interconnect has the largest cross-section and the second point is the point at which the interconnect has the smallest cross-section. In some embodiments, the in thickness of the interconnect does not appreciably or measurably change as a function of length and/or depth of the interconnect.

In some embodiments, the thickness of the interconnect is at least 1 μm, at least 2 μm, at least 3 μm, at least 4 μm, at least 5 μm, at least 6 μm, at least 10 μm, at least 15 μm, at least 20 μm, at least 25 μm, at least 30 μm, at least 35 μm, at least 40 μm, at least 45 μm, at least 50 μm, at least 55 μm, at least 60 μm, at least 65 μm, at least 70 μm, at least 75 μm, at least 80 μm, at least 85 μm, at least 90 μm, at least 95 μm, at least 100 μm, at least 105 μm, at least 110 μm, at least 115 μm, at least 120 μm, at least 125 μm, at least 130 μm, at least 135 μm, at least 140 μm, at least 145 μm, at least 150 μm, at least 155 μm, at least 160 μm, at least 165 μm, at least 170 μm, at least 175 μm, at least 180 μm, at least 185 μm, at least 190 μm, at least 195 μm, at least 200 μm, at least 205 μm, at least 210 μm, at least 215 μm, at least 220 μm, at least 225 μm, at least 230 μm, at least 235 μm, at least 240 μm, at least 245 μm, at least 250 μm, at least 255 μm, at least 260 μm, at least 265 μm, at least 270 μm, at least 275 μm, at least 280 μm, at least 285 μm, at least 290 μm, at least 295 μm, at least 300 μm, at least 305 μm, at least 310 μm, at least 315 μm, at least 320 μm, at least 325 μm, at least 330 μm, at least 335 μm, at least 340 μm, at least 345 μm, at least 350 μm, at least 355 μm, at least 360 μm, at least 365 μm, at least 370 μm, at least 375 μm, at least 380 μm, at least 385 μm, at least 390 μm, at least 395 μm, at least 400 μm, at least 405 μm, at least 410 μm, at least 415 μm, at least 420 μm, at least 425 μm, at least 430 μm, at least 435 μm, at least 440 μm, at least 445 μm, at least 450 μm, at least 455 μm, at least 460 μm, at least 465 μm, at least 470 μm, at least 475 μm, at least 480 μm, at least 485 μm, at least 490 μm, at least 495 μm, or at least 500 μm.

In some embodiments, the thickness of the interconnect is at most 1 μm, at most 2 μm, at most 3 μm, at most 4 μm, at most 5 μm, at most 6 μm, at most 10 μm, at most 15 μm, at most 20 μm, at most 25 μm, at most 30 μm, at most 35 μm, at most 40 μm, at most 45 μm, at most 50 μm, at most 55 μm, at most 60 μm, at most 65 μm, at most 70 μm, at most 75 μm, at most 80 μm, at most 85 μm, at most 90 μm, at most 95 μm, at most 100 μm, at most 105 μm, at most 110 μm, at most 115 μm, at most 120 μm, at most 125 μm, at most 130 μm, at most 135 μm, at most 140 μm, at most 145 μm, at most 150 μm, at most 155 μm, at most 160 μm, at most 165 μm, at most 170 μm, at most 175 μm, at most 180 μm, at most 185 μm, at most 190 μm, at most 195 μm, at most 200 μm, at most 205 μm, at most 210 μm, at most 215 μm, at most 220 μm, at most 225 μm, at most 230 μm, at most 235 μm, at most 240 μm, at most 245 μm, at most 250 μm, at most 255 μm, at most 260 μm, at most 265 μm, at most 270 μm, at most 275 μm, at most 280 μm, at most 285 μm, at most 290 μm, at most 295 μm, at most 300 μm, at most 305 μm, at most 310 μm, at most 315 μm, at most 320 μm, at most 325 μm, at most 330 μm, at most 335 μm, at most 340 μm, at most 345 μm, at most 350 μm, at most 355 μm, at most 360 μm, at most 365 μm, at most 370 μm, at most 375 μm, at most 380 μm, at most 385 μm, at most 390 μm, at most 395 μm, at most 400 μm, at most 405 μm, at most 410 μm, at most 415 μm, at most 420 μm, at most 425 μm, at most 430 μm, at most 435 μm, at most 440 μm, at most 445 μm, at most 450 μm, at most 455 μm, at most 460 μm, at most 465 μm, at most 470 μm, at most 475 μm, at most 480 μm, at most 485 μm, at most 490 μm, at most 495 μm, or at most 500 μm.

In some embodiments, the width of the interconnect is between 1 μm and 500 μm, between 1 μm and 450 μm, between 1 μm and 400 μm, between 1 μm and 350 μm, between 1 μm and 300 μm, between 1 μm and 250 μm, between 1 μm and 200 μm, between 1 μm and 150 μm, between 1 μm and 100 μm, between 1 μm and 50 μm, between 1 μm and 10 μm, between 2 μm and 500 μm, between 2 μm and 450 μm, between 2 μm and 400 μm, between 2 μm and 350 μm, between 2 μm and 300 μm, between 2 μm and 250 μm, between 2 μm and 200 μm, between 2 μm and 150 μm, between 2 μm and 100 μm, between 2 μm and 50 μm, between 2 μm and 10 μm, between 3 μm and 500 μm, between 3 μm and 450 μm, between 3 μm and 400 μm, between 3 μm and 350 μm, between 3 μm and 300 μm, between 3 μm and 250 μm, between 3 μm and 200 μm, between 3 μm and 150 μm, between 3 μm and 100 μm, between 3 μm and 50 μm, between 3 μm and 10 μm, between 4 μm and 500 μm, between 4 μm and 450 μm, between 4 μm and 400 μm, between 4 μm and 350 μm, between 4 μm and 300 μm, between 4 μm and 250 μm, between 4 μm and 200 μm, between 4 μm and 150 μm, between 4 μm and 100 μm, between 4 μm and 50 μm, between 4 μm and 10 μm, between 5 μm and 500 μm, between 5 μm and 450 μm, between 5 μm and 400 μm, between 5 μm and 350 μm, between 5 μm and 300 μm, between 5 μm and 250 μm, between 5 μm and 200 μm, between 5 μm and 150 μm, between 5 μm and 100 μm, between 5 μm and 50 μm, between 5 μm and 10 μm, between 6 μm and 500 μm, between 6 μm and 450 μm, between 6 μm and 400 μm, between 6 μm and 350 μm, between 6 μm and 300 μm, between 6 μm and 250 μm, between 6 μm and 200 μm, between 6 μm and 150 μm, between 6 μm and 100 μm, between 6 μm and 50 μm, between 6 μm and 10 μm, between 10 μm and 500 μm, between 10 μm and 450 μm, between 10 μm and 400 μm, between 10 μm and 350 μm, between 10 μm and 300 μm, between 10 μm and 250 μm, between 10 μm and 200 μm, between 10 μm and 150 μm, between 10 μm and 100 μm, between 10 μm and 90 μm, between 10 μm and 50 μm, between 75 μm and 500 μm, between 75 μm and 450 μm, between 75 μm and 400 μm, between 75 μm and 350 μm, between 75 μm and 300 μm, between 75 μm and 250 μm, between 75 μm and 200 μm, between 75 μm and 150 μm, between 75 μm and 100 μm, between 150 μm and 500 μm, between 150 μm and 450 μm, between 150 μm and 400 μm, between 150 μm and 350 μm, between 150 μm and 300 μm, between 150 μm and 250 μm, between 150 μm and 200 μm, between 225 μm and 500 μm, between 225 μm and 450 μm, between 225 μm and 400 μm, between 225 μm and 350 μm, between 225 μm and 300 μm, between 225 μm and 250 μm, between 300 μm and 550 μm, between 300 μm and 500 μm, between 300 μm and 450 μm, between 300 μm and 400 μm, between 300 μm and 350 μm between 375 μm and 500 μm, between 375 μm and 450 μm, between 375 μm and 400 μm, or between 450 μm and 500 μm.

In some embodiments, the width of the interconnect changes as a function of length and/or depth of the interconnect. For instance, in some embodiments, the width of the interconnect is at least 1, 2, 3, 5, 10, 15, 20, or 25 percent larger at one point in the length of the interconnect as it is at a second point in the length of the interconnect. In some embodiments, the first point in the length of the interconnect is the first point at which the interconnect has the largest cross-section and the second point is the point at which the interconnect has the smallest cross-section. In some embodiments, the in width of the interconnect does not appreciably or measurably change as a function of length and/or depth of the interconnect.

In some embodiments, the width of the interconnect is at least 1 μm, at least 2 μm, at least 3 μm, at least 4 μm, at least 5 μm, at least 6 μm, at least 10 μm, at least 15 μm, at least 20 μm, at least 25 μm, at least 30 μm, at least 35 μm, at least 40 μm, at least 45 μm, at least 50 μm, at least 55 μm, at least 60 μm, at least 65 μm, at least 70 μm, at least 75 μm, at least 80 μm, at least 85 μm, at least 90 μm, at least 95 μm, at least 100 μm, at least 105 μm, at least 110 μm, at least 115 μm, at least 120 μm, at least 125 μm, at least 130 μm, at least 135 μm, at least 140 μm, at least 145 μm, at least 150 μm, at least 155 μm, at least 160 μm, at least 165 μm, at least 170 μm, at least 175 μm, at least 180 μm, at least 185 μm, at least 190 μm, at least 195 μm, at least 200 μm, at least 205 μm, at least 210 μm, at least 215 μm, at least 220 μm, at least 225 μm, at least 230 μm, at least 235 μm, at least 240 μm, at least 245 μm, at least 250 μm, at least 255 μm, at least 260 μm, at least 265 μm, at least 270 μm, at least 275 μm, at least 280 μm, at least 285 μm, at least 290 μm, at least 295 μm, at least 300 μm, at least 305 μm, at least 310 μm, at least 315 μm, at least 320 μm, at least 325 μm, at least 330 μm, at least 335 μm, at least 340 μm, at least 345 μm, at least 350 μm, at least 355 μm, at least 360 μm, at least 365 μm, at least 370 μm, at least 375 μm, at least 380 μm, at least 385 μm, at least 390 μm, at least 395 μm, at least 400 μm, at least 405 μm, at least 410 μm, at least 415 μm, at least 420 μm, at least 425 μm, at least 430 μm, at least 435 μm, at least 440 μm, at least 445 μm, at least 450 μm, at least 455 μm, at least 460 μm, at least 465 μm, at least 470 μm, at least 475 μm, at least 480 μm, at least 485 μm, at least 490 μm, at least 495 μm, or at least 500 μm.

In some embodiments, the width of the interconnect is at most 1 μm, at most 2 μm, at most 3 μm, at most 4 μm, at most 5 μm, at most 6 μm, at most 10 μm, at most 15 μm, at most 20 μm, at most 25 μm, at most 30 μm, at most 35 μm, at most 40 μm, at most 45 μm, at most 50 μm, at most 55 μm, at most 60 μm, at most 65 μm, at most 70 μm, at most 75 μm, at most 80 μm, at most 85 μm, at most 90 μm, at most 95 μm, at most 100 μm, at most 105 μm, at most 110 μm, at most 115 μm, at most 120 μm, at most 125 μm, at most 130 μm, at most 135 μm, at most 140 μm, at most 145 μm, at most 150 μm, at most 155 μm, at most 160 μm, at most 165 μm, at most 170 μm, at most 175 μm, at most 180 μm, at most 185 μm, at most 190 μm, at most 195 μm, at most 200 μm, at most 205 μm, at most 210 μm, at most 215 μm, at most 220 μm, at most 225 μm, at most 230 μm, at most 235 μm, at most 240 μm, at most 245 μm, at most 250 μm, at most 255 μm, at most 260 μm, at most 265 μm, at most 270 μm, at most 275 μm, at most 280 μm, at most 285 μm, at most 290 μm, at most 295 μm, at most 300 μm, at most 305 μm, at most 310 μm, at most 315 μm, at most 320 μm, at most 325 μm, at most 330 μm, at most 335 μm, at most 340 μm, at most 345 μm, at most 350 μm, at most 355 μm, at most 360 μm, at most 365 μm, at most 370 μm, at most 375 μm, at most 380 μm, at most 385 μm, at most 390 μm, at most 395 μm, at most 400 μm, at most 405 μm, at most 410 μm, at most 415 μm, at most 420 μm, at most 425 μm, at most 430 μm, at most 435 μm, at most 440 μm, at most 445 μm, at most 450 μm, at most 455 μm, at most 460 μm, at most 465 μm, at most 470 μm, at most 475 μm, at most 480 μm, at most 485 μm, at most 490 μm, at most 495 μm, or at most 500 μm.

Block 410. Referring to block 410, in some embodiments, the composition 340 is a Newtonian composition, which is characterized by a linear relationship between an applied shear stress and a shear rate of the composition 340. However, the present disclosure is not limited thereto. In some embodiments, the composition 340 is a non-Newtonian composition. For instance, in some embodiments, the composition 340 is a shear-thinning composition, a shear-thickening composition, a viscoelastic composition, or a combination thereof. As a non-limiting example, in some embodiments, the non-Newtonian composition 240 is in the form of a polymer solution, a melt (e.g., a polymer melt, a filament melt, a liquid phase, etc.), a foam, a suspension, or a combination thereof. In some embodiments, the composition 340 is the shear-thickening composition when an apparent viscosity of the composition 340 decreases in proportional to an increase in shear rate. Accordingly, in some such embodiments, by utilizing the shear-thickening composition 340, the composition 340 is capable of increasing a flowability realized through the decreased viscosity when the deformable substrate is strained, which allows the composition 340 to fill maintain the coupling of the first circuit component 330-1 and the second circuit component 330-2 throughout the applied strain.

Block 412. Referring to block 412, in some embodiments, the composition 340 includes a homogenous mixture of the first metal material 342 and/or the filler material 344. For instance, in some embodiments, the first metal material 342 is a homogenous mixture of two or more different metal materials, such as a Ga-alloy. In some embodiments, the first metal material 342 and the filler material 344 form a homogenous mixture. Accordingly, by forming the composition 340 that includes the homogenous mixture of the first metal material 342 and/or the filler material 344, beneficial properties of the filler material 344 within the first metal material 344 are uniformly provided throughout the composition 340, which yields a high-quality electronic device that incorporates the composition 340.

Block 414. Referring to block 414, in some embodiments, the filler material 344 is a metal oxide, which is a material having a structure with a metal cation and an oxide anion. In some embodiments, the filler material 344 is a polymer, such as a conductive polymer (e.g., metal oxide-based polymer). In some embodiments, the filler material 344 includes both a metal oxide and a polymer.

Block 416. Referring to block 416 of FIG. 4B, in some embodiments, the filler material 344 includes aluminum (Al), carbon (C), copper (Cu), gallium (Ga), indium-tin oxide (ITO), lithium (Li), nickel (Ni), titanium (Ti), or a combination thereof. For instance, in some embodiments, in some embodiments, the filler material 344 includes aluminum oxide (Al₂O₃), copper(I) oxide (Cu₂O), copper(II) oxide (CuO), gallium oxide (Ga₂O₃), lithium oxide (Li₂O), nickel(II) oxide (NiO), nickel(III) oxide (Ni₂O₃), titanium oxide (TiO₂), or a combination thereof.

Block 418. Referring to block 418, in some embodiments, the filler material 344 includes a non-intrinsic metal oxide. For instance, in some embodiments, the filler material 344 is in the form of a powdered material, which allows for varying a particle size distribution of the filler material 344 in the composition 340, a shape of the filler material 344 in the composition 340, a flowability of the filler material 344, a bulk density of the filler material 344, a tap density of the filler material 344 (e.g., a ratio of a mass of the filler material 344 against a volume occupied by the filler material 344 after being disrupted, such as taped, for a threshold epoch), an angle of repose of the filler material 344, a Carr index of the filler material 344 (e.g., a compressibility of the filler material 344 based on a tap density against a bulk density of the filler material 344), or a combination thereof. In some embodiments, the filler material 344 is an extrinsic compound of the composition 340.

Block 420. Referring to block 420, in some embodiments, the method 400 includes adding the filler material 344 to the first metal material 342 in order to form the composition 340. In some embodiments, the filler material 344 in the form of microflakes, nanoflakes, microparticles, nanoparticles, nanowires, nanotubes, or a combination thereof, when added to form the composition 340. In some embodiments, the microflakes, nanoflakes, microparticles, nanoparticles, nanowires, nanotubes, or the combination thereof of the filler material 344 remain in an initial state after forming the composition 340 with the first metal material 342. For instance, in some embodiments, the filler material 344 is insoluble in the first metal material 342. However, the present disclosure is not limited thereto. In some embodiments, the filler material 344 is added to the first metal material 342 by a mechanical mixing technique, a melt mixing technique, a cryogenic grinding technique, a spray drying technique, a dissolution-precipitation technique, a mechanochemistry alloying technique, or a combination thereof.

Block 422. Referring to block 422, in some embodiments, the filler material 344 includes a conductive polymer. For instance, in some embodiments, the filler includes a 3,4-ethylenedioxythiophene- (EDT-) based monomer, an EDT based oligomer, an EDT based (co)polymer, or a combination thereof. In some embodiments, the conductive polymer includes Poly(3,4-ethylenedioxythiophene) (PEDOT).

Block 424. Referring to block 424, in some embodiments, the filler material 344 includes poly(3,4-ethylenedioxythiophene):poly(styrene sulfonate) (PEDOT:PSS). In some embodiments, the filler material includes poly(3,4-ethylenedioxythiophene)-poly(styrenesulfonate), poly(3,4-ethylenedioxythiophene)-poly(styrenesulfonate), poly(3,4-ethylenedioxythiophene)-poly(styrenesulfonate), poly(3,4-ethylenedioxythiophene)-poly(styrenesulfonate), poly(3,4-ethylenedioxythiophene)-poly(styrenesulfonate), poly(3,4-ethylenedioxythiophene)-poly(styrenesulfonate), poly(3,4-ethylenedioxythiophene)-poly(styrenesulfonate), poly(3,4-ethylenedioxythiophene)-poly(styrenesulfonate), poly(3,4-ethylenedioxythiophene)-poly(styrenesulfonate), or poly(3,4-ethylenedioxythiophene)-poly(styrenesulfonate).

In some embodiments, the conductivity of the filler material 344 is between 20 Siemens per centimeter (S/cm) and 500 S/cm, between 20 S/cm and 450 S/cm, between 20 S/cm and 400 S/cm, between 20 S/cm and 350 S/cm, between 20 S/cm and 300 S/cm, between 20 S/cm and 250 S/cm, between 20 S/cm and 200 S/cm, between 20 S/cm and 150 S/cm, between 20 S/cm and 100 S/cm, between 50 S/cm and 500 S/cm, between 50 S/cm and 450 S/cm, between 50 S/cm and 400 S/cm, between 50 S/cm and 350 S/cm, between 50 S/cm and 300 S/cm, between 50 S/cm and 250 S/cm, between 50 S/cm and 200 S/cm, between 50 S/cm and 150 S/cm, between 50 S/cm and 100 S/cm, between 100 S/cm and 500 S/cm, between 100 S/cm and 450 S/cm, between 100 S/cm and 400 S/cm, between 100 S/cm and 350 S/cm, between 100 S/cm and 300 S/cm, between 100 S/cm and 250 S/cm, between 100 S/cm and 200 S/cm, between 100 S/cm and 150 S/cm, between 150 S/cm and 500 S/cm, between 150 S/cm and 450 S/cm, between 150 S/cm and 400 S/cm, between 150 S/cm and 350 S/cm, between 150 S/cm and 300 S/cm, between 150 S/cm and 250 S/cm, between 150 S/cm and 200 S/cm, between 200 S/cm and 500 S/cm, between 200 S/cm and 450 S/cm, between 200 S/cm and 400 S/cm, between 200 S/cm and 350 S/cm, between 200 S/cm and 300 S/cm, between 200 S/cm and 250 S/cm, between 250 S/cm and 500 S/cm, between 250 S/cm and 450 S/cm, between 250 S/cm and 400 S/cm, between 250 S/cm and 350 S/cm, between 250 S/cm and 300 S/cm, between 300 S/cm and 500 S/cm, between 300 S/cm and 450 S/cm, between 300 S/cm and 400 S/cm, between 300 S/cm and 350 S/cm, between 350 S/cm and 500 S/cm, between 350 S/cm and 450 S/cm, between 350 S/cm and 400 S/cm, between 400 S/cm and 500 S/cm, between 400 S/cm and 450 S/cm, or between 450 S/cm and 500 S/cm.

In some embodiments, the conductivity of the filler material 344 is at least 20 S/cm, at least 50 S/cm, at least 70 S/cm, at least 90 S/cm, at least 110 S/cm, at least 130 S/cm, at least 150 S/cm, at least 170 S/cm, at least 190 S/cm, at least 210 S/cm, at least 230 S/cm, at least 250 S/cm, at least 270 S/cm, at least 290 S/cm, at least 310 S/cm, at least 330 S/cm, at least 350 S/cm, at least 370 S/cm, at least 390 S/cm, at least 410 S/cm, at least 430 S/cm, at least 450 S/cm, at least 470 S/cm, at least 490 S/cm, or at least 500 S/cm. In some embodiments, the conductivity of the filler material 344 is at most 20 S/cm, at most 50 S/cm, at most 70 S/cm, at most 90 S/cm, at most 110 S/cm, at most 130 S/cm, at most 150 S/cm, at most 170 S/cm, at most 190 S/cm, at most 210 S/cm, at most 230 S/cm, at most 250 S/cm, at most 270 S/cm, at most 290 S/cm, at most 310 S/cm, at most 330 S/cm, at most 350 S/cm, at most 370 S/cm, at most 390 S/cm, at most 410 S/cm, at most 430 S/cm, at most 450 S/cm, at most 470 S/cm, at most 490 S/cm, or at most 500 S/cm.

Block 426. Referring to block 426, in some embodiments, the method 400 includes disposing exogenously the filler material 344 within the first metal material 342 to form the composition 340. For instance, in some embodiments, the method 400 includes encapsulating, enclosing, entrapping, injecting, implanting, inserting, or a combination thereof the filler material 344 into a volume of the first metal material 342 in order to form the composition 340.

Block 428. Referring to block 428, in some embodiments, the method 400 includes disposing the filler material 344 within the first metal material 342 without sintering the first metal material 342 and/or the filler material 344 to form the composition 340. Accordingly, in some such embodiments, the first metal material 342 and/or the filler material 344 is not damaged by heat and/or pressure that would otherwise be applied during the sintering, which, in turns, improves a material property of the composition 340 such as a durability and/or a conductivity of the composition 340. However, the present disclosure is not limited thereto.

Blocks 430-432. Referring to block 430 and 432 of FIG. 4C, in some embodiments, the second w % of the filler material 344 is between 0.5 w % and 25 w % within the composition 340, or between 13 w % and 15 w % within the composition.

In some embodiments, the filler material 344 includes between 0.5 w % and 25 w % of the composition 340. For instance, in some embodiments, the interface with the filler material 344 and the second metal material 340-2 includes a composition formed by the filler material 344 combined with the second metal material, in which the filler material 344 includes between 0.5 w % and 25 w % of the composition formed at the interface.

For instance, in some embodiments, the filler material 344 includes a w % of the composition 340 between 0.5 w % and 24 w %, between 0.5 w % and 23 w %, between 0.5 w % and 22 w %, between 0.5 w % and 21 w %, between 0.5 w % and 20 w %, between 0.5 w % and 19 w %, between 0.5 w % and 18 w %, between 0.5 w % and 17 w %, between 0.5 w % and 16 w %, between 0.5 w % and 15 w %, between 0.5 w % and 14 w %, between 0.5 w % and 13 w %, between 0.5 w % and 12 w %, between 0.5 w % and 11 w %, between 0.5 w % and 10 w %, between 0.5 w % and 9 w %, between 0.5 w % and 8 w %, between 0.5 w % and 7 w %, between 0.5 w % and 6 w %, between 0.5 w % and 5 w %, between 0.5 w % and 4 w %, between 0.5 w % and 3 w %, between 0.5 w % and 2 w %, between 0.5 w % and 1 w %, between 2 w % and 24 w %, between 2 w % and 23 w %, between 2 w % and 22 w %, between 2 w % and 21 w %, between 2 w % and 20 w %, between 2 w % and 19 w %, between 2 w % and 18 w %, between 2 w % and 17 w %, between 2 w % and 16 w %, between 2 w % and 15 w %, between 2 w % and 14 w %, between 2 w % and 13 w %, between 2 w % and 12 w %, between 2 w % and 11 w %, between 2 w % and 10 w %, between 2 w % and 9 w %, between 2 w % and 8 w %, between 2 w % and 7 w %, between 2 w % and 6 w %, between 2 w % and 5 w %, between 2 w % and 4 w %, between 2 w % and 3 w %, between 4 w % and 24 w %, between 4 w % and 23 w %, between 4 w % and 22 w %, between 4 w % and 21 w %, between 4 w % and 20 w %, between 4 w % and 19 w %, between 4 w % and 18 w %, between 4 w % and 17 w %, between 4 w % and 16 w %, between 4 w % and 15 w %, between 4 w % and 14 w %, between 4 w % and 13 w %, between 4 w % and 12 w %, between 4 w % and 11 w %, between 4 w % and 10 w %, between 4 w % and 9 w %, between 4 w % and 8 w %, between 4 w % and 7 w %, between 4 w % and 6 w %, between 4 w % and 5 w %, between 6.5 w % and 24 w %, between 6.5 w % and 23 w %, between 6.5 w % and 22 w %, between 6.5 w % and 21 w %, between 6.5 w % and 20 w %, between 6.5 w % and 19 w %, between 6.5 w % and 18 w %, between 6.5 w % and 17 w %, between 6.5 w % and 16 w %, between 6.5 w % and 15 w %, between 6.5 w % and 14 w %, between 6.5 w % and 13 w %, between 6.5 w % and 12 w %, between 6.5 w % and 11 w %, between 6.5 w % and 10 w %, between 6.5 w % and 9 w %, between 6.5 w % and 8 w %, between 6.5 w % and 7 w %, between 9 w % and 24 w %, between 9 w % and 23 w %, between 9 w % and 22 w %, between 9 w % and 21 w %, between 9 w % and 20 w %, between 9 w % and 19 w %, between 9 w % and 18 w %, between 9 w % and 17 w %, between 9 w % and 16 w %, between 9 w % and 15 w %, between 9 w % and 14 w %, between 9 w % and 13 w %, between 9 w % and 12 w %, between 9 w % and 11 w %, between 9 w % and 10 w %, between 13 w % and 24 w %, between 13 w % and 23 w %, between 13 w % and 22 w %, between 13 w % and 21 w %, between 13 w % and 20 w %, between 13 w % and 19 w %, between 13 w % and 18 w %, between 13 w % and 17 w %, between 13 w % and 16 w %, between 13 w % and 15 w %, between 13 w % and 14 w %, between 16 w % and 24 w %, between 16 w % and 23 w %, between 16 w % and 22 w %, between 16 w % and 21 w %, between 16 w % and 20 w %, between 16 w % and 19 w %, between 16 w % and 18 w %, between 16 w % and 17 w %, between 18 w % and 24 w %, between 18 w % and 23 w %, between 18 w % and 22 w %, between 18 w % and 21 w %, between 18 w % and 20 w %, between 18 w % and 19 w %, between 21 w % and 24 w %, between 21 w % and 23 w %, between 21 w % and 22 w %, or between 23 w % and 24 w %.

In some embodiments, the filler material 344 includes a w % of the composition 340 of at least 0.5 w %, at least 1 w %, at least 1.5 w %, at least 2 w %, at least 2.5 w %, at least 3 w %, at least 3.5 w %, at least 4 w %, at least 4.5 w %, at least 5 w %, at least 5.5 w %, at least 6 w %, at least 6.5 w %, at least 7 w %, at least 7.5 w %, at least 8 w %, at least 8.5 w %, at least 9 w %, at least 9.5 w %, at least 10 w %, at least 10.5 w %, at least 11 w %, at least 11.5 w %, at least 12 w %, at least 12.5 w %, at least 13 w %, at least 13.5 w %, at least 14 w %, at least 14.5 w %, at least 15 w %, at least 15.5 w %, at least 16 w %, at least 16.5 w %, at least 17 w %, at least 17.5 w %, at least 18 w %, at least 18.5 w %, at least 19 w %, at least 19.5 w %, at least 20 w %, at least 20.5 w %, at least 21 w %, at least 21.5 w %, at least 22 w %, at least 22.5 w %, at least 23 w %, at least 23.5 w %, at least 24 w %, at least 24.5 w %, or at least 25 w % of the composition 340. In some embodiments, the filler material 344 includes a w % of the composition 340 of at most 0.5 w %, at most 1 w %, at most 1.5 w %, at most 2 w %, at most 2.5 w %, at most 3 w %, at most 3.5 w %, at most 4 w %, at most 4.5 w %, at most 5 w %, at most 5.5 w %, at most 6 w %, at most 6.5 w %, at most 7 w %, at most 7.5 w %, at most 8 w %, at most 8.5 w %, at most 9 w %, at most 9.5 w %, at most 10 w %, at most 10.5 w %, at most 11 w %, at most 11.5 w %, at most 12 w %, at most 12.5 w %, at most 13 w %, at most 13.5 w %, at most 14 w %, at most 14.5 w %, at most 15 w %, at most 15.5 w %, at most 16 w %, at most 16.5 w %, at most 17 w %, at most 17.5 w %, at most 18 w %, at most 18.5 w %, at most 19 w %, at most 19.5 w %, at most 20 w %, at most 20.5 w %, at most 21 w %, at most 21.5 w %, at most 22 w %, at most 22.5 w %, at most 23 w %, at most 23.5 w %, at most 24 w %, at most 24.5 w %, or at most 25 w % of the composition 340.

Block 434. Referring to block 434, in some embodiments, the second w % of the filler material 344 is greater than 15 w % within the composition 340. For instance, in some embodiments, the second w % of the filler material 344 is greater than 15 w %, greater than 15.2 w %, greater than 15.4 w %, greater than 15.6 w %, greater than 15.8 w %, greater than 16 w %, greater than 16.2 w %, greater than 16.4 w %, greater than 16.6 w %, greater than 16.8 w %, greater than 17 w %, greater than 17.2 w %, greater than 17.4 w %, greater than 17.6 w %, greater than 17.8 w %, greater than 18 w %, greater than 18.2 w %, greater than 18.4 w %, greater than 18.6 w %, greater than 18.8 w %, greater than 19 w %, greater than 19.2 w %, greater than 19.4 w %, greater than 19.6 w %, greater than 19.8 w %, greater than 20 w %, greater than 20.2 w %, greater than 20.4 w %, greater than 20.6 w %, greater than 20.8 w %, greater than 21 w %, greater than 21.2 w %, greater than 21.4 w %, greater than 21.6 w %, greater than 21.8 w %, greater than 22 w %, greater than 22.2 w %, greater than 22.4 w %, greater than 22.6 w %, greater than 22.8 w %, greater than 23 w %, greater than 23.2 w %, greater than 23.4 w %, greater than 23.6 w %, greater than 23.8 w %, greater than 24 w %, greater than 24.2 w %, greater than 24.4 w %, greater than 24.6 w %, greater than 24.8 w %, or greater than 25 w % of the composition 340. In some embodiments, the second w % of the filler material 344 is less than 15.2 w %, less than 15.4 w %, less than 15.6 w %, less than 15.8 w %, less than 16 w %, less than 16.2 w %, less than 16.4 w %, less than 16.6 w %, less than 16.8 w %, less than 17 w %, less than 17.2 w %, less than 17.4 w %, less than 17.6 w %, less than 17.8 w %, less than 18 w %, less than 18.2 w %, less than 18.4 w %, less than 18.6 w %, less than 18.8 w %, less than 19 w %, less than 19.2 w %, less than 19.4 w %, less than 19.6 w %, less than 19.8 w %, less than 20 w %, less than 20.2 w %, less than 20.4 w %, less than 20.6 w %, less than 20.8 w %, less than 21 w %, less than 21.2 w %, less than 21.4 w %, less than 21.6 w %, less than 21.8 w %, less than 22 w %, less than 22.2 w %, less than 22.4 w %, less than 22.6 w %, less than 22.8 w %, less than 23 w %, less than 23.2 w %, less than 23.4 w %, less than 23.6 w %, less than 23.8 w %, less than 24 w %, less than 24.2 w %, less than 24.4 w %, less than 24.6 w %, less than 24.8 w %, or less than 25 w % of the composition 340.

Block 436. Referring to block 436, in some embodiments, the first metal material 342 is a solvent of the composition 340. Furthermore, in some embodiments, the filler material 344 is a solute of the composition 340.

Block 438. Referring to block 438, in some embodiments, the method 400 includes coupling the first circuit component 330-1 to the second circuit component 330-2 with the composition 340. In some embodiments, this coupling of the first circuit component 330-1 to the second circuit component 330-2 with the composition 340 forms the interconnect. In some embodiments, the first circuit component 330-1 to the second circuit component 330-2 with the composition 340 is a fixed coupling, such that removal of the coupling between the first circuit component 330-1 and the composition 340 and/or between the second circuit component 330-2 and the composition 340 destroys the electrical communication between the first circuit component 330-1 and the second circuit component 330-2.

In some embodiments, the composition 340 forms when the filler material 344 is oversaturated in excess of a saturation point of the filler material 344 in the first metal material 342 in the composition 340. In some embodiments, the saturation point of the filler material 344 is about 15 w % within the composition 340. In some embodiments, the saturation point is an amount of a first material that is absorbable or dissolvable into a second material, such as a solution in the form the first metal material 340-1.

Block 440. Referring to block 440, in some embodiments, the interconnect formed by the composition 340 has a resistance under at most 100 Ohms per centimeter (Ω/cm), at most 100 Ω/cm, or at most 150 Ω/cm under when the interconnect, including the composition 340, is subjected to 100% strain.

For instance, in some embodiments, the interconnect formed by the composition 340, including the composition 340, is configured to maintain conductivity, including through the composition 340, with a resistance of between 0.1 Ω/cm and 100 Ω/cm, between 0.1 Ω/cm and 90 Ω/cm, between 0.1 Ω/cm and 700 Ω/cm, between 0.1 Ω/cm and 50 Ω/cm, between 0.1 Ω/cm and 40 Ω/cm, between 0.1 Ω/cm and 30 Ω/cm, between 0.1 Ω/cm and 25 Ω/cm, between 0.1 Ω/cm and 20 Ω/cm, between 0.1 Ω/cm and 10 Ω/cm, between 0.1 Ω/cm and 5 Ω/cm, between 0.1 Ω/cm and 3 Ω/cm, between 0.5 Ω/cm and 100 Ω/cm, between 0.5 Ω/cm and 90 Ω/cm, between 0.5 Ω/cm and 70 Ω/cm, between 0.5 Ω/cm and 50 Ω/cm, between 0.5 Ω/cm and 40 Ω/cm, between 0.5 Ω/cm and 30 Ω/cm, between 0.5 Ω/cm and 25 Ω/cm, between 0.5 Ω/cm and 20 Ω/cm, between 0.5 Ω/cm and 10 Ω/cm, between 0.5 Ω/cm and 5 Ω/cm, between 0.5 Ω/cm and 3 Ω/cm, between 1 Ω/cm and 100 Ω/cm, between 1 Ω/cm and 90 Ω/cm, between 1 Ω/cm and 70 Ω/cm, between 1 Ω/cm and 50 Ω/cm, between 1 Ω/cm and 40 Ω/cm, between 1 Ω/cm and 30 Ω/cm, between 1 Ω/cm and 25 Ω/cm, between 1 Ω/cm and 20 Ω/cm, between 1 Ω/cm and 10 Ω/cm, between 1 Ω/cm and 5 Ω/cm, between 1 Ω/cm and 3 Ω/cm, between 2.5 Ω/cm and 100 Ω/cm, between 2.5 Ω/cm and 90 Ω/cm, between 2.5 Ω/cm and 70 Ω/cm, between 2.5 Ω/cm and 50 Ω/cm, between 2.5 Ω/cm and 40 Ω/cm, between 2.5 Ω/cm and 30 Ω/cm, between 2.5 Ω/cm and 25 Ω/cm, between 2.5 Ω/cm and 20 Ω/cm, between 2.5 Ω/cm and 10 Ω/cm, between 2.5 Ω/cm and 5 Ω/cm, between 2.5 Ω/cm and 3 Ω/cm, between 8 Ω/cm and 100 Ω/cm, between 8 Ω/cm and 90 Ω/cm, between 8 Ω/cm and 70 Ω/cm, between 8 Ω/cm and 50 Ω/cm, between 8 Ω/cm and 40 Ω/cm, between 8 Ω/cm and 30 Ω/cm, between 8 Ω/cm and 25 Ω/cm, between 8 Ω/cm and 20 Ω/cm, between 8 Ω/cm and 10 Ω/cm, between 13 Ω/cm and 100 Ω/cm, between 13 Ω/cm and 90 Ω/cm, between 13 Ω/cm and 70 Ω/cm, between 13 Ω/cm and 50 Ω/cm, between 13 Ω/cm and 40 Ω/cm, between 13 Ω/cm and 30 Ω/cm, between 13 Ω/cm and 25 Ω/cm, between 13 Ω/cm and 20 Ω/cm, between 25 Ω/cm and 100 Ω/cm, between 25 Ω/cm and 90 Ω/cm, between 25 Ω/cm and 70 Ω/cm, between 25 Ω/cm and 50 Ω/cm, between 25 Ω/cm and 40 Ω/cm, between 25 Ω/cm and 30 Ω/cm, between 45 Ω/cm and 100 Ω/cm, between 45 Ω/cm and 90 Ω/cm, between 45 Ω/cm and 70 Ω/cm, between 45 Ω/cm and 50 Ω/cm, between 60 Ω/cm and 100 Ω/cm, between 60 Ω/cm and 90 Ω/cm, between 60 Ω/cm and 70 Ω/cm, between 85 Ω/cm and 100 Ω/cm, or between 85 Ω/cm and 90 Ω/cm when subjected to 100% strain.

In some embodiments, the interconnect formed by the composition 340, including the composition 340, is configured to maintain conductivity, including through the composition 340, with a resistance of at least 0.1 Ω/cm, at least 0.4 Ω/cm, at least 0.8 Ω/cm, at least 1 Ω/cm, at least 1.5 Ω/cm, at least 2 Ω/cm, at least 2.5 Ω/cm, at least 3 Ω/cm, at least 3.5 Ω/cm, at least 4 Ω/cm, at least 4.5 Ω/cm, at least 5 Ω/cm, at least 5.5 Ω/cm, at least 6 Ω/cm, at least 6.5 Ω/cm, at least 7 Ω/cm, at least 7.5 Ω/cm, at least 8 Ω/cm, at least 8.5 Ω/cm, at least 9 Ω/cm, at least 9.5 Ω/cm, at least 10 Ω/cm, at least 10.5 Ω/cm, at least 11 Ω/cm, at least 11.5 Ω/cm, at least 12 Ω/cm, at least 12.5 Ω/cm, at least 13 Ω/cm, at least 13.5 Ω/cm, at least 14 Ω/cm, at least 14.5 Ω/cm, at least 15 Ω/cm, at least 15.5 Ω/cm, at least 16 Ω/cm, at least 16.5 Ω/cm, at least 17 Ω/cm, at least 17.5 Ω/cm, at least 18 Ω/cm, at least 18.5 Ω/cm, at least 19 Ω/cm, at least 19.5 Ω/cm, at least 20 Ω/cm, at least 20.5 Ω/cm, at least 21 Ω/cm, at least 21.5 Ω/cm, at least 22 Ω/cm, at least 22.5 Ω/cm, at least 23 Ω/cm, at least 23.5 Ω/cm, at least 24 Ω/cm, at least 24.5 Ω/cm, at least 25 Ω/cm, at least 25.5 Ω/cm, at least 26 Ω/cm, at least 26.5 Ω/cm, at least 27 Ω/cm, at least 27.5 Ω/cm, at least 28 Ω/cm, at least 28.5 Ω/cm, at least 29 Ω/cm, at least 29.5 Ω/cm, at least 30 Ω/cm, at least 30.5 Ω/cm, at least 31 Ω/cm, at least 31.5 Ω/cm, at least 32 Ω/cm, at least 32.5 Ω/cm, at least 33 Ω/cm, at least 33.5 Ω/cm, at least 34 Ω/cm, at least 34.5 Ω/cm, at least 35 Ω/cm, at least 35.5 Ω/cm, at least 36 Ω/cm, at least 36.5 Ω/cm, at least 37 Ω/cm, at least 37.5 Ω/cm, at least 38 Ω/cm, at least 38.5 Ω/cm, at least 39 Ω/cm, at least 39.5 Ω/cm, at least 40 Ω/cm, at least 40.5 Ω/cm, at least 41 Ω/cm, at least 41.5 Ω/cm, at least 42 Ω/cm, at least 42.5 Ω/cm, at least 43 Ω/cm, at least 43.5 Ω/cm, at least 44 Ω/cm, at least 44.5 Ω/cm, at least 45 Ω/cm, at least 45.5 Ω/cm, at least 46 Ω/cm, at least 46.5 Ω/cm, at least 47 Ω/cm, at least 47.5 Ω/cm, at least 48 Ω/cm, at least 48.5 Ω/cm, at least 49 Ω/cm, at least 49.5 Ω/cm, at least 50 Ω/cm, at least 50.5 Ω/cm, at least 51 Ω/cm, at least 51.5 Ω/cm, at least 52 Ω/cm, at least 52.5 Ω/cm, at least 53 Ω/cm, at least 53.5 Ω/cm, at least 54 Ω/cm, at least 54.5 Ω/cm, at least 55 Ω/cm, at least 55.5 Ω/cm, at least 56 Ω/cm, at least 56.5 Ω/cm, at least 57 Ω/cm, at least 57.5 Ω/cm, at least 58 Ω/cm, at least 58.5 Ω/cm, at least 59 Ω/cm, at least 59.5 Ω/cm, at least 60 Ω/cm, at least 60.5 Ω/cm, at least 61 Ω/cm, at least 61.5 Ω/cm, at least 62 Ω/cm, at least 62.5 Ω/cm, at least 63 Ω/cm, at least 63.5 Ω/cm, at least 64 Ω/cm, at least 64.5 Ω/cm, at least 65 Ω/cm, at least 65.5 Ω/cm, at least 66 Ω/cm, at least 66.5 Ω/cm, at least 67 Ω/cm, at least 67.5 Ω/cm, at least 68 Ω/cm, at least 68.5 Ω/cm, at least 69 Ω/cm, at least 69.5 Ω/cm, at least 70 Ω/cm, at least 70.5 Ω/cm, at least 71 Ω/cm, at least 71.5 Ω/cm, at least 72 Ω/cm, at least 72.5 Ω/cm, at least 73 Ω/cm, at least 73.5 Ω/cm, at least 74 Ω/cm, at least 74.5 Ω/cm, at least 75 Ω/cm, at least 75.5 Ω/cm, at least 76 Ω/cm, at least 76.5 Ω/cm, at least 77 Ω/cm, at least 77.5 Ω/cm, at least 78 Ω/cm, at least 78.5 Ω/cm, at least 79 Ω/cm, at least 79.5 Ω/cm, at least 80 Ω/cm, at least 80.5 Ω/cm, at least 81 Ω/cm, at least 81.5 Ω/cm, at least 82 Ω/cm, at least 82.5 Ω/cm, at least 83 Ω/cm, at least 83.5 Ω/cm, at least 84 Ω/cm, at least 84.5 Ω/cm, at least 85 Ω/cm, at least 85.5 Ω/cm, at least 86 Ω/cm, at least 86.5 Ω/cm, at least 87 Ω/cm, at least 87.5 Ω/cm, at least 88 Ω/cm, at least 88.5 Ω/cm, at least 89 Ω/cm, at least 89.5 Ω/cm, at least 90 Ω/cm, at least 90.5 Ω/cm, at least 91 Ω/cm, at least 91.5 Ω/cm, at least 92 Ω/cm, at least 92.5 Ω/cm, at least 93 Ω/cm, at least 93.5 Ω/cm, at least 94 Ω/cm, at least 94.5 Ω/cm, at least 95 Ω/cm, at least 95.5 Ω/cm, at least 96 Ω/cm, at least 96.5 Ω/cm, at least 97 Ω/cm, at least 97.5 Ω/cm, at least 98 Ω/cm, at least 98.5 Ω/cm, at least 99 Ω/cm, at least 99.5 Ω/cm, or at least 100 Ω/cm when subjected to 100% strain.

In some embodiments, the interconnect formed by the composition 340, including the composition 340, is configured to maintain conductivity, including through the composition 340, with a resistance of at most 0.1 Ω/cm, at most 0.4 Ω/cm, at most 0.8 Ω/cm, at most 1 Ω/cm, at most 1.5 Ω/cm, at most 2 Ω/cm, at most 2.5 Ω/cm, at most 3 Ω/cm, at most 3.5 Ω/cm, at most 4 Ω/cm, at most 4.5 Ω/cm, at most 5 Ω/cm, at most 5.5 Ω/cm, at most 6 Ω/cm, at most 6.5 Ω/cm, at most 7 Ω/cm, at most 7.5 Ω/cm, at most 8 Ω/cm, at most 8.5 Ω/cm, at most 9 Ω/cm, at most 9.5 Ω/cm, at most 10 Ω/cm, at most 10.5 Ω/cm, at most 11 Ω/cm, at most 11.5 Ω/cm, at most 12 Ω/cm, at most 12.5 Ω/cm, at most 13 Ω/cm, at most 13.5 Ω/cm, at most 14 Ω/cm, at most 14.5 Ω/cm, at most 15 Ω/cm, at most 15.5 Ω/cm, at most 16 Ω/cm, at most 16.5 Ω/cm, at most 17 Ω/cm, at most 17.5 Ω/cm, at most 18 Ω/cm, at most 18.5 Ω/cm, at most 19 Ω/cm, at most 19.5 Ω/cm, at most 20 Ω/cm, at most 20.5 Ω/cm, at most 21 Ω/cm, at most 21.5 Ω/cm, at most 22 Ω/cm, at most 22.5 Ω/cm, at most 23 Ω/cm, at most 23.5 Ω/cm, at most 24 Ω/cm, at most 24.5 Ω/cm, at most 25 Ω/cm, at most 25.5 Ω/cm, at most 26 Ω/cm, at most 26.5 Ω/cm, at most 27 Ω/cm, at most 27.5 Ω/cm, at most 28 Ω/cm, at most 28.5 Ω/cm, at most 29 Ω/cm, at most 29.5 Ω/cm, at most 30 Ω/cm, at most 30.5 Ω/cm, at most 31 Ω/cm, at most 31.5 Ω/cm, at most 32 Ω/cm, at most 32.5 Ω/cm, at most 33 Ω/cm, at most 33.5 Ω/cm, at most 34 Ω/cm, at most 34.5 Ω/cm, at most 35 Ω/cm, at most 35.5 Ω/cm, at most 36 Ω/cm, at most 36.5 Ω/cm, at most 37 Ω/cm, at most 37.5 Ω/cm, at most 38 Ω/cm, at most 38.5 Ω/cm, at most 39 Ω/cm, at most 39.5 Ω/cm, at most 40 Ω/cm, at most 40.5 Ω/cm, at most 41 Ω/cm, at most 41.5 Ω/cm, at most 42 Ω/cm, at most 42.5 Ω/cm, at most 43 Ω/cm, at most 43.5 Ω/cm, at most 44 Ω/cm, at most 44.5 Ω/cm, at most 45 Ω/cm, at most 45.5 Ω/cm, at most 46 Ω/cm, at most 46.5 Ω/cm, at most 47 Ω/cm, at most 47.5 Ω/cm, at most 48 Ω/cm, at most 48.5 Ω/cm, at most 49 Ω/cm, at most 49.5 Ω/cm, at most 50 Ω/cm, at most 50.5 Ω/cm, at most 51 Ω/cm, at most 51.5 Ω/cm, at most 52 Ω/cm, at most 52.5 Ω/cm, at most 53 Ω/cm, at most 53.5 Ω/cm, at most 54 Ω/cm, at most 54.5 Ω/cm, at most 55 Ω/cm, at most 55.5 Ω/cm, at most 56 Ω/cm, at most 56.5 Ω/cm, at most 57 Ω/cm, at most 57.5 Ω/cm, at most 58 Ω/cm, at most 58.5 Ω/cm, at most 59 Ω/cm, at most 59.5 Ω/cm, at most 60 Ω/cm, at most 60.5 Ω/cm, at most 61 Ω/cm, at most 61.5 Ω/cm, at most 62 Ω/cm, at most 62.5 Ω/cm, at most 63 Ω/cm, at most 63.5 Ω/cm, at most 64 Ω/cm, at most 64.5 Ω/cm, at most 65 Ω/cm, at most 65.5 Ω/cm, at most 66 Ω/cm, at most 66.5 Ω/cm, at most 67 Ω/cm, at most 67.5 Ω/cm, at most 68 Ω/cm, at most 68.5 Ω/cm, at most 69 Ω/cm, at most 69.5 Ω/cm, at most 70 Ω/cm, at most 70.5 Ω/cm, at most 71 Ω/cm, at most 71.5 Ω/cm, at most 72 Ω/cm, at most 72.5 Ω/cm, at most 73 Ω/cm, at most 73.5 Ω/cm, at most 74 Ω/cm, at most 74.5 Ω/cm, at most 75 Ω/cm, at most 75.5 Ω/cm, at most 76 Ω/cm, at most 76.5 Ω/cm, at most 77 Ω/cm, at most 77.5 Ω/cm, at most 78 Ω/cm, at most 78.5 Ω/cm, at most 79 Ω/cm, at most 79.5 Ω/cm, at most 80 Ω/cm, at most 80.5 Ω/cm, at most 81 Ω/cm, at most 81.5 Ω/cm, at most 82 Ω/cm, at most 82.5 Ω/cm, at most 83 Ω/cm, at most 83.5 Ω/cm, at most 84 Ω/cm, at most 84.5 Ω/cm, at most 85 Ω/cm, at most 85.5 Ω/cm, at most 86 Ω/cm, at most 86.5 Ω/cm, at most 87 Ω/cm, at most 87.5 Ω/cm, at most 88 Ω/cm, at most 88.5 Ω/cm, at most 89 Ω/cm, at most 89.5 Ω/cm, at most 90 Ω/cm, at most 90.5 Ω/cm, at most 91 Ω/cm, at most 91.5 Ω/cm, at most 92 Ω/cm, at most 92.5 Ω/cm, at most 93 Ω/cm, at most 93.5 Ω/cm, at most 94 Ω/cm, at most 94.5 Ω/cm, at most 95 Ω/cm, at most 95.5 Ω/cm, at most 96 Ω/cm, at most 96.5 Ω/cm, at most 97 Ω/cm, at most 97.5 Ω/cm, at most 98 Ω/cm, at most 98.5 Ω/cm, at most 99 Ω/cm, at most 99.5 Ω/cm, or at most 100 Ω/cm when subjected to 100% strain.

In some embodiments, the strain (ε) is defined as a function of a change in a gauge length (δ) against an original gauge length (L), such as: ε=δ/L. For instance, in some embodiments, a strain of X % means a ratio in a change in length of the deformable substrate 302 along a first axis, a second axis, a third axis, or a combination thereof, in which the first axis, the second axis, and the third axis are mutually perpendicular. In some embodiments, the first axis is parallel to the direction of a maximum elongation of the deformable substrate 302, the second axis is parallel to the direction of a minimum elongation of the deformable substrate 302, and the third axis is parallel to the direction of an intermediate elongation of the deformable substrate 302. As a non-limiting example, if an original length of the deformable substrate is 10 centimeters (cm) and is subjected to 100% strain to stretch to a new length of 20 cm along the first axis.

In some embodiments, the interconnect is free of degradation in conductivity when the deformable substrate 302 is bent, such as bent around a cylinder. In some embodiments, the interconnect is free of degradation in conductivity when the deformable substrate 302 is that has a radius of between 2 centimeters (cm) and 10 cm, between 2 cm and 8 cm, between 2 cm and 6 cm, between 2 cm and 4 cm, 4 cm and 10 cm, between 4 cm and 8 cm, between 4 cm and 6 cm, between 6 cm and 10 cm, between 6 cm and 8 cm, or between 8 cm and 10 cm for a period of time and then released. In some embodiments, the radius of the cylinder is at least 2 cm, at least 3 cm, at least 4 cm, at least 5 cm, at least 6 cm, at least 7 cm, at least 8 cm, at least 9 cm, or at least 10 cm. In some embodiments, the radius of the cylinder is at most 2 cm, at most 3 cm, at most 4 cm, at most 5 cm, at most 6 cm, at most 7 cm, at most 8 cm, at most 9 cm, or at most 10 cm.

In some embodiments, the period of time is between 10 seconds and 5 minutes, between 10 seconds and 4 minutes, between 10 seconds and 3 minutes, between 10 seconds and 2 minutes, between 10 seconds and 1 minute, between 10 seconds and 30 seconds, between 30 seconds and 5 minutes, between 10 seconds and 4 minutes, between 10 seconds and 3 minutes, between 10 seconds and 2 minutes, between 10 seconds and 1 minute, between 1 minute and 5 minutes, between 1 minute and 4 minutes, between 1 minute and 3 minutes, between 1 minute and 2 minutes, or between 3 minutes and 5 minutes. In some embodiments, the period of time is at least 10 seconds, at least 20 seconds, at least 30 seconds, at least 60 seconds, at least 1.5 minutes, at least 2 minutes, at least 2.5 minutes, at least 3 minutes, at least 3.5 minutes, at least 4 minutes, at least 4.5 minutes, or at least 5 minutes. In some embodiments, the period of time is at most 10 seconds, at most 20 seconds, at most 30 seconds, at most 60 seconds, at most 1.5 minutes, at most 2 minutes, at most 2.5 minutes, at most 3 minutes, at most 3.5 minutes, at most 4 minutes, at most 4.5 minutes, or at most 5 minutes.

In some embodiments, the interconnect is free of degradation in conductivity when a first conductivity of the interconnect before bending and a second conductivity of the interconnect after or during bending is substantially the same. For instance, in some embodiments, the interconnect is free of degradation when the second conductivity satisfies a threshold ratio in comparison against the first conductivity of the interconnect. In some embodiments, the threshold ratio is between 0.99 and 1.01, between 0.995 and 1.005, or between 0.999 and 1.001. In some embodiments, the threshold ratio is at least 0.95, at least 0.96, at least 0.97, at least 0.98, at least 0.99, at least 0.999, at least 0.9999, at least 1, at least 1.0001, at least 1.001, at least 1.01, at least 1.02, at least 1.03, at least 1.04, at least 1.05, or at least 1.1. In some embodiments, the threshold ratio is at most 0.95, at most 0.96, at most 0.97, at most 0.98, at most 0.99, at most 0.999, at most 0.9999, at most 1, at most 1.0001, at most 1.001, at most 1.01, at most 1.02, at most 1.03, at most 1.04, at most 1.05, or at most 1.1.

Block 442. Referring to block 442, in some embodiments, the interconnect formed by the composition 340 maintains conductivity, including through the composition 340, when subjected to at least 15,000 strain cycles. In some embodiments, the interconnect formed by the composition 340 maintains conductivity when subjected to the second strain cycle.

Furthermore, in some embodiments, the interconnect formed by the composition 340 maintains conductivity, including through the composition 340, when at a temperature between 10° C. and 40° C., between 10° C. and 36° C., between 10° C. and 32° C., between 10° C. and 28° C., between 10° C. and 24° C., between 10° C. and 20° C., between 10° C. and 16° C., between 10° C. and 12° C., between 14° C. and 40° C., between 14° C. and 36° C., between 14° C. and 32° C., between 14° C. and 28° C., between 14° C. and 24° C., between 14° C. and 20° C., between 14° C. and 16° C., between 18° C. and 40° C., between 18° C. and 36° C., between 18° C. and 32° C., between 18° C. and 28° C., between 18° C. and 24° C., between 18° C. and 20° C., between 22° C. and 40° C., between 22° C. and 36° C., between 22° C. and 32° C., between 22° C. and 28° C., between 22° C. and 24° C., between 26° C. and 40° C., between 26° C. and 36° C., between 26° C. and 32° C., between 26° C. and 28° C., between 30° C. and 40° C., between 30° C. and 36° C., between 30° C. and 32° C., between 30° C. and 28° C., between 30° C. and 24° C., between 30° C. and 20° C., between 30° C. and 16° C., between 30° C. and 12° C., between 34° C. and 40° C., between 34° C. and 36° C., or between 38° C. and 40° C.

In some embodiments, the interconnect formed by the composition 340 maintains conductivity, including through the composition 340, when at a temperature of at least 10° C., at least 11° C., at least 12° C., at least 13° C., at least 14° C., at least 15° C., at least 16° C., at least 17° C., at least 18° C., at least 19° C., at least 20° C., at least 21° C., at least 22° C., at least 23° C., at least 24° C., at least 25° C., at least 26° C., at least 27° C., at least 28° C., at least 29° C., at least 30° C., at least 31° C., at least 32° C., at least 33° C., at least 34° C., at least 35° C., at least 36° C., at least 37° C., at least 38° C., at least 39° C., or at least 40° C. In some embodiments, the interconnect formed by the composition 340 maintains conductivity when at a temperature of at most 10° C., at most 11° C., at most 12° C., at most 13° C., at most 14° C., at most 15° C., at most 16° C., at most 17° C., at most 18° C., at most 19° C., at most 20° C., at most 21° C., at most 22° C., at most 23° C., at most 24° C., at most 25° C., at most 26° C., at most 27° C., at most 28° C., at most 29° C., at most 30° C., at most 31° C., at most 32° C., at most 33° C., at most 34° C., at most 35° C., at most 36° C., at most 37° C., at most 38° C., at most 39° C., or at most 40° C.

Block 444. Referring to block 444 of FIG. 4D, in some embodiments, the interconnect formed by the composition 340 has a resistance under at most 50 Ω/cm when the interconnect is subjected to 100% strain at a first strain cycle, and under at most 50 Ω/cm when subjected to 100% strain at a second strain cycle. In some embodiments, the interconnect formed by the composition 340 has a resistance under at most 100 Ω/cm when the interconnect is subjected to 100% strain at the first strain cycle, and under at most 100 Ω/cm when subjected to 100% strain at the second strain cycle. In some embodiments, the interconnect formed by the composition 340 has a resistance under at most 150 Ω/cm when the interconnect is subjected to 100% strain at the first strain cycle, and under at most 150 Ω/cm when subjected to 100% strain at the second strain cycle.

Block 446. Referring to block 446, in some embodiments, the second strain cycle is at least 15,000 strain cycles greater than the first strain cycle. In some embodiments, the first strain cycle is one cycle (e.g., a single cycle). In some embodiments, the second strain cycle includes between 2 strain cycles and 30,000 strain cycles, between 2 strain cycles and 20,000 strain cycles, between 2 strain cycles and 15,000 strain cycles, between 2 strain cycles and 10,000 strain cycles, between 2 strain cycles and 6,000 strain cycles, between 2 strain cycles and 4,000 strain cycles, between 2 strain cycles and 1,000 strain cycles, between 2 strain cycles and 700 strain cycles, between 2 strain cycles and 500 strain cycles, between 2 strain cycles and 100 strain cycles, between 50 strain cycles and 30,000 strain cycles, between 50 strain cycles and 20,000 strain cycles, between 50 strain cycles and 15,000 strain cycles, between 50 strain cycles and 10,000 strain cycles, between 50 strain cycles and 6,000 strain cycles, between 50 strain cycles and 4,000 strain cycles, between 50 strain cycles and 1,000 strain cycles, between 50 strain cycles and 700 strain cycles, between 50 strain cycles and 500 strain cycles, between 50 strain cycles and 100 strain cycles, between 850 strain cycles and 30,000 strain cycles, between 850 strain cycles and 20,000 strain cycles, between 850 strain cycles and 15,000 strain cycles, between 850 strain cycles and 10,000 strain cycles, between 850 strain cycles and 6,000 strain cycles, between 850 strain cycles and 4,000 strain cycles, between 850 strain cycles and 1,000 strain cycles, between 2,000 strain cycles and 30,000 strain cycles, between 2,000 strain cycles and 20,000 strain cycles, between 2,000 strain cycles and 15,000 strain cycles, between 2,000 strain cycles and 10,000 strain cycles, between 2,000 strain cycles and 6,000 strain cycles, between 2,000 strain cycles and 4,000 strain cycles, between 7,000 strain cycles and 30,000 strain cycles, between 7,000 strain cycles and 20,000 strain cycles, between 7,000 strain cycles and 15,000 strain cycles, between 7,000 strain cycles and 10,000 strain cycles, between 12,000 strain cycles and 30,000 strain cycles, between 12,000 strain cycles and 20,000 strain cycles, between 12,000 strain cycles and 15,000 strain cycles, between 17,000 strain cycles and 30,000 strain cycles, or between 17,000 strain cycles and 20,000 strain cycles.

In some embodiments, the second strain cycle includes at least 10 cycles, at least 50 cycles, at least 100 cycles, at least 200 cycles, at least 500 cycles, at least 1,000 cycles, at least 2,000 cycles, at least 3,000 cycles, at least 4,000 cycles, at least 5,000 cycles, at least 6,000 cycles, at least 7,000 cycles, at least 8,000 cycles, at least 9,000 cycles, at least 10,000 cycles, at least 11,000 cycles, at least 12,000 cycles, at least 13,000 cycles, at least 14,000 cycles, at least 15,000 cycles, at least 16,000 cycles, at least 17,000 cycles, at least 18,000 cycles, at least 19,000 cycles, at least 20,000 cycles, at least 21,000 cycles, at least 22,000 cycles, at least 23,000 cycles, at least 24,000 cycles, at least 25,000 cycles, at least 26,000 cycles, at least 27,000 cycles, at least 28,000 cycles, at least 29,000 cycles, or at least 30,000 cycles. In some embodiments, the second strain cycle includes at most 10 cycles, at most 50 cycles, at most 100 cycles, at most 200 cycles, at most 500 cycles, at most 1,000 cycles, at most 2,000 cycles, at most 3,000 cycles, at most 4,000 cycles, at most 5,000 cycles, at most 6,000 cycles, at most 7,000 cycles, at most 8,000 cycles, at most 9,000 cycles, at most 10,000 cycles, at most 11,000 cycles, at most 12,000 cycles, at most 13,000 cycles, at most 14,000 cycles, at most 15,000 cycles, at most 16,000 cycles, at most 17,000 cycles, at most 18,000 cycles, at most 19,000 cycles, at most 20,000 cycles, at most 21,000 cycles, at most 22,000 cycles, at most 23,000 cycles, at most 24,000 cycles, at most 25,000 cycles, at most 26,000 cycles, at most 27,000 cycles, at most 28,000 cycles, at most 29,000 cycles, or at most 30,000 cycles.

In some embodiments, a cycle is completed when the deformable substrate 302, including the composition 340, satisfies a threshold strain. In some embodiments, the threshold strain is between 25% and 200%, between 25% and 195%, between 25% and 190%, between 25% and 185%, between 25% and 180%, between 25% and 175%, between 25% and 170%, between 25% and 165%, between 25% and 160%, between 25% and 155%, between 25% and 150%, between 25% and 145%, between 25% and 140%, between 25% and 135%, between 25% and 130%, between 25% and 125%, between 25% and 120%, between 25% and 115%, between 25% and 110%, between 25% and 105%, between 25% and 100%, between 25% and 95%, between 25% and 90%, between 25% and 85%, between 25% and 80%, between 25% and 75%, between 25% and 70%, between 25% and 65%, between 25% and 60%, between 25% and 55%, between 25% and 50%, between 25% and 100%, between 25% and 95%, between 25% and 90%, between 25% and 85%, between 25% and 80%, between 25% and 75%, between 25% and 70%, between 25% and 65%, between 25% and 60%, between 25% and 55%, between 25% and 50%, between 35% and 200%, between 35% and 195%, between 35% and 190%, between 35% and 185%, between 35% and 180%, between 35% and 175%, between 35% and 170%, between 35% and 165%, between 35% and 160%, between 35% and 155%, between 35% and 150%, between 35% and 145%, between 35% and 140%, between 35% and 135%, between 35% and 130%, between 35% and 125%, between 35% and 120%, between 35% and 115%, between 35% and 110%, between 35% and 105%, between 35% and 100%, between 35% and 95%, between 35% and 90%, between 35% and 85%, between 35% and 80%, between 35% and 75%, between 35% and 70%, between 35% and 65%, between 35% and 60%, between 35% and 55%, between 35% and 50%, between 45% and 200%, between 45% and 195%, between 45% and 190%, between 45% and 185%, between 45% and 180%, between 45% and 175%, between 45% and 170%, between 45% and 165%, between 45% and 160%, between 45% and 155%, between 45% and 150%, between 45% and 145%, between 45% and 140%, between 45% and 135%, between 45% and 130%, between 45% and 125%, between 45% and 120%, between 45% and 115%, between 45% and 110%, between 45% and 105%, between 45% and 100%, between 45% and 95%, between 45% and 90%, between 45% and 85%, between 45% and 80%, between 45% and 75%, between 45% and 70%, between 45% and 65%, between 45% and 60%, between 45% and 55%, between 45% and 50%, between 55% and 200%, between 55% and 195%, between 55% and 190%, between 55% and 185%, between 55% and 180%, between 55% and 175%, between 55% and 170%, between 55% and 165%, between 55% and 160%, between 55% and 155%, between 55% and 150%, between 55% and 145%, between 55% and 140%, between 55% and 135%, between 55% and 130%, between 55% and 125%, between 55% and 120%, between 55% and 115%, between 55% and 110%, between 55% and 105%, between 55% and 100%, between 55% and 95%, between 55% and 90%, between 55% and 85%, between 55% and 80%, between 55% and 75%, between 55% and 70%, between 55% and 65%, between 55% and 60%, between 65% and 200%, between 65% and 195%, between 65% and 190%, between 65% and 185%, between 65% and 180%, between 65% and 175%, between 65% and 170%, between 65% and 165%, between 65% and 160%, between 65% and 155%, between 65% and 150%, between 65% and 145%, between 65% and 140%, between 65% and 135%, between 65% and 130%, between 65% and 125%, between 65% and 120%, between 65% and 115%, between 65% and 110%, between 65% and 105%, between 65% and 100%, between 65% and 95%, between 65% and 90%, between 65% and 85%, between 65% and 80%, between 65% and 75%, between 65% and 70%, between 75% and 200%, between 75% and 195%, between 75% and 190%, between 75% and 185%, between 75% and 180%, between 75% and 175%, between 75% and 170%, between 75% and 165%, between 75% and 160%, between 75% and 155%, between 75% and 150%, between 75% and 145%, between 75% and 140%, between 75% and 135%, between 75% and 130%, between 75% and 125%, between 75% and 120%, between 75% and 115%, between 75% and 110%, between 75% and 105%, between 75% and 100%, between 75% and 95%, between 75% and 90%, between 75% and 85%, between 75% and 80%, between 85% and 200%, between 85% and 195%, between 85% and 190%, between 85% and 185%, between 85% and 180%, between 85% and 175%, between 85% and 170%, between 85% and 165%, between 85% and 160%, between 85% and 155%, between 85% and 150%, between 85% and 145%, between 85% and 140%, between 85% and 135%, between 85% and 130%, between 85% and 125%, between 85% and 120%, between 85% and 115%, between 85% and 110%, between 85% and 105%, between 85% and 100%, between 85% and 95%, between 85% and 90%, between 95% and 200%, between 95% and 195%, between 95% and 190%, between 95% and 185%, between 95% and 180%, between 95% and 175%, between 95% and 170%, between 95% and 165%, between 95% and 160%, between 95% and 155%, between 95% and 150%, between 95% and 145%, between 95% and 140%, between 95% and 135%, between 95% and 130%, between 95% and 125%, between 95% and 120%, between 95% and 115%, between 95% and 110%, between 95% and 105%, between 95% and 100%, between 140% and 200%, between 140% and 195%, between 140% and 190%, between 140% and 185%, between 140% and 180%, between 140% and 175%, between 140% and 170%, between 140% and 165%, between 140% and 160%, between 140% and 155%, between 140% and 150%, between 140% and 145%, between 180% and 200%, between 180% and 195%, between 180% and 190%, or between 180% and 185%.

In some embodiments, the threshold strain is at least 25%, at least 30%, at least 35%, at least 40%, at least 45%, at least 50%, at least 55%, at least 60%, at least 65%, at least 70%, at least 75%, at least 80%, at least 85%, at least 90%, at least 95%, at least 99%, or at least 100%, at least 125%, at least 130%, at least 135%, at least 140%, at least 145%, at least 150%, at least 155%, at least 160%, at least 165%, at least 170%, at least 175%, at least 180%, at least 185%, at least 190%, at least 195%, at least 199%, or at least 200%. In some embodiments, the threshold strain is at most 25%, at most 30%, at most 35%, at most 40%, at most 45%, at most 50%, at most 55%, at most 60%, at most 65%, at most 70%, at most 75%, at most 80%, at most 85%, at most 90%, at most 95%, at most 99%, at most 100%, at most 125%, at most 130%, at most 135%, at most 140%, at most 145%, at most 150%, at most 155%, at most 160%, at most 165%, at most 170%, at most 175%, at most 180%, at most 185%, at most 190%, at most 195%, at most 199%, or at most 200%.

Block 448. Referring to block 448, in some embodiments, the method 400 includes disposing the composition 340 between the first circuit component 330-1 and second component. In some embodiments, the composition 340 is disposed using a source for the composition 340, such as a reservoir configured to retain a supple of the composition 340 or spool of filament of the composition 340. In some embodiments, the composition 340 is disposed such that, at a temperature between 64° F. and 72° F., the composition 340 has a viscosity that is between 0.5 Pa·s and 1.6 Pa·s. In some embodiments, this disposing of the composition forms the interconnect between the first circuit component 330-1 and the second circuit component 330-2.

Block 450. Referring to block 450, in some embodiments, the composition 340 further includes a dispersant material different from the first metal material 342 and the filler material 344. For instance, in some embodiments, the dispersant material is configured to prevent cohesion of the filler material 344 within the first metal material 342, such as preventing agglomeration of the filler material within the composition 340.

Block 452. Referring to block 452, in some embodiments, the composition 340 includes a contact angle of less than 90 degrees (°) when interfacing with the deformable substrate 302. In some embodiments, the composition 340 is required to have a threshold contact angle in order to wet a surface of the deformable substrate 302. For instance, in some embodiments, when a first contact angle of the composition 340 when interfacing with the deformable substrate 302 is greater than a second contact angle of the composition 340 when interfacing with the deformable substrate 302, the second contact angle is said to have improved wettability in comparison to the first contact angle. In some embodiments, the threshold contact angle is between 0° and 115°, between 0° and 110°, between 0° and 105°, between 0° and 100°, between 0° and 95°, between 0° and 90°, between 0° and 85°, between 0° and 80°, between 0° and 75°, between 0° and 70°, between 0° and 65°, between 0° and 60°, between 0° and 55° between 0° and 50° between 0° and 45° between 0° and 40° between 0° and 35°, between 0° and 30°, between 0° and 25°, between 0° and 20°, between 0° and 15 between 0° and 10°, between 0° and 5°, between 5° and 115°, between 5° and 110°, between 5° and 105°, between 5° and 100°, between 5° and 95°, between 5° and 90°, between 5° and 85°, between 5° and 80°, between 5° and 75°, between 5° and 70°, between 5° and 65°, between 5° and 60° between 5° and 55° between 5° and 50° between 5° and 45°, between 5° and 40°, between 5° and 35°, between 5° and 30°, between 5° and 25°, between 5° and 20°, between 5° and 15°, between 5° and 10°, between 10° and 115°, between 10° and 110°, between 10° and 105°, between 10° and 100°, between 10° and 95 between 10° and 90° between 10° and 85° between 10° and 80° between 10° and 75 between 10° and 70° between 10° and 65° between 10° and 60° between 10° and 55 between 10° and 50° between 10° and 45° between 10° and 40° between 10° and 35° between 10° and 30° between 10° and 25° between 10° and 20° between 10° and 15 between 15° and 115°, between 15° and 110°, between 15° and 105°, between 15° and 100°, between 15° and 95°, between 15° and 90°, between 15° and 85°, between 15° and 80° between 15° and 75° between 15° and 70° between 15° and 65° between 15° and 60° between 15° and 55° between 15° and 50° between 15° and 45° between 15° and 40° between 15° and 35° between 15° and 30° between 15° and 25° between 15° and 20°, between 20° and 115° between 20° and 110°, between 20° and 105°, between 20° and 100°, between 20° and 95° between 20° and 90°, between 20° and 85°, between 20° and 80° between 20° and 75° between 20° and 70° between 20° and 65° between 20° and 60° between 20° and 55° between 20° and 50° between 20° and 45° between 20° and 40° between 20° and 35° between 20° and 30° between 20° and 25° between 25° and 115°, between 25° and 110°, between 25° and 105° between 25° and 100° between 25° and 95°, between 25° and 90°, between 25° and 85° between 25° and 80° between 25° and 75° between 25° and 70° between 25° and 65° between 25° and 60° between 25° and 55° between 25° and 50° between 25° and 45° between 25° and 40° between 25° and 35° between 25° and 30° between 30° and 115°, between 30° and 110°, between 30° and 105°, between 30° and 100°, between 30° and 95°, between 30° and 90° between 30° and 85° between 30° and 80° between 30° and 75° between 30° and 70° between 30° and 65° between 30° and 60° between 30° and 55° between 30° and 50° between 30° and 45° between 30° and 400, between 30° and 35° between 35° and 115°, between 35° and 110°, between 35° and 105°, between 35° and 100°, between 35° and 95°, between 35° and 90° between 35° and 85° between 35° and 80° between 35° and 75° between 35° and 70° between 35° and 65° between 35° and 60° between 35° and 55° between 35° and 50°, between 35° and 45° between 35° and 40°, between 40° and 115°, between 40° and 110°, between 40° and 105°, between 40° and 100°, between 40° and 95°, between 40° and 90°, between 40° and 85°, between 40° and 80°, between 40° and 75°, between 40° and 70°, between 40° and 65°, between 40° and 60°, between 40° and 55°, between 40° and 50°, between 40° and 45°, between 45° and 115°, between 45° and 110°, between 45° and 105°, between 45° and 100°, between 45° and 95°, between 45° and 90°, between 45° and 85°, between 45° and 80°, between 45° and 75°, between 45° and 70°, between 45° and 65°, between 45° and 60°, between 45° and 55°, between 45° and 50°, between 50° and 115°, between 50° and 110°, between 50° and 105°, between 50° and 100°, between 50° and 95°, between 50° and 90°, between 50° and 85°, between 50° and 80°, between 50° and 75°, between 50° and 70°, between 50° and 65°, between 50° and 60°, between 50° and 55°, between 55° and 115°, between 55° and 110°, between 55° and 105°, between 55° and 100°, between 55° and 95°, between 55° and 90°, between 55° and 85°, between 55° and 80°, between 55° and 75°, between 55° and 70°, between 55° and 65°, between 55° and 60°, between 60° and 115°, between 60° and 110°, between 60° and 105°, between 60° and 100°, between 60° and 95°, between 60° and 90°, between 60° and 85°, between 60° and 80°, between 60° and 75°, between 60° and 70°, between 60° and 65°, between 65° and 115°, between 65° and 110°, between 65° and 105°, between 65° and 100°, between 65° and 95°, between 65° and 90°, between 65° and 85°, between 65° and 80°, between 65° and 75°, between 65° and 70°, between 70° and 115°, between 70° and 110°, between 70° and 105°, between 70° and 100°, between 70° and 95°, between 70° and 90°, between 70° and 85°, between 70° and 80°, between 70° and 75°, between 75° and 115°, between 75° and 110°, between 75° and 105°, between 75° and 100°, between 75° and 95°, between 75° and 90°, between 75° and 85°, between 75° and 80°, between 80° and 115°, between 80° and 110°, between 80° and 105°, between 80° and 100°, between 80° and 95°, between 80° and 90°, between 80° and 85°, between 85° and 115°, between 85° and 110°, between 85° and 105°, between 85° and 100°, between 85° and 95°, between 85° and 90°, between 90° and 115°, between 90° and 110°, between 90° and 105°, between 90° and 100°, between 90° and 95°, between 95° and 115°, between 95° and 110°, between 95° and 105°, between 95° and 100°, between 100° and 115°, between 100° and 110°, between 100° and 105°, between 105° and 115°, between 105° and 110°, or between 110° and 115°.

In some embodiments, the threshold contact angle is at least 0°, at least 5°, at least 10°, at least 15°, at least 20°, at least 25°, at least 30°, at least 35°, at least 40°, at least 45°, at least 50°, at least 55°, at least 60°, at least 65°, at least 70°, at least 75°, at least 80°, at least 85°, at least 90°, at least 95°, at least 100°, at least 105°, at least 110°, or at least 115°. In some embodiments, the threshold contact angle is at most 0°, at most 5°, at most 10°, at most 15°, at most 20°, at most 25°, at most 30°, at most 35°, at most 40°, at most 45°, at most 50°, at most 55°, at most 60°, at most 65°, at most 70°, at most 75°, at most 80°, at most 85°, at most 90°, at most 95°, at most 100°, at most 105°, at most 110°, or at most 115°.

### Example 1: Surface Tension of Composition 340

In some embodiments, a composition 340 of the present disclosure was provided with a first surface tension that was less than a second surface tension of a conventional Ga-based liquid metal (e.g., Ga-based liquid metal 1 of FIG. 5, Ga-based liquid metal 1 of FIG. 8, etc.). For instance, referring to FIG. 5, in some embodiments, the first surface tension was less than the second surface tension, such that the composition 340 does not bead on a surface of a deformable substrate 302. Furthermore, this first surface tension allowed the composition 340 to wet the deformable substrate 302.

### Example 2: Viscosity of Composition 340

Referring to FIGS. 5 and 8, a viscosity (e.g., apparent viscosity) of various compositions 340 of the present disclosure was determined.

Referring to FIG. 5, a first composition 340-1 included a first w % of a first metal material 342 and a second w % of a filler material 344. In some embodiments, the first metal material 342 included a gallium indium alloy, such as eutectic GaIn (EGaIn). In some embodiments, the filler material 344 included indium tin oxide (ITO). In some embodiments, the second w % of the filler material 344 included about 5 w % of the first composition 340-1.

A second composition 340-2 included a third w % of the first metal material 342 and a fourth w % of the filler material 344. In some embodiments, the first metal material 342 included a gallium indium alloy, EGaIn. In some embodiments, the filler material 344 included ITO. In some embodiments, the fourth w % of the filler material 344 included about 10 w % of the second composition 340-2.

A third composition 340-3 included a fifth w % of the first metal material 342 and a sixth w % of the filler material 344. In some embodiments, the first metal material 342 included a gallium indium alloy, EGaIn. In some embodiments, the filler material 344 included ITO. In some embodiments, the sixth w % of the filler material 344 included about 20 w % of the third composition 340-3.

Referring to FIG. 8, in some embodiments, a first line interconnect (e.g., trace) of the composition 340 was disposed on a first portion of a surface of a deformable substrate 302. A second line interconnect of a conventional Ga-based liquid metal was disposed on a second portion of the surface of the deformable substrate 302 adjacent to the first portion of the surface. Accordingly, in some embodiments, the composition 340 was more viscous than the conventional Ga-based liquid metal, such that the composition 340 did not smear or streak when subjected to a shear stress.

### Example 3: Resistance of Composition 340

Referring to FIG. 9, a resistance of a composition 340 of the present disclosure was determined.

The composition 340 included a first w % of a first metal material 342 and a second w % of a filler material 344. In some embodiments, the first metal material 342 included a gallium indium alloy, such as eutectic GaIn (EGaIn). In some embodiments, the filler material 344 included a metal oxide. In some embodiments, the filler material 344 includes Al, C, Cu, Ga, ITO, Li, Ni, Ti, Al₂O₃, Cu₂O, CuO, Ga₂O₃, Li₂O, NiO, Ni₂O₃, TiO₂, or a combination thereof.

In some embodiments, the composition 340 was disposed on a deformable substrate 302. Deformable substrate 302 included a first layer 310-1 of a circuit 305 having a composition 340 of the present disclosure disposed on a surface of the first layer 310-1.

In some embodiments, the first layer 310-1 included polyethylene terephthalate (PET). In some embodiments, the first layer 310-1 is loaded with nanoparticles of a first material, such as Au, Ag, Cu, Pd, Pt, or a combination thereof, or any alloy thereof.

In some embodiments, a second layer 310-2 of the circuit was formed overlaying a portion of the first layer 310-1. In some embodiments, the second layer 31-2 includes one or more polyorganosiloxanes, one or more fillers, one or more additives, or a combination thereof.

In some embodiments, the second layer 310-2 included a silicon solvent. In some embodiments, the silicon solvent included a first portion of hexamethyldisiloxane and a second portion of octamethyltrisiloxane.

In some embodiments, the second layer 310-2 includes 50 w % of the one or more polyorganosiloxanes, one or more fillers, one or more additives, or the combination thereof. In some embodiments, the deformable substrate 302 includes 50 w % of the first portion of hexamethyldisiloxane and the second portion of octamethyltrisiloxane.

In some embodiments, the deformable substrate 302 included an interconnect (e.g., a trace) interposing between the first layer 310-1 and the second layer 310-2, that represented a coupling between a first circuit component 330-1 and a second circuit component 330-2 of the circuit 305. The interconnected included a composition 340 of the present disclosure. In some embodiments, the second layer 310-2 encapsulated the interconnect. In some embodiments, a size (e.g., width) W3 of the interconnect was about 0.1 cm.

The deformable substrate was subjected to 100% strain at a first strain cycle of at least 15,000 cycles.

Accordingly, the composition 340 provides a resistance between 0.07 Ω/cm and 0.16 Ω/cm between about 100 cycles and about 15,000 cycles of the first strain cycle. In some embodiments, the composition 340 provides a resistance of 0.06 Ω/cm, at least 0.07 Ω/cm, or at least 0.08 Ω/cm during the first strain cycle. In some embodiments, the composition 340 provides a resistance of at most 0.15 Ω/cm, at most 0.16 Ω/cm, or at most 0.17 Ω/cm during the first strain cycle.

Accordingly, the composition 340 of the present disclosure provides improved deformability (e.g., stretchability). Moreover, the composition 340 of the present disclosure maintains fluidic behavior after being subjected to 100% strain at the first strain cycle of at least 15,000 cycles.

### Example 4: Deformable Substrate 302

Referring to FIG. 10, an exemplary deformable substrate 302 is depicted. In some embodiments, the deformable substrate 302 included a first layer 310-1 of a circuit 305 and a second layer 310-2 of the circuit 305.

In some embodiments, the thickness of layer 310 is between 0.01 centimeters (cm) and 50 cm, between 0.01 cm and 45 cm, between 0.01 cm and 40 cm, between 0.01 cm and 35 cm, between 0.01 cm and 30 cm, between 0.01 cm and 25 cm, between 0.01 cm and 20 cm, between 0.01 cm and 15 cm, between 0.01 cm and 10 cm, between 0.01 cm and 5 cm, between 0.01 cm and 3 cm, between 0.01 cm and 1 cm, between 0.01 cm and 0.1 cm, between 0.1 cm and 50 cm, between 0.1 cm and 45 cm, between 0.1 cm and 40 cm, between 0.1 cm and 35 cm, between 0.1 cm and 30 cm, between 0.1 cm and 25 cm, between 0.1 cm and 20 cm, between 0.1 cm and 15 cm, between 0.1 cm and 10 cm, between 0.1 cm and 5 cm, between 0.1 cm and 3 cm, between 0.1 cm and 1 cm, between 0.5 cm and 50 cm, between 0.5 cm and 45 cm, between 0.5 cm and 40 cm, between 0.5 cm and 35 cm, between 0.5 cm and 30 cm, between 0.5 cm and 25 cm, between 0.5 cm and 20 cm, between 0.5 cm and 15 cm, between 0.5 cm and 10 cm, between 0.5 cm and 5 cm, between 0.5 cm and 3 cm, between 0.5 cm and 1 cm, between 1 cm and 50 cm, between 1 cm and 45 cm, between 1 cm and 40 cm, between 1 cm and 35 cm, between 1 cm and 30 cm, between 1 cm and 25 cm, between 1 cm and 20 cm, between 1 cm and 15 cm, between 1 cm and 10 cm, between 1 cm and 5 cm, between 3 cm and 50 cm, between 3 cm and 45 cm, between 3 cm and 40 cm, between 3 cm and 35 cm, between 3 cm and 30 cm, between 3 cm and 25 cm, between 3 cm and 20 cm, between 3 cm and 15 cm, between 3 cm and 10 cm, between 3 cm and 5 cm, between 10 cm and 50 cm, between 10 cm and 45 cm, between 10 cm and 40 cm, between 10 cm and 35 cm, between 10 cm and 30 cm, between 10 cm and 25 cm, between 10 cm and 20 cm, between 10 cm and 15 cm, between 15 cm and 50 cm, between 15 cm and 45 cm, between 15 cm and 40 cm, between 15 cm and 35 cm, between 15 cm and 30 cm, between 15 cm and 25 cm, between 15 cm and 20 cm, between 20 cm and 50 cm, between 20 cm and 45 cm, between 20 cm and 40 cm, between 20 cm and 35 cm, between 20 cm and 30 cm, between 20 cm and 25 cm, between 25 cm and 50 cm, between 25 cm and 45 cm, between 25 cm and 40 cm, between 25 cm and 35 cm, between 25 cm and 30 cm, between 30 cm and 50 cm, between 30 cm and 45 cm, between 30 cm and 40 cm, between 30 cm and 35 cm, between 35 cm and 50 cm, between 35 cm and 45 cm, between 35 cm and 40 cm, between 40 cm and 50 cm, between 40 cm and 45 cm, or between 45 cm and 50 cm.

In some embodiments, the thickness of layer 310 is at least 0.01 cm, at least 0.03 cm, at least 0.05 cm, at least 0.08 cm, at least 0.1 cm, at least 0.3 cm, at least 0.5 cm, at least 0.8 cm, at least 1 cm, at least 3 cm, at least 5 cm, at least 8 cm, at least 10 cm, at least 13 cm, at least 15 cm, at least 18 cm, at least 20 cm, at least 23 cm, at least 25 cm, at least 28 cm, at least 30 cm, at least 33 cm, at least 35 cm, at least 38 cm, at least 40 cm, at least 43 cm, at least 45 cm, at least 48 cm, or at least 50 cm. In some embodiments, the thickness of layer 310 is at most 0.01 cm, at most 0.03 cm, at most 0.05 cm, at most 0.08 cm, at most 0.1 cm, at most 0.3 cm, at most 0.5 cm, at most 0.8 cm, at most 1 cm, at most 3 cm, at most 5 cm, at most 8 cm, at most 10 cm, at most 13 cm, at most 15 cm, at most 18 cm, at most 20 cm, at most 23 cm, at most 25 cm, at most 28 cm, at most 30 cm, at most 33 cm, at most 35 cm, at most 38 cm, at most 40 cm, at most 43 cm, at most 45 cm, at most 48 cm, or at most 50 cm.

For instance, in some embodiments, the first layer 310-1 has a first length L1 of about 30 cm, a first width W1 of about 14 cm, a first thickness of about 0.0125 cm, or a combination thereof. In some embodiments, the second layer 310-2 has a second length L2 of about 26 cm, a second width W2 of about 10 cm, the first thickness of about 0.0125 cm, or a combination thereof. In some embodiments, the second layer 310-2 has a second thickness different from the first thickness.

In some embodiments, the deformable substrate 302 was translucent or transparent.

In some embodiments, the first layer 310-1 included polyethylene terephthalate (PET). In some embodiments, the first layer 310-1 is loaded with nanoparticles of a first material, such as Au, Ag, Cu, Pt, Pd, or a combination thereof, or any allow thereof.

In some embodiments, the second layer 310-2 includes one or more polyorganosiloxanes, one or more fillers, one or more additives, or a combination thereof.

In some embodiments, the second layer 310-2 included a silicon solvent. In some embodiments, the silicon solvent included a first portion of hexamethyldisiloxane and a second portion of octamethyltrisiloxane.

In some embodiments, the second layer 310-2 includes 50 w % of the one or more polyorganosiloxanes, one or more fillers, one or more additives, or the combination thereof. In some embodiments, the deformable substrate 302 includes 50 w % of the first portion of hexamethyldisiloxane and the second portion of octamethyltrisiloxane.

### Example 5: Strain of Composition 340

Referring to FIGS. 11A and 11B, a deformable substrate 302 included a first layer 310-1 of a circuit 305 having a composition 340 of the present disclosure disposed on a surface of the first layer 310-1.

In some embodiments, the first layer 310-1 included polyethylene terephthalate (PET). In some embodiments, the first layer 310-1 is loaded with nanoparticles of a first material, such as Au, Ag, Cu, Pd, Pt, or any combination thereof, or any alloy thereof.

In some embodiments, a second layer 310-2 of the circuit 305 was formed overlaying a portion of the first layer 310-1. In some embodiments, the second layer 31-2 includes one or more polyorganosiloxanes, one or more fillers, one or more additives, or a combination thereof.

In some embodiments, the second layer 310-2 included a silicon solvent. In some embodiments, the silicon solvent includes a first portion of hexamethyldisiloxane and a second portion of octamethyltrisiloxane.

In some embodiments, the second layer 310-2 includes 50 w % of the one or more polyorganosiloxanes, one or more fillers, one or more additives, or the combination thereof. In some embodiments, the deformable substrate 302 includes 50 w % of the first portion of hexamethyldisiloxane and the second portion of octamethyltrisiloxane.

In some embodiments, the deformable substrate 302 included an interconnect (e.g., a trace) interposing between the first layer 310-1 and the second layer 310-2, that represented a coupling between a first circuit component 330-1 and a second circuit component 330-2 of the circuit 305. The interconnected included a composition 340 of the present disclosure. In some embodiments, the second layer 310-2 encapsulated the interconnect. In some embodiments, a size (e.g., width) W3 of the interconnect was about 0.1 cm.

In some embodiments, the deformable substrate 302 was subjected to 100% strain at a first strain cycle of at least 16,000 cycles. The first strain cycle strained the deformable substrate 302 at a rate of about 20% per second. FIG. 11A illustrates the deformable substrate 302 and the interconnect that included the composition 340 formed on a Cu layer of the interconnect. FIG. 11B illustrates the deformable substrate 302 and the interconnect that included the composition 340 after subjected to the first strain cycle. Accordingly, the composition 340 provides a resistance between 0.2 Ω/cm and 0.7 Ω/cm between about 2,000 cycles and about 16,000 cycles of the first strain cycle.

### Example 6: Disposing a Composition 340 Using an Additive Manufacture Apparatus 250

In some embodiments, a first circuit component 330-1 and a second circuit component 330-2 of a circuit 305 of a deformable substrate 302 was coupled with a composition 340 in order to form electronical communication through the circuit 305 between the first circuit component 330-1 and the second circuit component 330-2. One or more additive manufacture apparatuses 250 is utilized in order to form the first circuit component 330-1, the second circuit component 330-2, the deformable substrate 302, a structure from the composition 340, or a combination.

In some embodiments, a first additive manufacture apparatus 250-1 is utilized to form the electronical communication provided by the composition 340 between the first circuit component 330-1, the second circuit component 330-2, the composition 340, or a combination thereof.

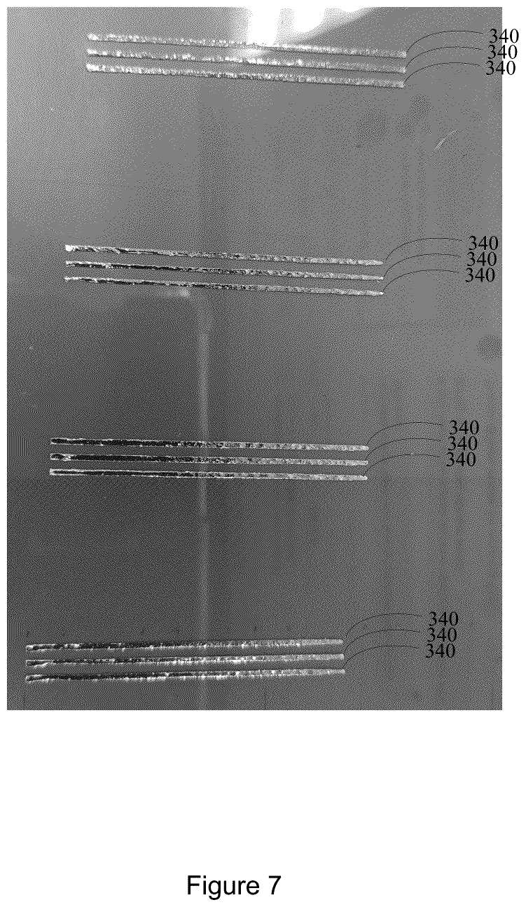

Referring to FIG. 7, in some embodiments, the first additive manufacture apparatus 250-1 was utilized to dispose a volume of the composition 340 using a stencil printing pattern technique.

Referring to FIG. 8, in some embodiments, the first additive manufacture apparatus 250-1 was utilized to dispose a volume of the composition 340 using a screen printing pattern technique.

Accordingly, the composition 340 of the present disclosure was utilized with various additive manufacture apparatus 250 and pattern techniques in order to dispose the composition 340 on a portion of the deformable substrate 302.

### Example 7: Disposing a Volume of a Second Metal Material 340-2 Using an Additive Manufacture Apparatus 250

Referring to FIG. 12A, a set of interconnect circuit components 330 was formed on a first surface of a deformable substrate 302.

In some embodiments, the deformable substrate 302 includes one or more polyorganosiloxanes, one or more fillers, one or more additives, or a combination thereof.

In some embodiments, the deformable substrate 302 included a silicon solvent. In some embodiments, the silicon solvent includes a first portion of hexamethyldisiloxane and a second portion of octamethyltrisiloxane.

In some embodiments, the deformable substrate 302 includes 50 w % of the one or more polyorganosiloxanes, one or more fillers, one or more additives, or the combination thereof. In some embodiments, the deformable substrate 302 includes 50 w % of the first portion of hexamethyldisiloxane and the second portion of octamethyltrisiloxane.

In some embodiments, the layer of an interconnect in the set of interconnects is about 1 μm in size (e.g., about 1 μm thick and/or 1 μm width). In some embodiments, the layer of the interconnect in the set of interconnects was Cu. In some embodiments, the layer of the interconnect in the set of interconnects was formed by a sputtering technique.

Referring to FIG. 12B, in some embodiments, a volume of a composition 340 was disposed on a portion of the layer of the set of interconnects. In some embodiments, the volume of the composition 340 was disposed using a first additive manufacture apparatus 250.

### Example 8: Method of Manufacturing Wearable Electronic Device

In some embodiments, the present disclosure provided a method of manufacturing an electronic device. The method included forming a first circuit component 330-1 at a first portion of a deformable substrate 302. The method further included forming a second circuit component 330-2 at a second portion of the deformable substrate 302. Furthermore, the method included electronically coupling the first circuit component 330-1 and the second circuit component 330-2 with a composition 340. The composition 340 included a first metal material 340-1 having a first w % of the composition 340. The first metal material 340-1 was gallium indium alloy, gallium tin alloy, gallium indium tin alloy, gallium indium tin zinc alloy, or a combination thereof. The composition 340 further included a filler material 340-2 disposed within the first metal material 340-1. The filler material 340-2 included a second w % of the composition. From this composition 340, the method formed an interconnect between the first circuit component 3300-1 and the second circuit component 330-2. The interconnect is free of degradation in conductivity when the deformable substrate 302 is bent around a cylinder that has a radius of between 14 cm and 25 cm for a period of time between 10 seconds and 1 hour and then released. In some embodiments, this cylinder is sized to resemble a size of an adult human wrist. In some embodiments, the first circuit component 330-1 is a CPU (e.g., CPU 274 of FIG. 2). In some embodiments, the first circuit component 330-1 is a sensor. In some embodiments, the second circuit component 330-2 is a sensor. In some embodiments, the first circuit component 330-1 is a first sensor and the second circuit component 330-2 is a second sensor different from the first sensor.

### EXEMPLARY IMPLEMENTATIONS

Implementation 1. A method of manufacturing an electronic device. The method includes forming a first circuit component at a first portion of a deformable substrate. The method further includes forming a second circuit component at a second portion of the deformable substrate. Furthermore, the method includes electronically coupling the first circuit component and the second circuit component with a composition. The composition a first metal material having a first weight percent (w %) of the composition. The first metal material is gallium indium alloy, gallium tin alloy, gallium indium tin alloy, gallium indium tin zinc alloy, or a combination thereof. The composition further includes a filler material disposed within the first metal material. The filler material includes a second w % of the composition. From this composition, the method forms an interconnect between the first circuit component and the second circuit component.

Implementation 2. The method of Implementation 1, in which the composition is a non-Newtonian composition and/or a shear-thinning composition.

Implementation 3. The method of Implementations 1 or 2, in which the composition includes a homogenous mixture of the first metal material and the filler material.

Implementation 4. The method of any one of Implementations 1-3, in which the filler material is a metal oxide, a metal oxide-based polymer, or a combination thereof.

Implementation 5. The method of any one of Implementations 1-4, in which the filler material includes aluminum, carbon, copper, gallium, indium-tin oxide (ITO), lithium, nickel, titanium, or a combination thereof.

Implementation 6. The method of any one of Implementations 1-5, in which the filler material includes a non-intrinsic metal oxide.

Implementation 7. The method of any one of Implementations 1-6, in which adding the filler material to the first metal material is added in the form of microflakes, nanoflakes, microparticles, nanoparticles, nanowires, nanotubes, or a combination thereof, to form the composition.

Implementation 8. The method of any one of Implementations 1-7, in which the filler material includes poly(3,4-ethylenedioxythiophene) (PEDOT).

Implementation 9. The method of any one of Implementations 1-8, in which the filler material includes polystyrene sulfonate (PEDOT:PSS).

Implementation 10. The method of any one of Implementations 1-9, in which the method further includes disposing exogenously the filler material within the first metal material to form the composition.

Implementation 11. The method of any one of Implementations 1-10, in which the method further includes disposing the filler material within the first metal material without sintering the first metal material and/or the filler material to form the composition.

Implementation 12. The method of any one of Implementations 1-11, in which the second w % of the filler material is between 0.5 w % and 25 w % within the composition.

Implementation 13. The method of any one of Implementations 1-12, in which the second w % of the filler material is between 13 w % and 15 w % within the composition.

Implementation 14. The method of any one of Implementations 1-13, in which the second w % of the filler material is greater than 15 w % within the composition.

Implementation 15. The method of any one of Implementations 1-14, in which the first metal material is a solvent of the composition, and the filler material is a solute of the composition.

Implementation 16. The method of any one of Implementations 1-15, in which the method further includes coupling the first circuit component to the second circuit component with the composition to form the interconnect when the filler material is oversaturated in excess of a saturation point of the filler material in the first metal material in the composition.

Implementation 17. The method of any one of Implementations 1-16, in which the interconnect formed by the composition has a resistance under at most 100 Ohms per cm when the interconnect is subjected to 100% strain.

Implementation 18. The method of any one of Implementations 1-17, in which the interconnect formed by the composition maintains conductivity when subjected to at least 15,000 strain cycles.

Implementation 19. The method of any one of Implementations 1-18, in which the interconnect formed by the composition has a resistance under at most 100 Ohms per cm when the interconnect is subjected to 100% strain at a first strain cycle, and under at most 100 Ohms per cm when subjected to 100% strain at a second strain cycle.

Implementation 20. The method of any one of Implementations 1-19, in which the second strain cycle is at least 15,000 strain cycles greater than the first strain cycle.

Implementation 21. The method of any one of Implementations 1-20, in which the method further includes disposing the composition between the first circuit component and the second circuit component using a source for the composition that, at a temperature between 64 degrees Fahrenheit (° F.) and 72° F., has a viscosity that is between 0.5 Pascal seconds (Pa·s) and 1.6 Pa·s, thereby forming the interconnect.

Implementation 22. The method of any one of Implementations 1-21, in which the composition further includes a dispersant material different than the first metal material and the filler material.

Implementation 23. The method of any one of Implementations 1-22, in which the composition includes a contact angle of less than 90 degrees (°) when interfacing with a deformable substrate.

Implementation 24. The method of any one of Implementations 1-23, in which the interconnect has a width of less than 500 μm, less than 400 μm, less than 300 μm, less than 200 μm, less than 100 μm, less than 90 μm, less than 80 μm, less than 70 μm, less than 60 μm less than 50 μm, less than 40 μm, less than 30 μm, less than 20 μm, less than 10 μm, less than 5 μm or less than 1 μm.

Implementation 25. The method of any one of Implementations 1-24, in which the interconnect has a width of between 1 and 500 μm, between 2 and 400 μm, between 3 and 300 μm, between 4 and 200 μm, between 6 and 100 μm, or between 10 and 90 μm.

Implementation 26. The method of any one of Implementations 1-25, in which the interconnect has a thickness of less than 500 μm, less than 400 μm, less than 300 μm, less than 200 μm, less than 100 μm, less than 90 μm, less than 80 μm, less than 70 μm, less than 60 μm less than 50 μm, less than 40 μm, less than 30 μm, less than 20 μm, less than 10 μm, less than 5 μm or less than 1 μm.

Implementation 27. The method of any one of Implementations 1-26, in which the interconnect has a thickness of between 1 and 500 μm, between 2 and 400 μm, between 3 and 300 μm, between 4 and 200 μm, between 6 and 100 μm, or between 10 and 90 μm.

Implementation 28. The method of any one of Implementations 1-27, in which the electronically coupling includes tracing out one or more lines, one or more vias, or any combination of one or more lines and one or more vias to form the interconnect between the first circuit component and the second circuit component using the composition.

Implementation 29. The method of any one of Implementations 1-28, in which the electronic device is a display.

Implementation 30. The method of any one of Implementations 1-29, in which the first circuit component and the second circuit component form part of an active-matrix array.

Implementation 31. The method of any one of Implementations 1-30, in which the interconnect is free of degradation in conductivity when the deformable substrate is bent around a cylinder that has a radius of between 2 centimeters (cm) and 10 cm for a period of time and then released.

Implementation 32. The method of any one of Implementations 1-31, in which the period of time is between 10 seconds and five minutes.

Implementation 33. The method of any one of Implementations 1-32, in which the first circuit component and the second circuit component are part of a transistor switch.

Implementation 34. An electronic device is provided. The electronic device includes a deformable substrate. Furthermore, the deformable substrate includes a circuit. The circuit includes a first circuit component and a second circuit component. The first circuit component is disposed at a first portion of the deformable substrate. Moreover, the second circuit component is disposed at a second portion of the deformable substrate. The circuit further includes an interconnect extending from the first portion of the deformable substrate to the second portion of the deformable substrate. The interconnect includes a first metal material and a filler material. The first metal material includes a first weight percent (w %) of the composition. Moreover, the first metal material is gallium indium alloy, gallium tin alloy, gallium indium tin alloy, gallium indium tin zinc alloy, or a combination thereof. Furthermore, the filler material is disposed within the first metal material. The filler material includes a second w % of the composition, thereby forming an interconnect between the first circuit component and the second circuit component.

Implementation 35. The electronic device of Implementation 34, in which the filler material is a metal oxide.

### REFERENCES CITED AND ALTERNATIVE EMBODIMENTS

All references cited herein are incorporated herein by reference in their entirety and for all purposes to the same extent as if each individual publication or patent or patent application was specifically and individually indicated to be incorporated by reference in its entirety for all purposes.

The present invention can be implemented as a computer program product that includes a computer program mechanism embedded in a non-transitory computer-readable storage medium. For instance, the computer program product could contain instructions for operating the user interfaces described with respect to FIG. 2. These program modules can be stored on a CD-ROM, DVD, magnetic disk storage product, USB key, or any other non-transitory computer readable data or program storage product.

Many modifications and variations of this invention can be made without departing from its spirit and scope, as will be apparent to those skilled in the art. The specific embodiments described herein are offered by way of example only. The embodiments were chosen and described in order to best explain the principles of the invention and its practical applications, to thereby enable others skilled in the art to best utilize the invention and various embodiments with various modifications as are suited to the particular use contemplated. The invention is to be limited only by the terms of the appended claims, along with the full scope of equivalents to which such claims are entitled.

What is claimed is:

1. A method of manufacturing an electronic device comprising
forming a first circuit component at a first portion of a deformable substrate;
forming a second circuit component at a second portion of the deformable substrate; and
electronically coupling the first circuit component and the second circuit component with a composition comprising
a first metal material comprising a first weight percent (w %) of the composition, wherein the first metal material is gallium indium alloy, gallium tin alloy, gallium indium tin alloy, gallium indium tin zinc alloy, or a combination thereof, and
a filler material disposed within the first metal material, wherein the filler material comprises a second w % of the composition, thereby forming an interconnect between the first circuit component and the second circuit component.

2. The method of claim 1, wherein the composition is a non-Newtonian composition and/or a shear-thinning composition.

3. The method of claim 1, wherein the composition comprises a homogenous mixture of the first metal material and the filler material.

4. The method of claim 1, wherein the filler material is a metal oxide, a metal oxide-based polymer, or a combination thereof.

5. The method of claim 1, wherein the filler material comprises a non-intrinsic metal oxide.

6. The method of claim 1, wherein the method further comprises disposing exogenously the filler material within the first metal material to form the composition.

7. The method of claim 1, the method further comprising adding the filler material to the first metal material in the form of microflakes, nanoflakes, microparticles, nanoparticles, nanowires, nanotubes, or a combination thereof, to form the composition.

8. The method of claim 1, the method further comprising disposing the filler material within the first metal material without sintering the first metal material and/or the filler material to form the composition.

9. The method of claim 1, wherein the filler material comprises indium-tin oxide (ITO).

10. The method of claim 1, wherein the filler material comprises aluminum, carbon, copper, gallium, lithium, nickel, titanium, or a combination thereof.

11. The method of claim 1, wherein the filler material comprises poly(3,4-ethylenedioxythiophene) (PEDOT) or polystyrene sulfonate (PEDOT:PSS).

12. The method of claim 1, wherein the second w % of the filler material is between 0.5 w % and 25 w %, or between 13 w % and 15 w % within the composition.

13. The method of claim 1, the method further comprising coupling the first circuit component to the second circuit component with the composition to form the interconnect when the filler material is oversaturated in excess of a saturation point of the filler material in the first metal material in the composition.

14. The method of claim 1, wherein the interconnect formed by the composition has a resistance under at most 100 Ohms per centimeter (cm) when the interconnect is subjected to 100% strain at a first strain cycle, and under at most 100 Ohms per cm when subjected to 100% strain at a second strain cycle at least 15,000 strain cycles greater than the first strain cycle.

15. The method of claim 1, wherein the method further comprises disposing the composition between the first circuit component and the second circuit component using a source for the composition that, at a temperature between 64 degrees Fahrenheit (° F.) and 72° F., has a viscosity that is between 0.5 Pascal seconds (Pa·s) and 1.6 Pa·s, thereby forming the interconnect.

16. The method of claim 1, wherein the composition further comprises a dispersant material different from the first metal material and the filler material.

17. The method of claim 1, wherein the interconnect has
a width between 1 and 500 microns (μm), between 2 and 400 μm, between 3 and 300 μm, between 4 and 200 μm, between 6 and 100 μm, or between 10 and 90 μm, and
a thickness that is between 1 and 500 μm, between 2 and 400 μm, between 3 and 300 μm, between 4 and 200 μm, between 6 and 100 μm, or between 10 and 90 μm.

18. The method of claim 1, wherein the first circuit component and the second circuit component form part of an active-matrix array.

19. The method of claim 1, wherein the interconnect is free of degradation in conductivity when the deformable substrate is bent around a cylinder that has a radius of between 2 cm and 10 cm for a period of time between 10 seconds and five minutes and then released.

20. A method of manufacturing an electronic device comprising
forming a first circuit component at a first portion of a deformable substrate;
forming a second circuit component at a second portion of the deformable substrate; and
electronically coupling the first circuit component and the second circuit component with a composition comprising
a first metal material comprising a first weight percent (w %) of the composition, wherein the first metal material is gallium indium alloy, gallium tin alloy, gallium indium tin alloy, gallium indium tin zinc alloy, or a combination thereof, and
a filler material disposed within the first metal material, wherein the filler material comprises a second w % of the composition, thereby forming an interconnect between the first circuit component and the second circuit component, and wherein
the interconnect is free of degradation in conductivity when the deformable substrate is bent around a cylinder that has a radius of between 14 cm and 25 cm for a period of time between 10 seconds and 1 hour and then released.
